(19) United States
(12) Patent Application Publication
(10) Pub. No.: US 2010/0133996 A1
(43) Pub. Date: Jun. 3, 2010

(54) Novel anthracene typed compound and the organic electroluminescence display device using the same

(75) Inventors: Hyoung-don Moon, Osan-City (KR); Tae-jin Park, Incheon (KR); Hyun-cheol An, HwaSeoung-City (KR); Jong-hyub Baek, Seoul (KR); Hoe-taek Yang, Hwaseoung-City (KR); Sang-ook Kang, Chungcheongnam-do (KR); Won-sik Han, Seoul (KR); Kyung-ryang Wee, Yeosu-City (KR); Ji-yun Chun, Seoul (KR)

Correspondence Address: LEXYOUME IP GROUP, LLC, 5180 PARKSTONE DRIVE, SUITE 175, CHANTILLY, VA, 20151, US

(73) Assignee: Dongjin Semichem Co., Ltd, Incheon (KR)

(21) Appl. No.: 12/598,493

(22) PCT Filed: May 7, 2008
(86) PCT No.: PCT/KR08/02568

§ 371 Date: Nov. 2, 2009

(30) Foreign Application Priority Data
May 9, 2007 (KR) 10-2007-0044881
Jun. 26, 2007 (KR) 10-2007-0063117

(51) Int. Cl. H05B 33/02; C07F 7/08; C07C 25/22

(52) U.S. Cl. 313/504; 556/489; 546/14; 548/406; 570/129

(57) ABSTRACT

The present invention relates to an anthracene compound and an organic electroluminescent display device using the same. Particularly, the present invention relates to an anthracene compound which has good blue light emitting property, transports holes and electrons efficiently to enable an organic electroluminescent display device to have a low voltage, high brightness and long lifetime, and an organic electroluminescent display device using the same.

### TECHNICAL FIELD

The present invention relates to a novel compound and an organic electroluminescent display device using the same, and more particularly, to a compound which has good blue light emitting property, transports holes and electrons efficiently to enable an organic electroluminescent display device to have a low voltage, high brightness and long lifetime, and an organic electroluminescent display device using the same.

### BACKGROUND ART

An organic electroluminescent display device has such a configuration that an anode is formed on a substrate, and a hole transporting layer, a light emitting layer, an electron transporting layer and a cathode are sequentially formed on the anode. The hole transporting layer, the light emitting layer and the electron transporting layer are organic thin layers including an organic compound.

A driving principle of an organic electroluminescent display device having the foregoing configuration is as follows.

If a voltage is applied to the anode and cathode, a hole is moved from the anode to the light emitting layer through the hole transporting layer. Meanwhile, an electron is injected to the light emitting layer through the electron transporting layer, and carriers are recombined in the light emitting layer to generate an exiton. The exiton is changed from an excited state to a ground state, and accordingly, fluorescent molecules in the light emitting layer emit light to thereby form an image. If the excited state is changed into a ground state through a singlet excited state, it is called fluorescence. If the excited state is changed into a ground state through a triplet excited state, it is called phosphorescence. As for the fluorescence, the probability of a single excited state is 25% (75% for a triplet state) and a light emitting efficient is limited. Meanwhile, if phosphorescence is used, a triplet excited state of 75% and a singlet excited state of 25% may be used. Theoretically, up to 100% internal quantum efficiency is available.

There have been attempts since the early 1960's to apply an anthracene compound to an organic electroluminescent display device. In 1965, Helfrich and Pope announced a blue organic electroluminescent phenomenon using a single crystal of anthracene. However, a high voltage was required to emit light with anthracene single crystal and lifetime of the device was too short to be practical.

Even recently, there are lots of attempts to apply an anthracene molecule having various substitution bodies to an organic electroluminescent display device. For example, Korean Patent First Publication No. 10-2006-0050915 and Korean Patent No. 10-0422914 (chemical formula F below) disclose anthracene derivatives as a blue light emitting material. However, a blue light emitting derivative which has anthracene combining with a silane derivative is yet to be disclosed.

### DISCLOSURE

### Technical Problem

Accordingly, it is an aspect of the present invention to provide a compound which has good blue light emitting property, transports holes and electrons efficiently to enable an organic electroluminescent display device to have a low voltage, high brightness and long lifetime, and an organic electroluminescent display device using the same.

### Technical Solution

Additional aspects and advantages of the general inventive concept will be set forth in part in the description which follows and, in part, will be obvious from the description, or may be learned by practice of the general inventive concept.

The foregoing and/or other aspects and advantages of the present invention are achieved by providing a compound which is represented by one of following chemical formulas 1 to 6:

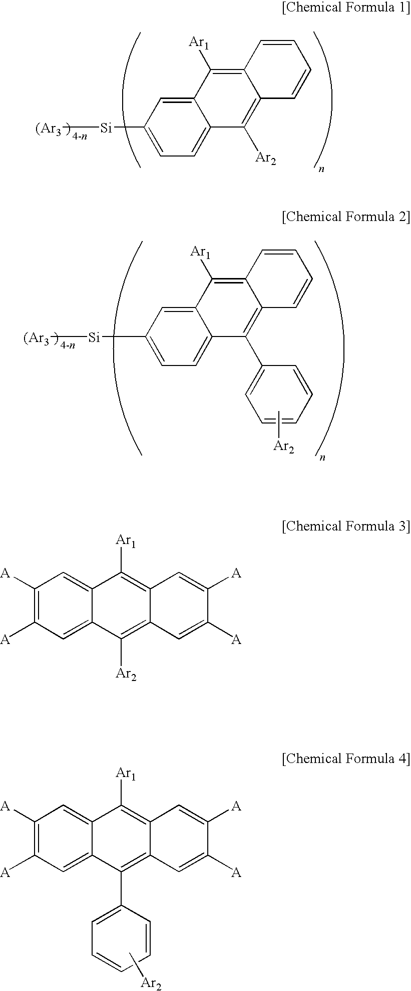

wherein, Ar₁, Ar₂ and Ar₃ are a substituted or unsubstituted aryl group, independently, n is a positive number from 1 to 4, A is hydrogen, CF₃ or a substituted or unsubstituted triarylsilyl group, and at least one of A is CF₃ or a substituted or unsubstituted triarylsilyl group,

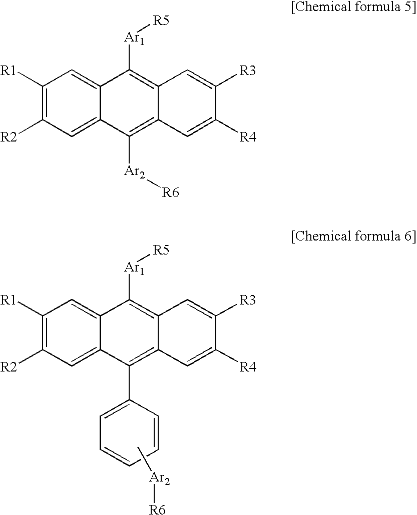

wherein, Ar₁ and Ar₂ are a substituted or unsubstituted aryl group, independently, R₁ to R₆ are hydrogen or CF₃, independently, and at least one of R₁ to R₆ is CF₃.

The foregoing and/or other aspects and advantages of the present invention are achieved by providing a making method of a compound which is represented by one of the chemical formulas 1 to 4 including one of following reaction formulas 1 to 4:

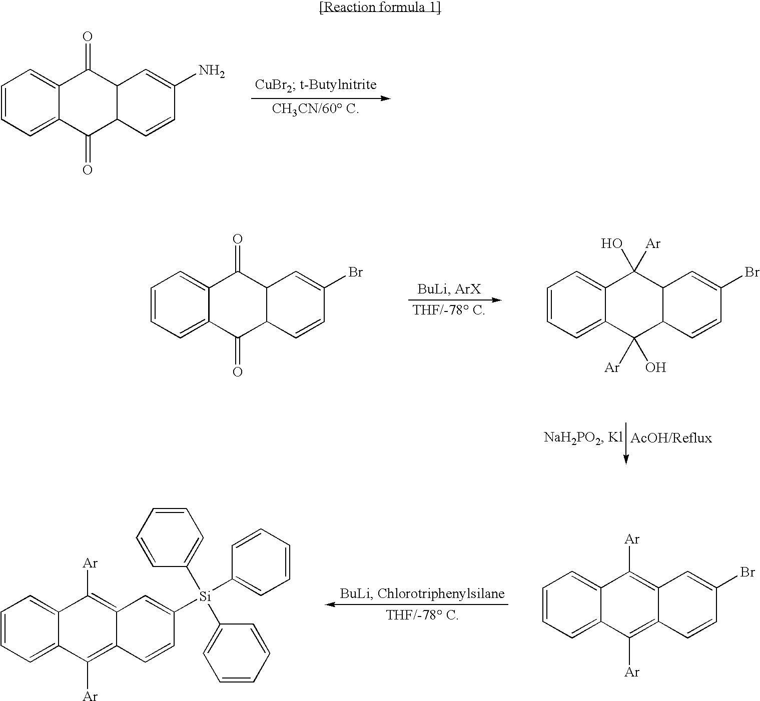

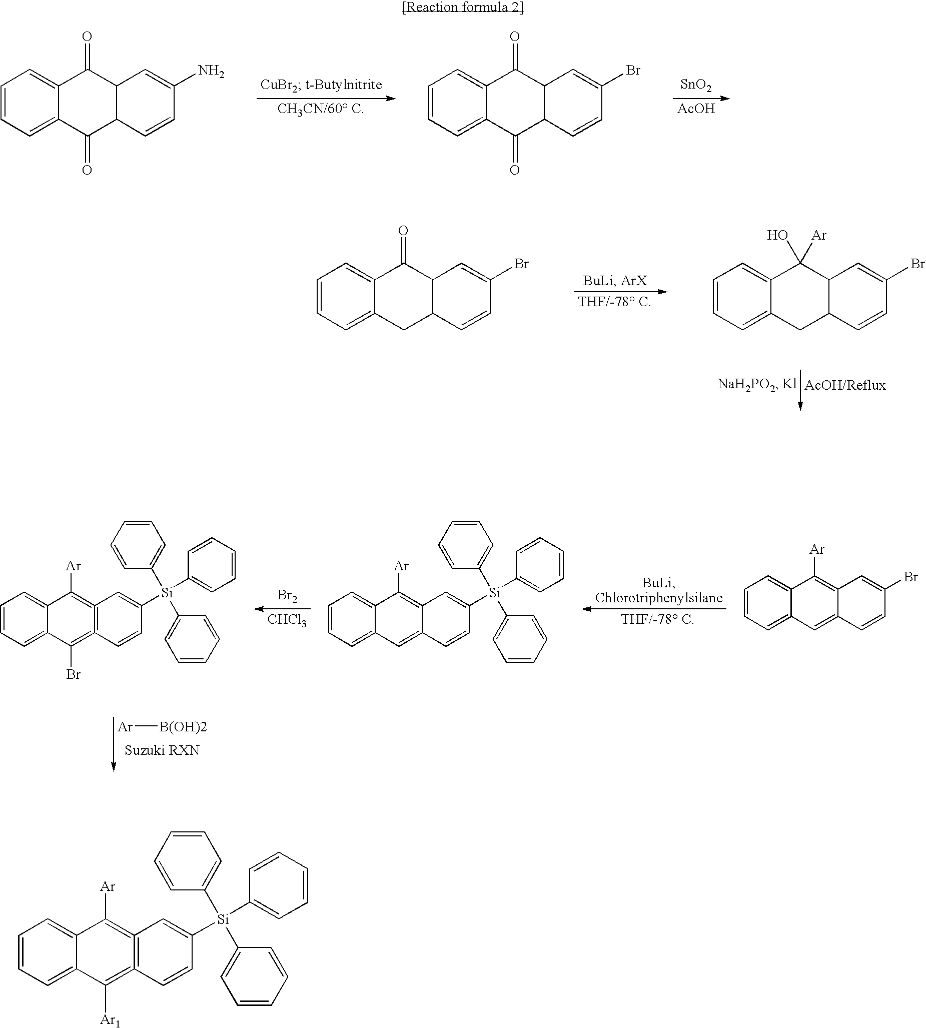

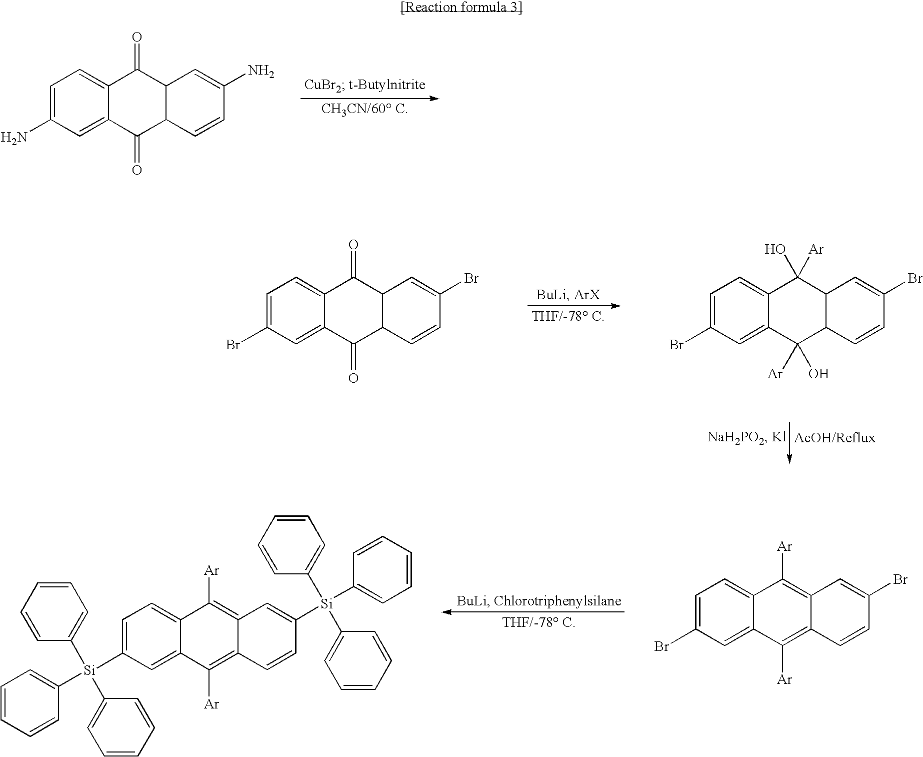

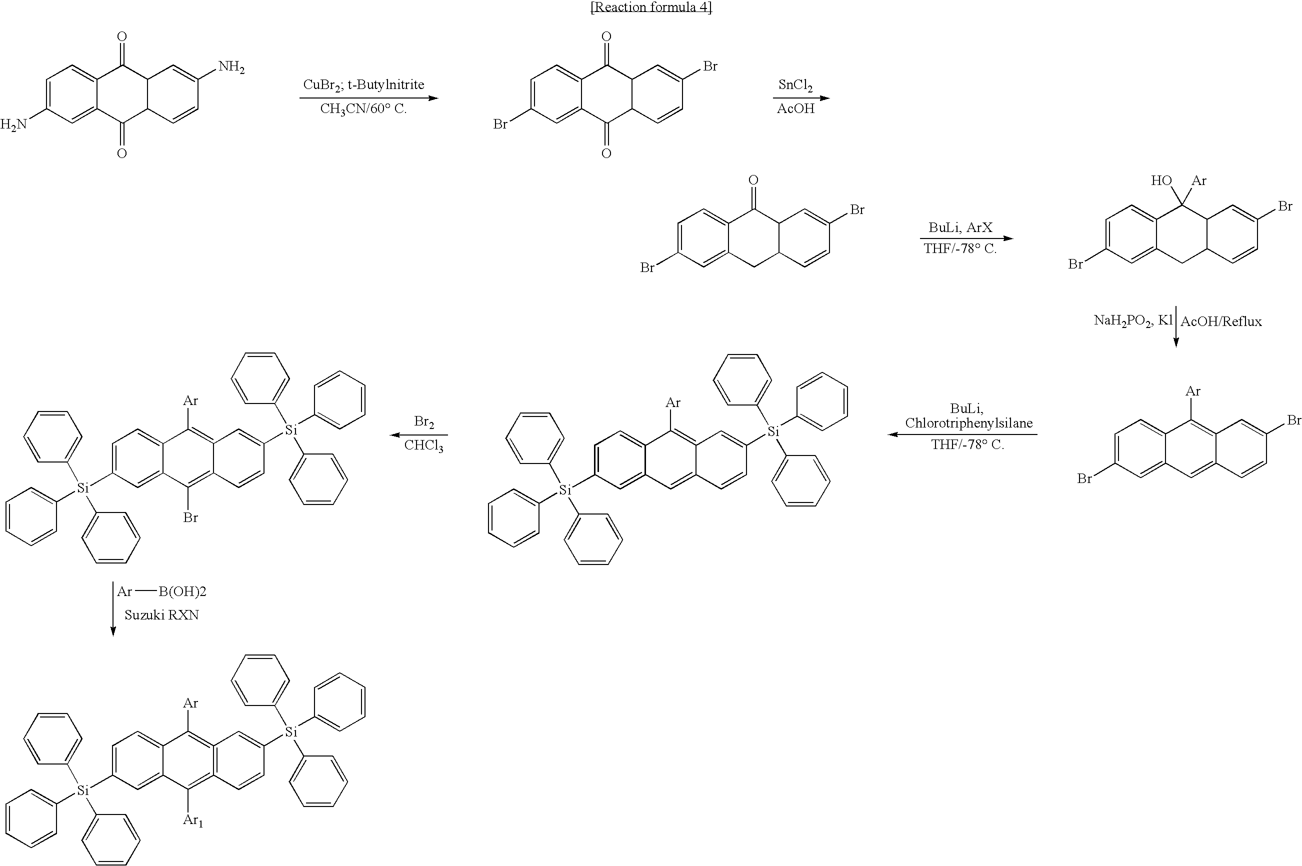

wherein, Ar and Ar₁ are a substituted or unsubstituted aryl group, independently, and X is a halogen compound.

The foregoing and/or other aspects and advantages of the present invention are achieved by providing an organic thin layer of an organic electroluminescent device which is formed by the anthracene compound.

The foregoing and/or other aspects and advantages of the present invention are achieved by providing an organic electroluminescent device which comprises at least one organic thin layer between an anode and a cathode, the display device comprising at least one organic thin layer.

The foregoing and/or other aspects and advantages of the present invention are achieved by providing a display device which comprises the organic electroluminescent display device.

### ADVANTAGEOUS EFFECTS

An anthracene type compound which is represented by chemical formulas 1 to 6 according to the present invention provides good blue light emitting property and hole transporting property, is used as a blue light emitting material or a host for various phosphorescent or fluorescent dopants such as red, green, blue and white colors, is applicable to an organic electroluminescent display device for high efficiency, low voltage, high brightness and long lifetime.

### DESCRIPTION OF DRAWINGS

The above and/or other aspects of the present invention will become apparent and more readily appreciated from the following description of the embodiments, taken in conjunction with the accompany drawings of which:

FIG. 1 is a sectional view of an organic electroluminescent display device according to an exemplary embodiment of the present invention; and

FIGS. 2 and 3 illustrate electroluminescent spectrum, voltage-brightness curve, voltage-current density curve and efficiency curve of the organic electroluminescent display device having a light emitting layer including a compound synthesized according to the exemplary embodiment of the present invention.

### MODE FOR INVENTION

Hereinafter, exemplary embodiments of the present invention will be described with reference to accompanying drawings, wherein like numerals refer to like elements and repetitive descriptions will be avoided as necessary.

Hereinafter, the present invention will be described in detail.

An anthracene compound which is represented by one of chemical formulas 1 to 6 according to the present invention has good blue light emitting property, transports holes and electrons efficiently to enable an organic electroluminescent display device to have a low voltage, high brightness and long lifetime, and an organic electroluminescent display device using the same.

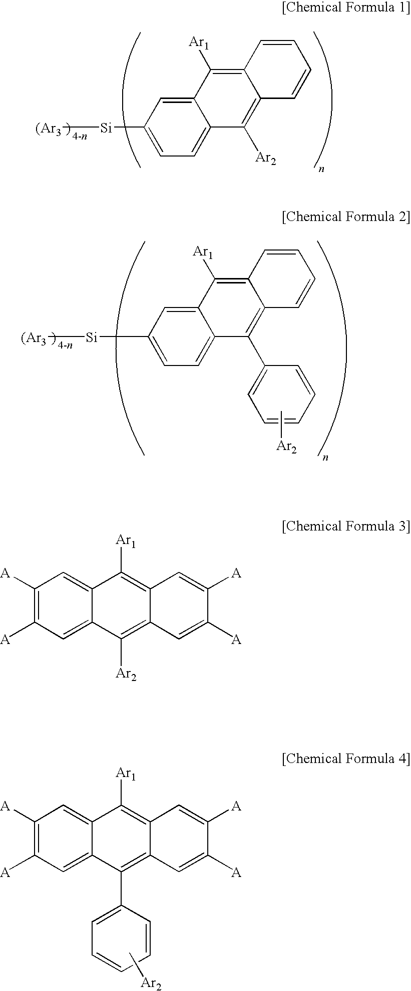

In the chemical formulas 1 to 4, Ar₁, Ar₂ and Ar₃ are a substituted or unsubstituted aryl group, independently. n is a positive number from 1 to 4, A is hydrogen, CF₃ or a substituted or unsubstituted triarylsilyl group. At least one of A is CF₃ or a substituted or unsubstituted triarylsilyl group.

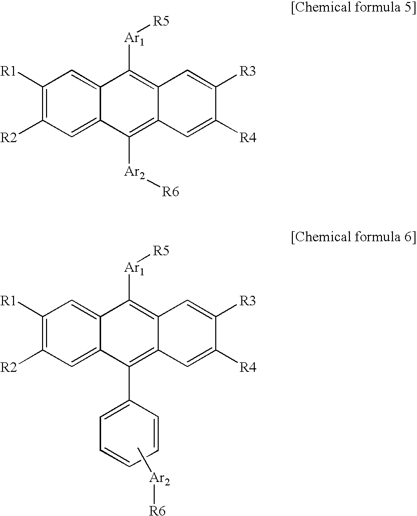

In the chemical formulas 5 and 6, Ar₁ and Ar₂ are a substituted or unsubstituted aryl group, independently. R₁ to R₆ are hydrogen or CF₃ independently, and at least one of R₁ to R₆ is CF₃.

Preferably, 6 to 50 carbons are included in the aryl group.

The compound which is represented by the chemical formulas 1 to 4 may be made by one of reaction formulas 1 to 4.

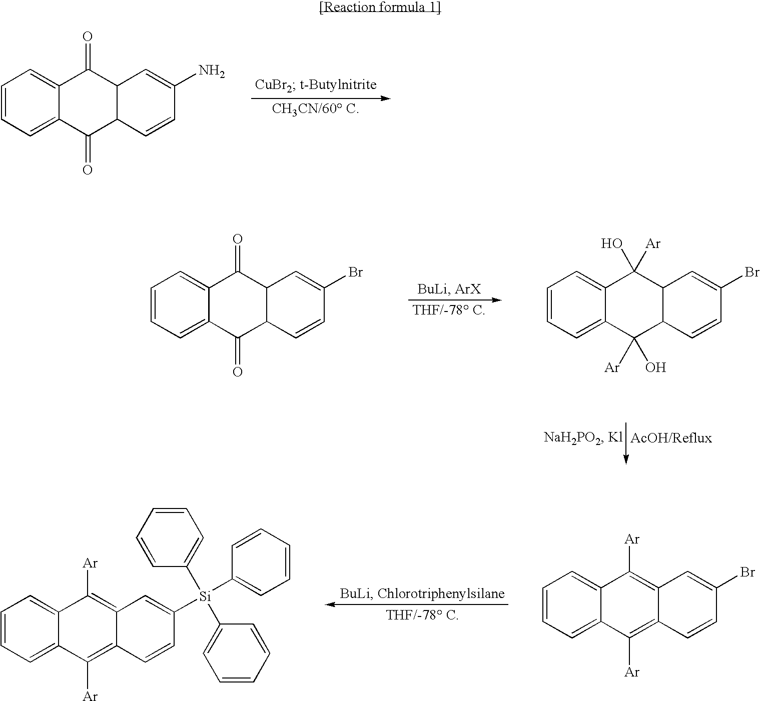

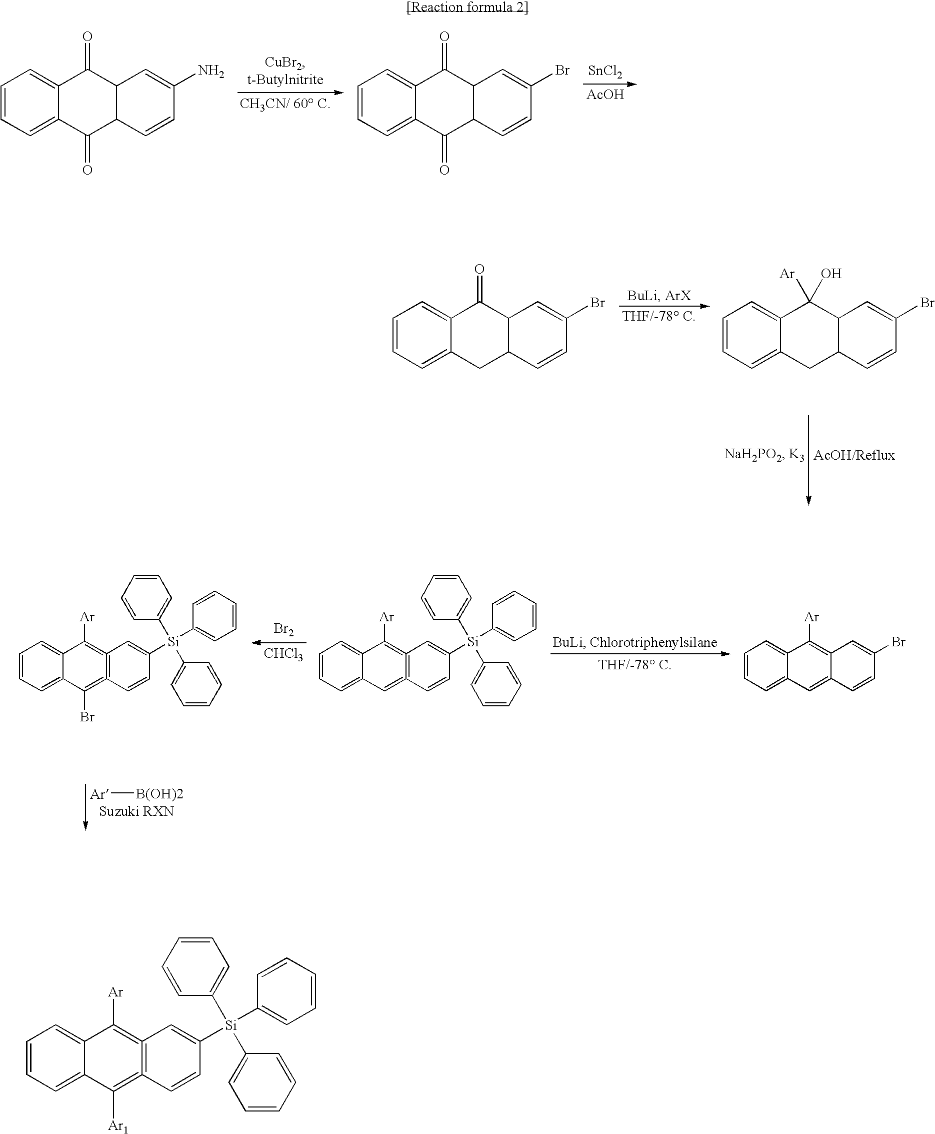

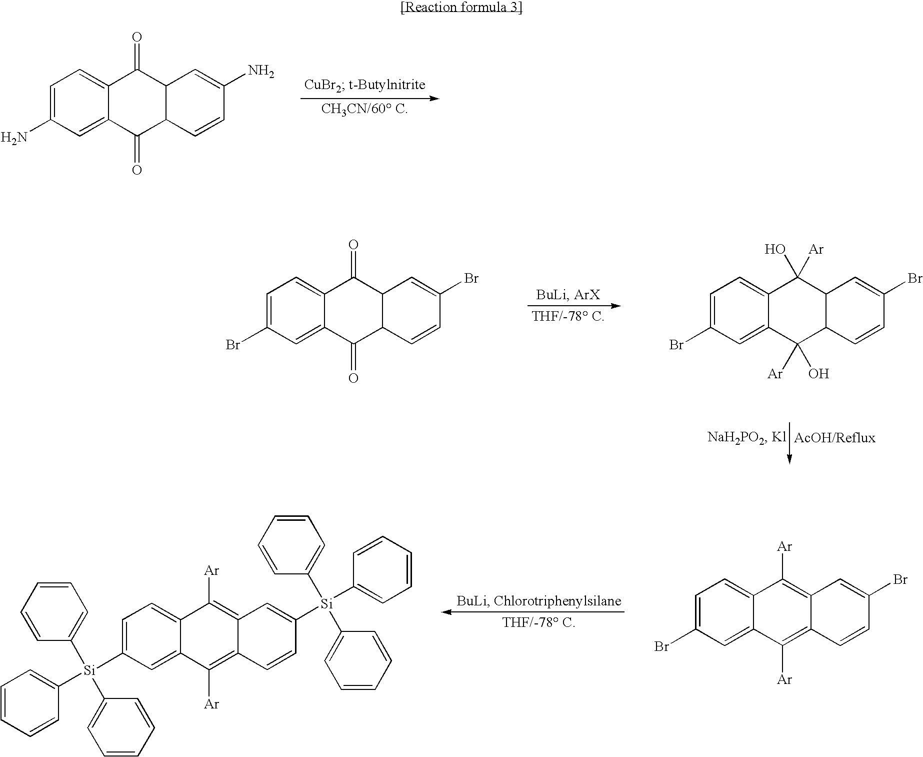

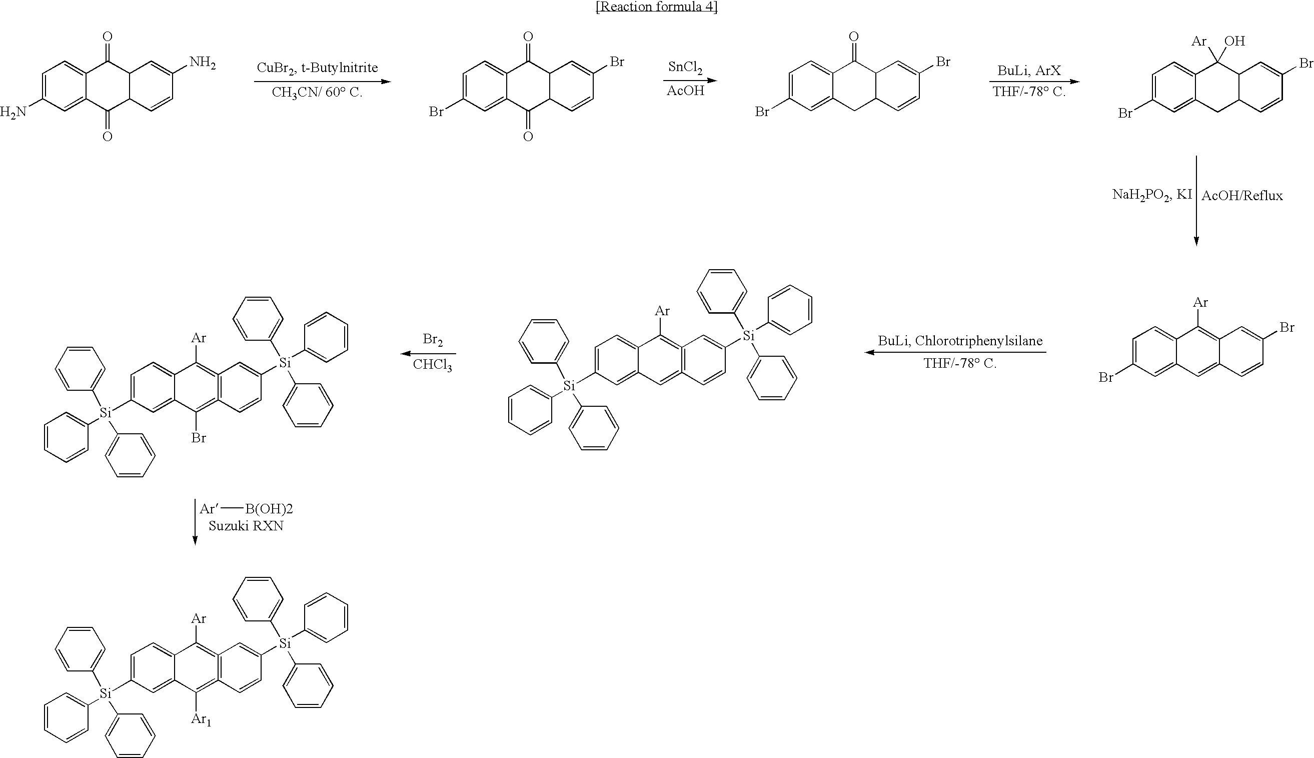

In the reaction formulas 1 to 4, Ar and Ar₁ are a substituted or unsubstituted aryl group, independently. The aryl group has carbons of 6 to 50, X is a halogen compound, and preferably, X is Br.

Preferably, the compound which is represented by the chemical formulas 1 to 6 includes one of compounds represented by chemical formulas 1-1 to 6-2.

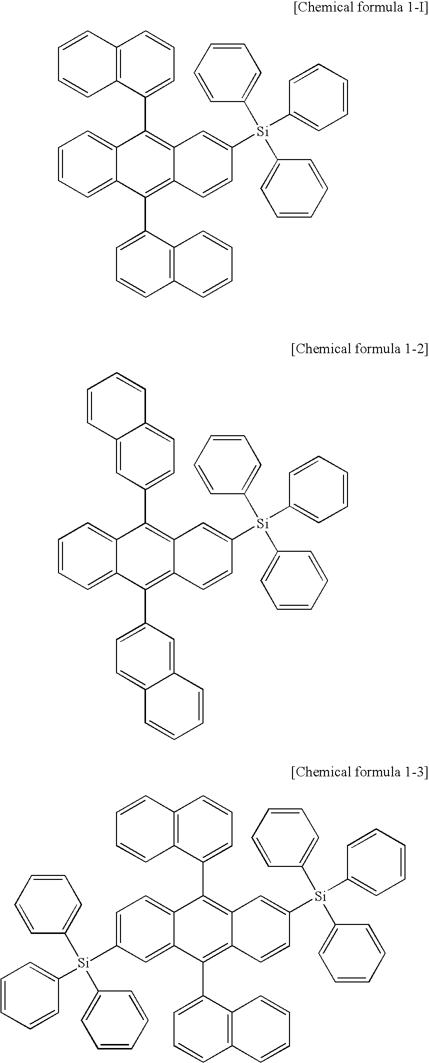

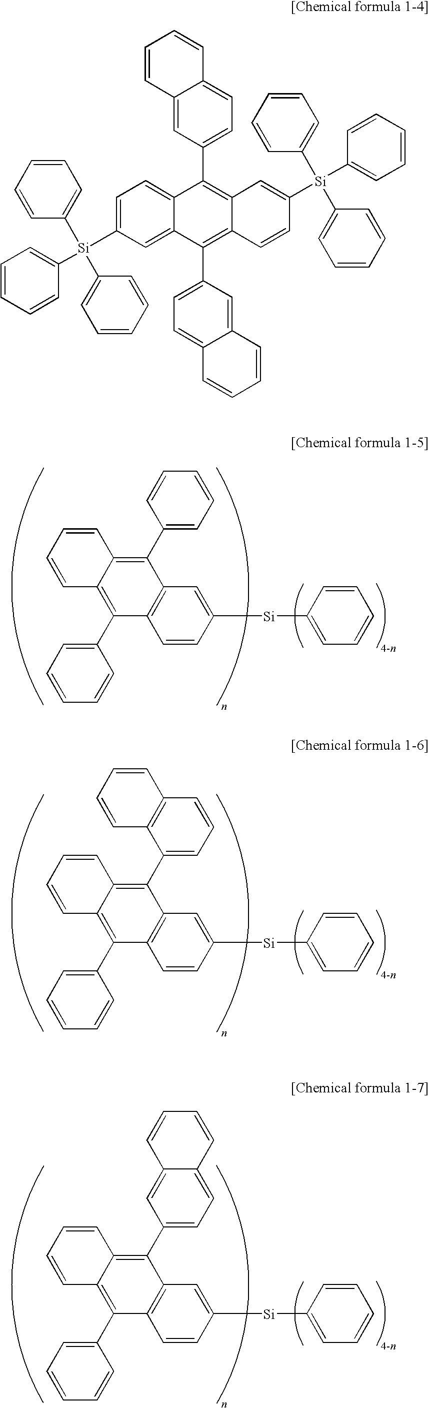

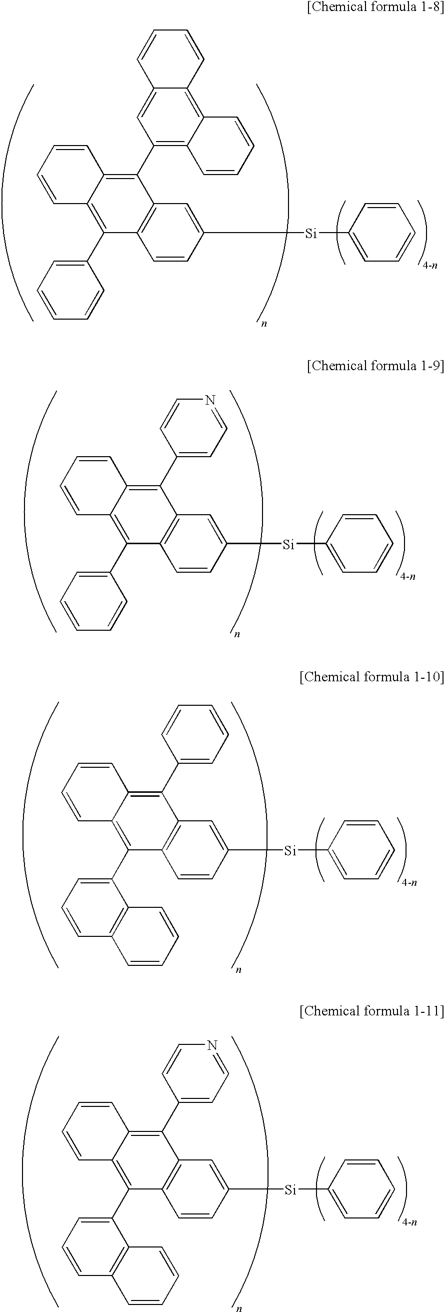

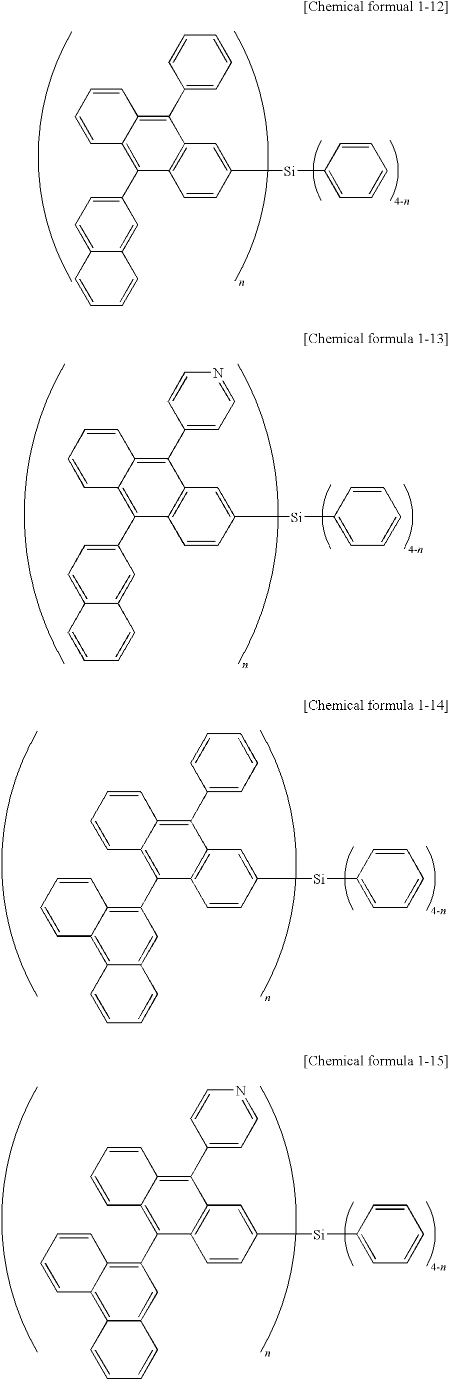

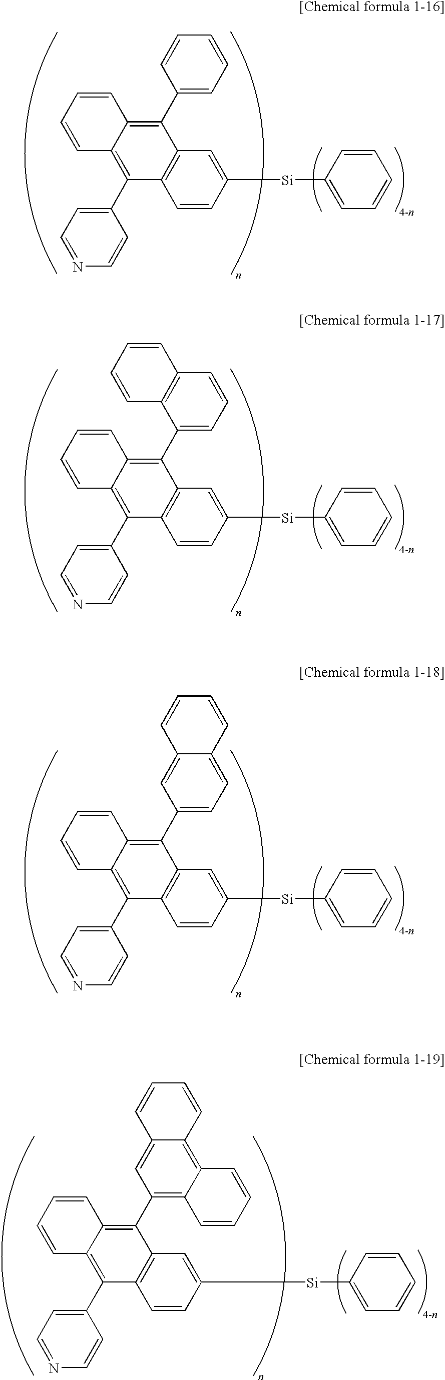

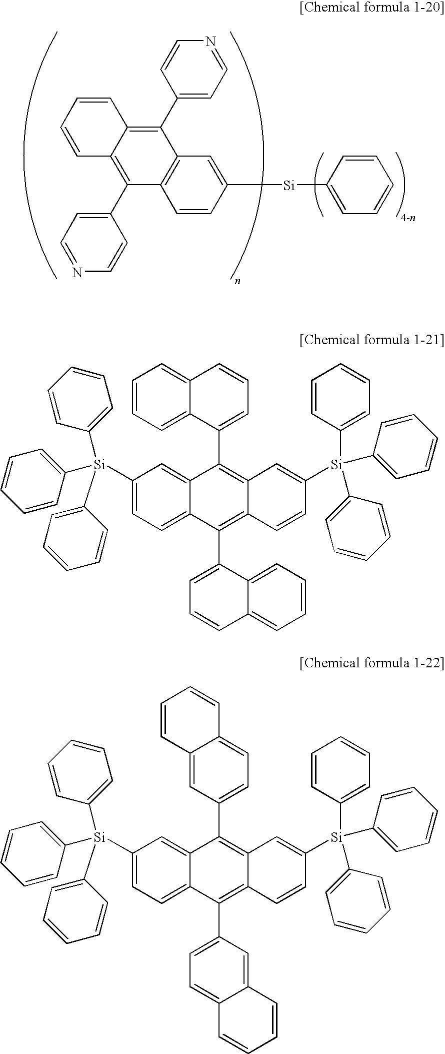

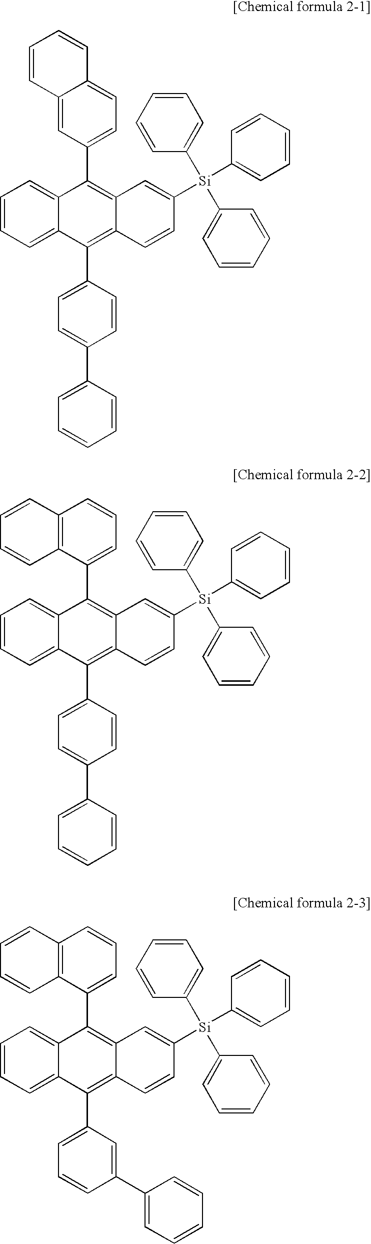

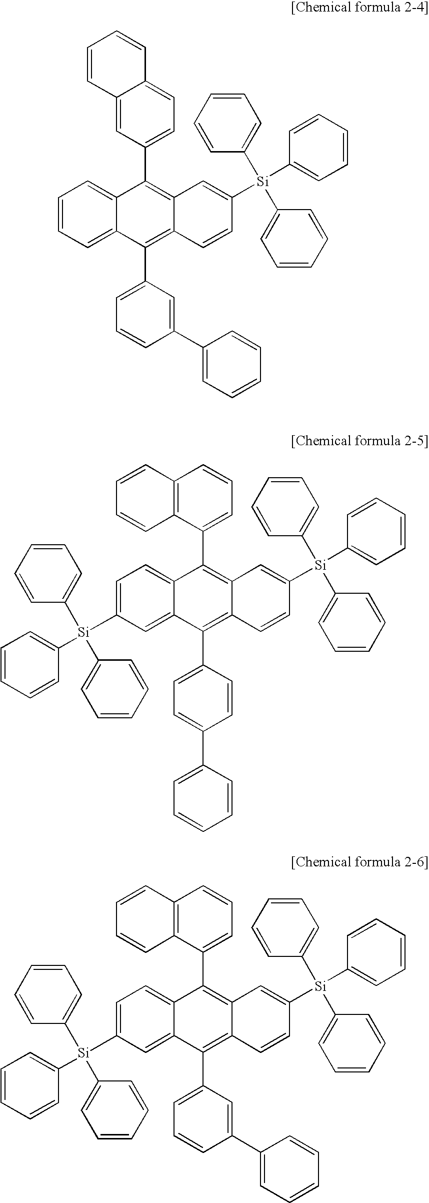

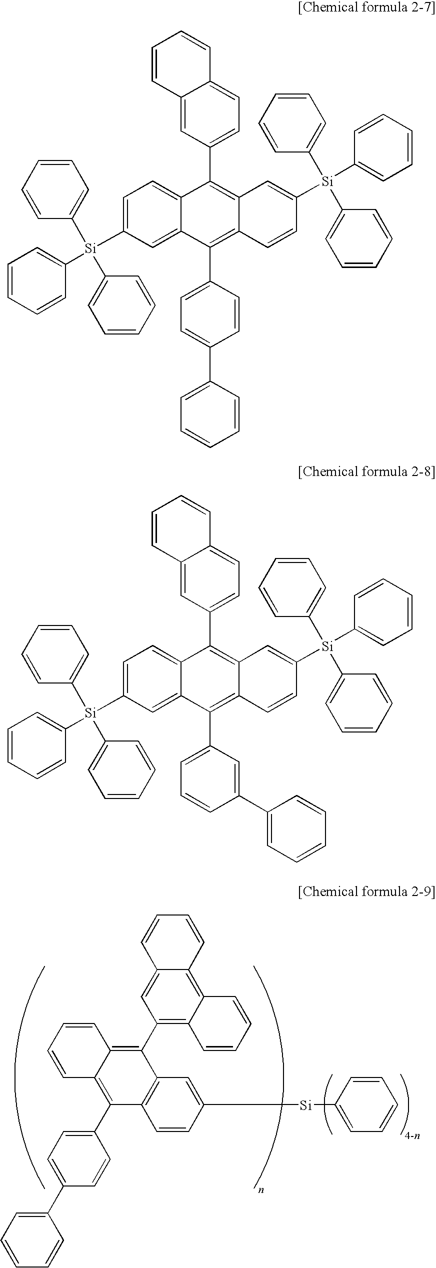

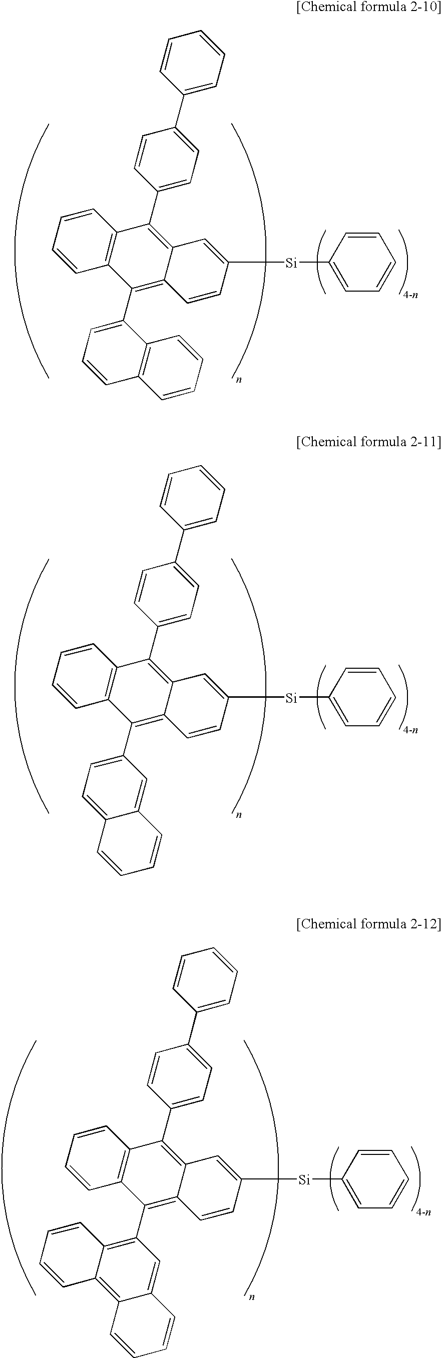

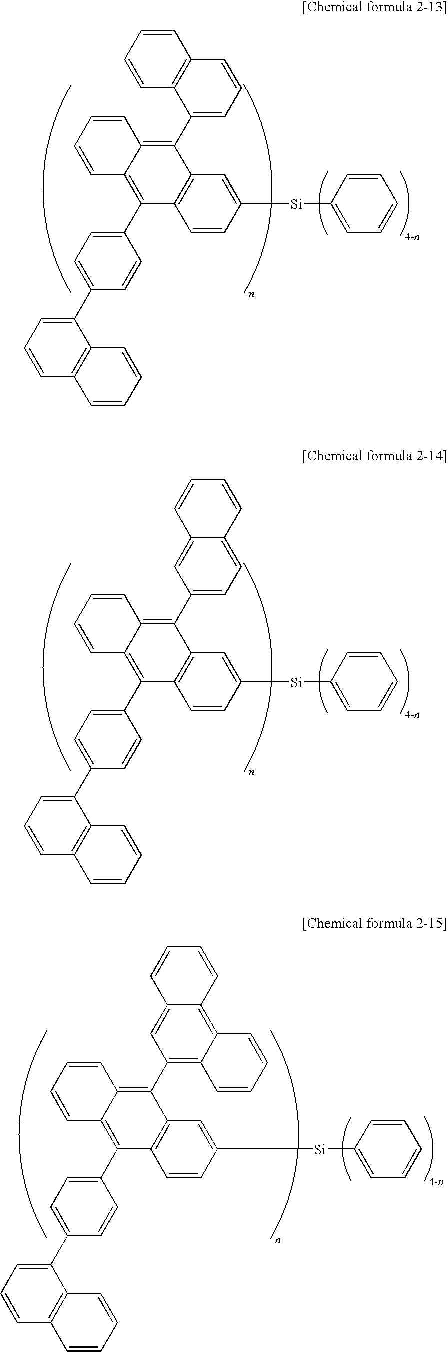

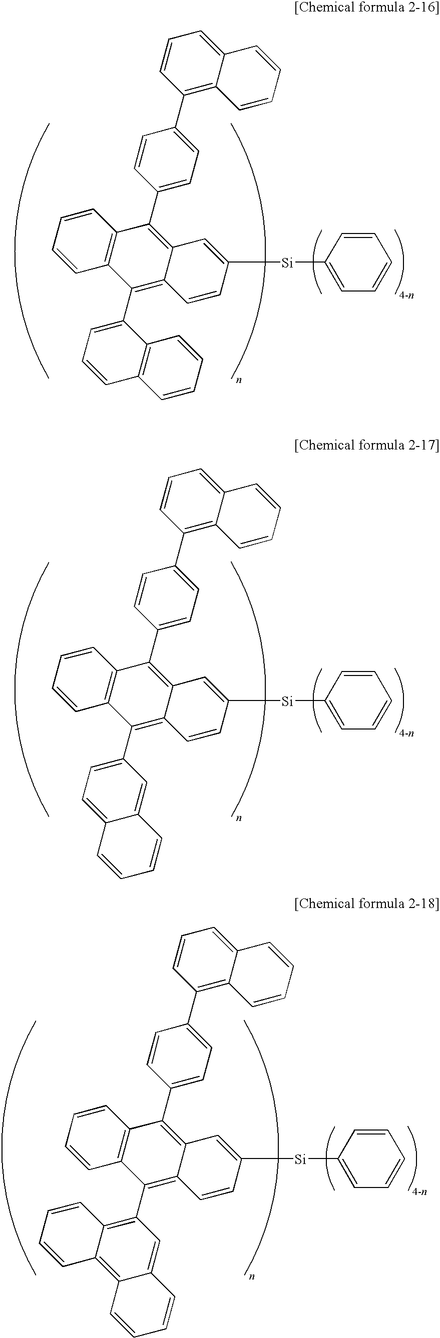

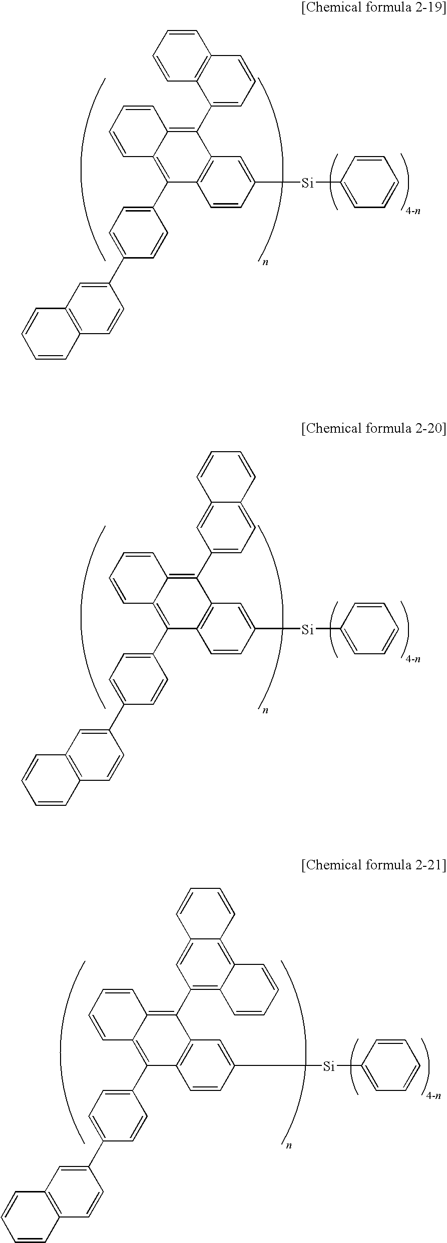

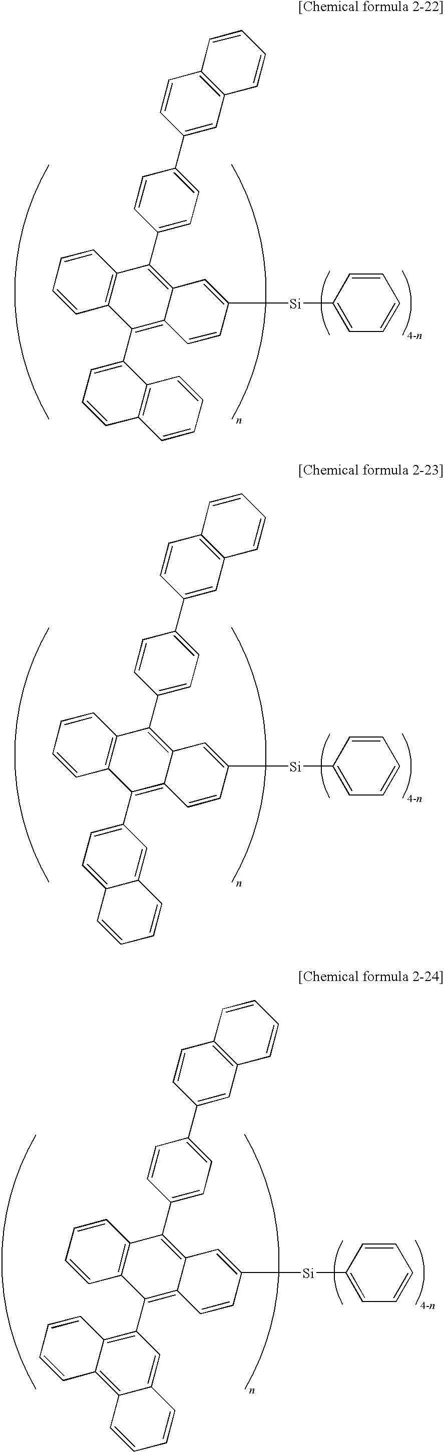

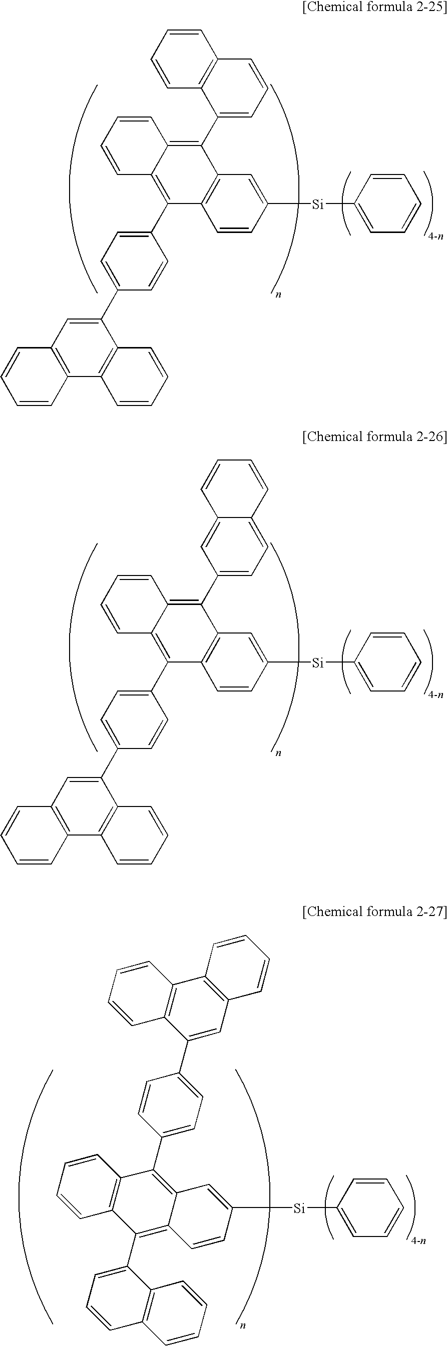

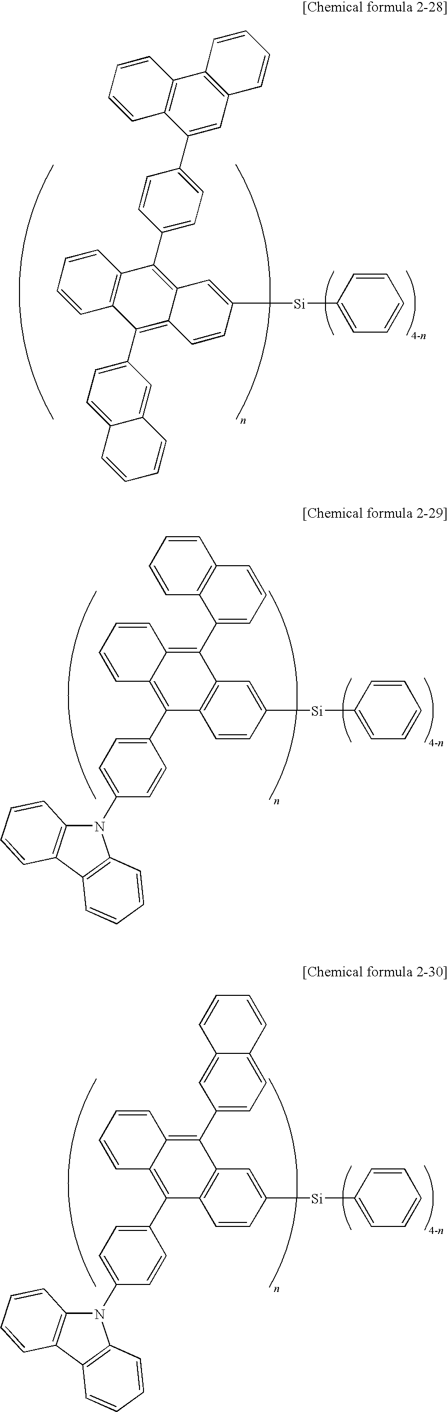

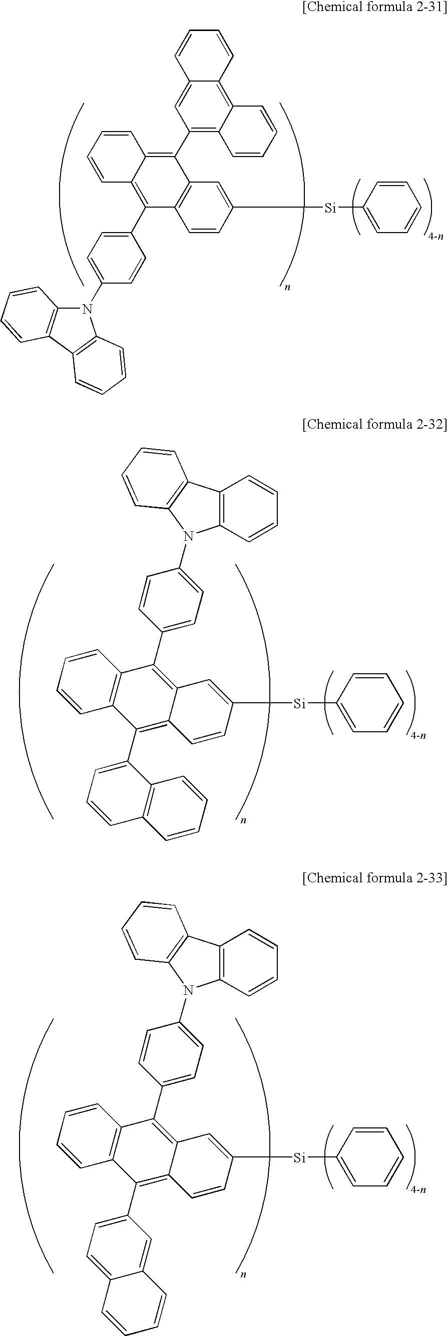

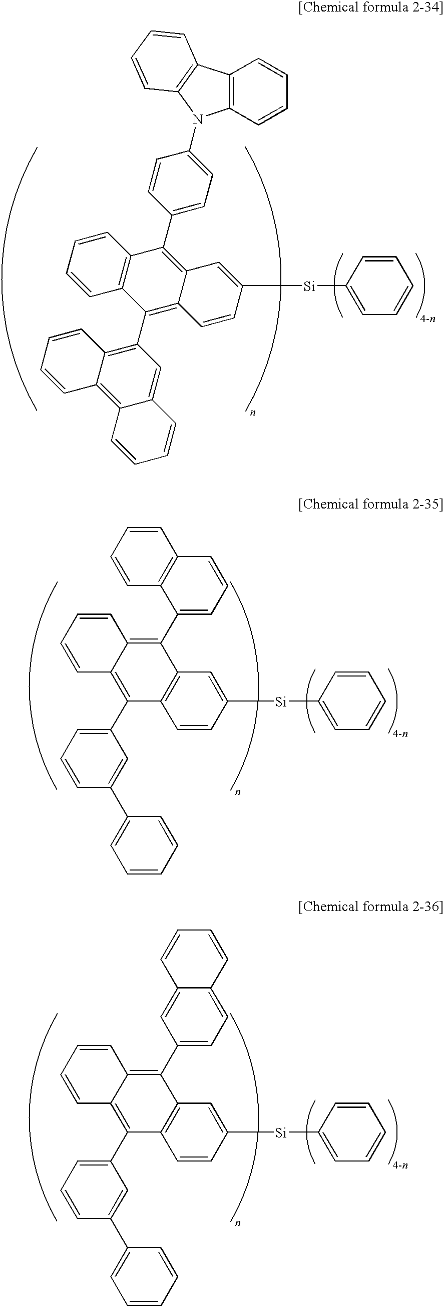

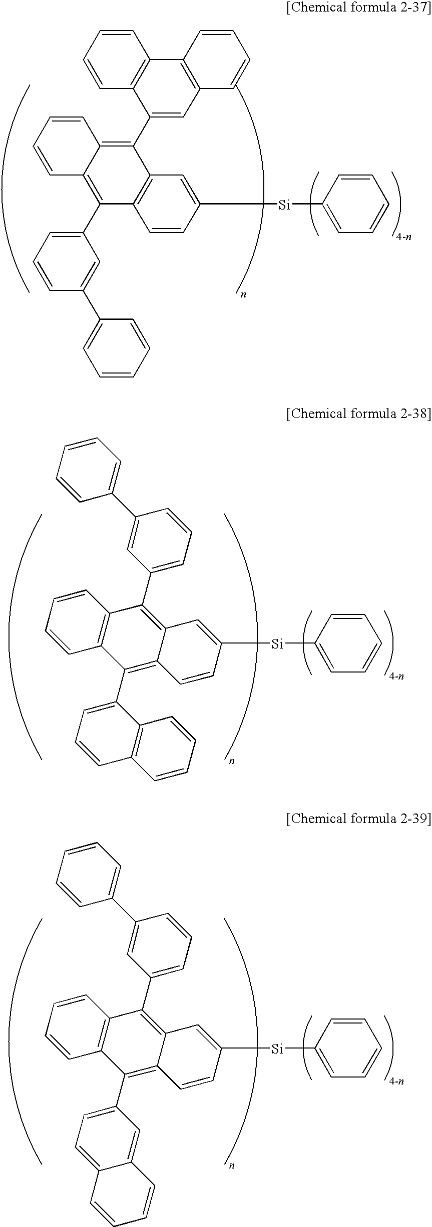

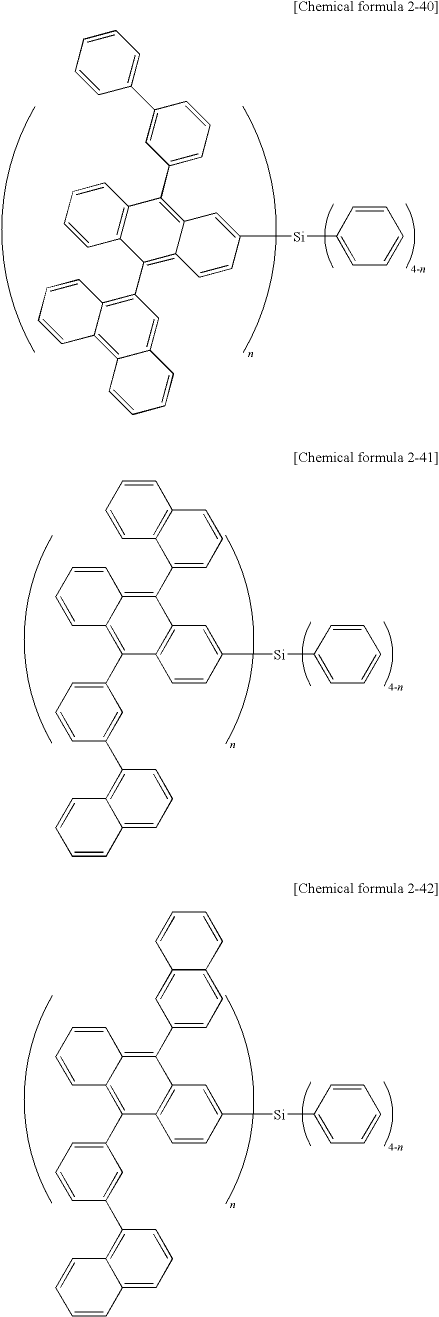

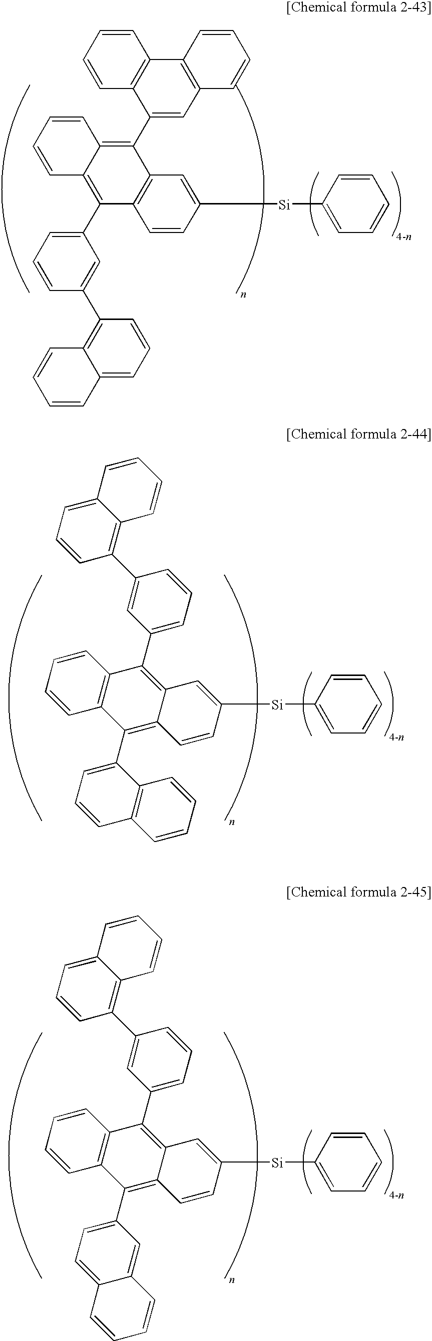

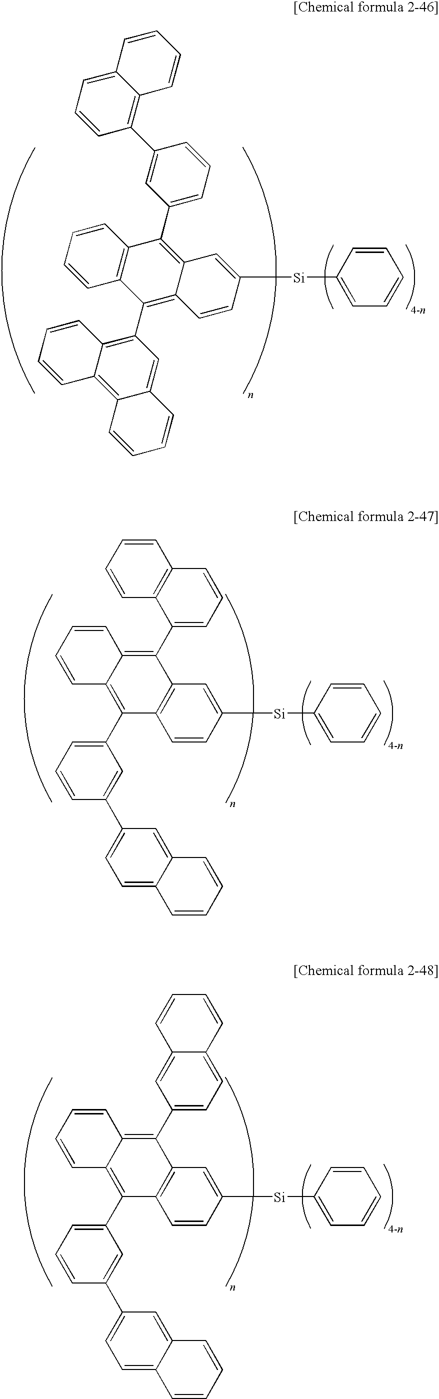

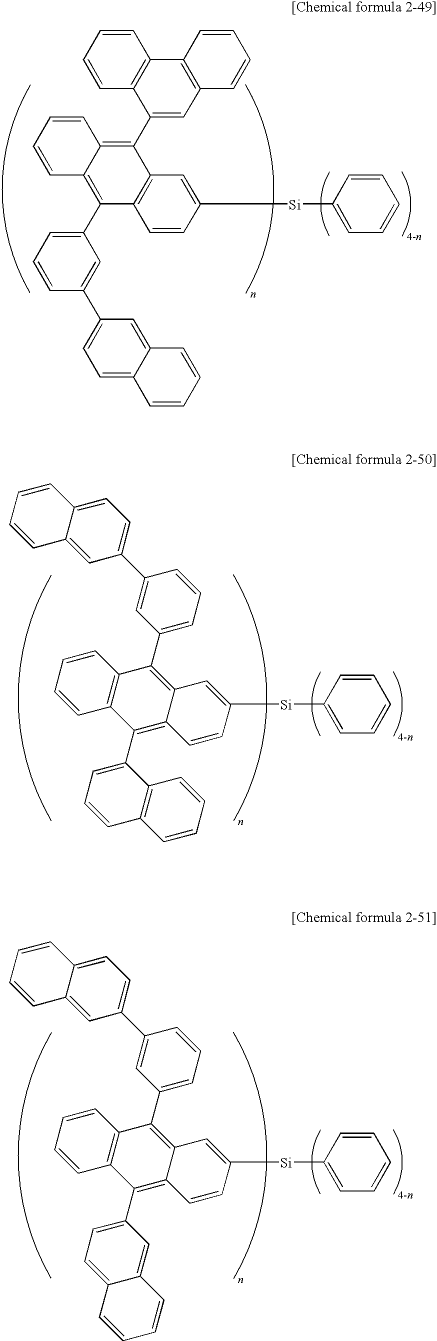

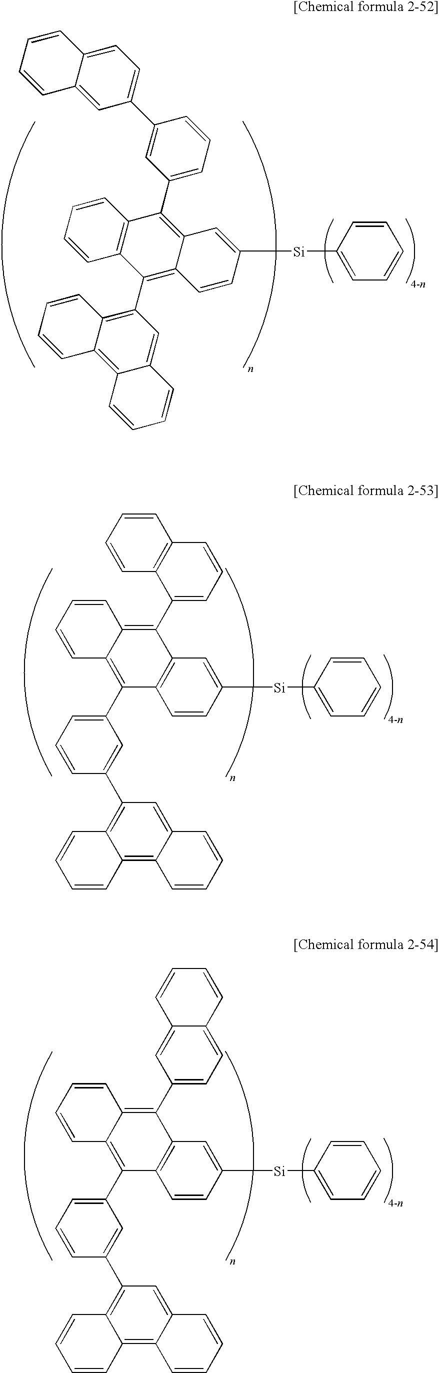

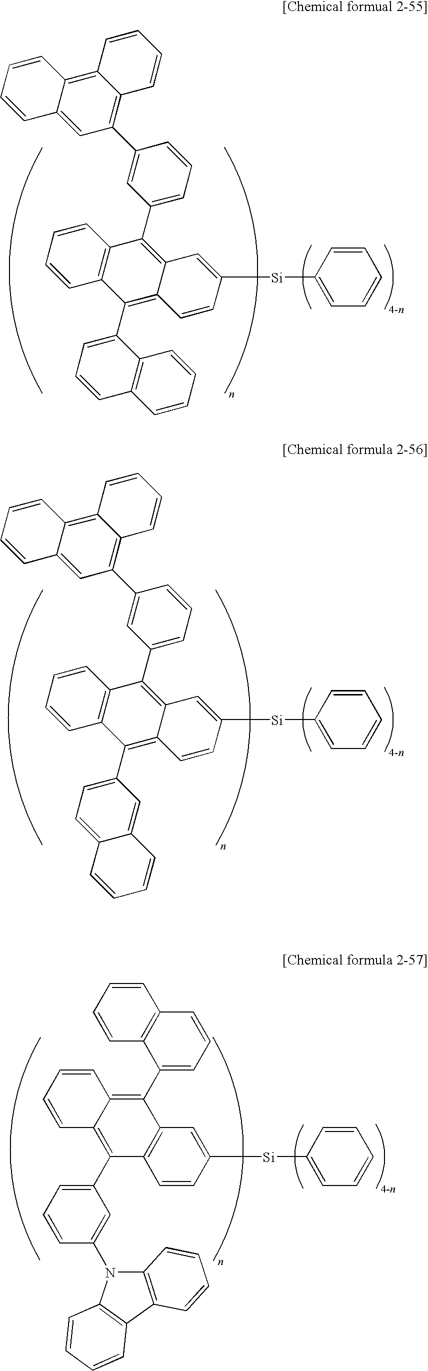

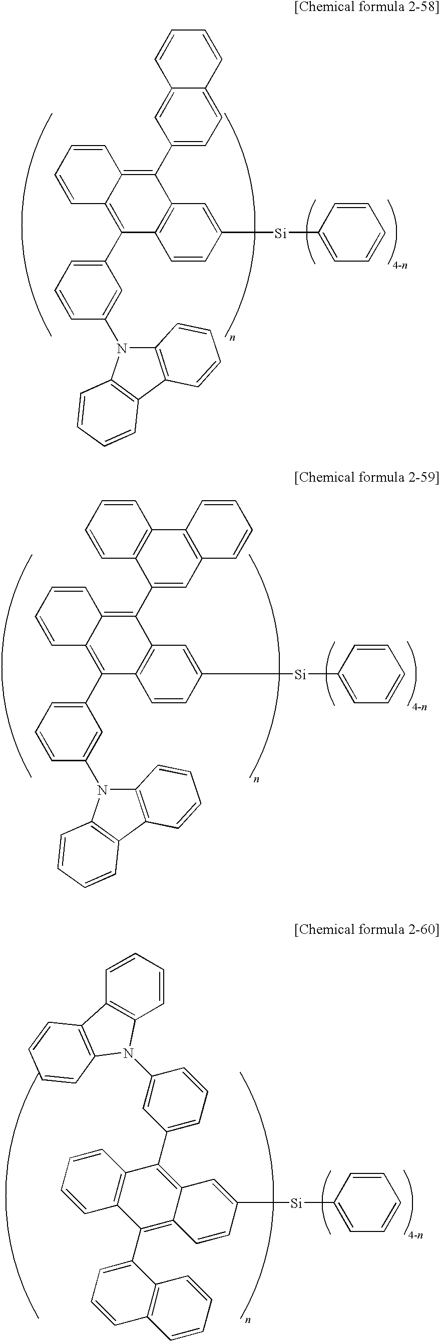

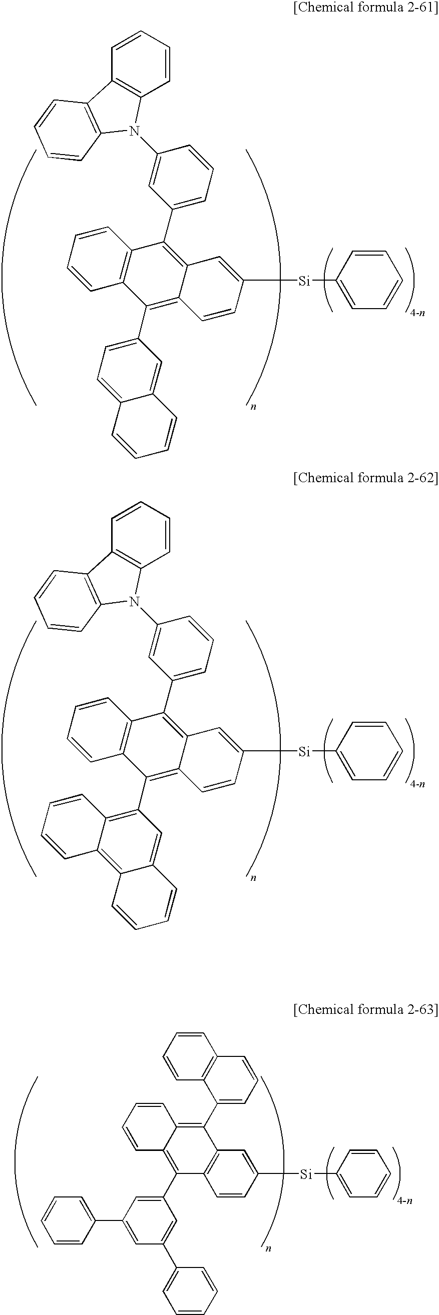

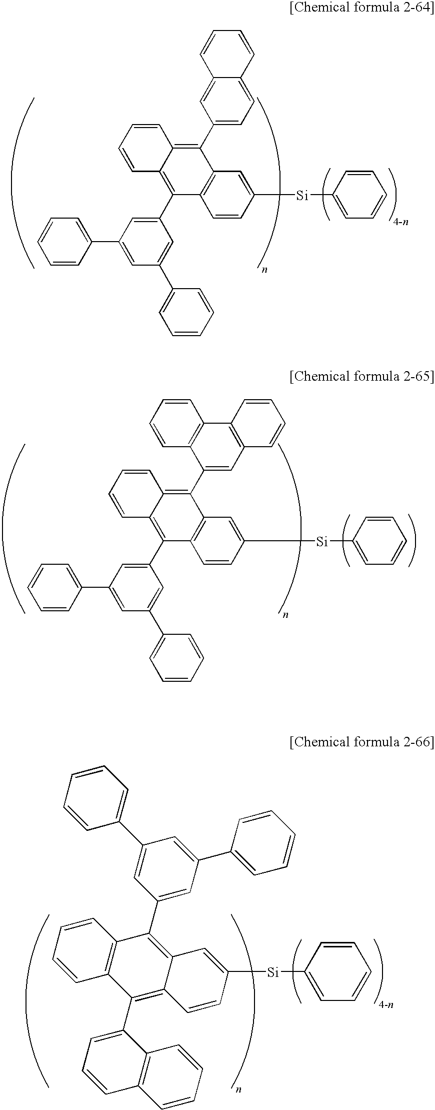

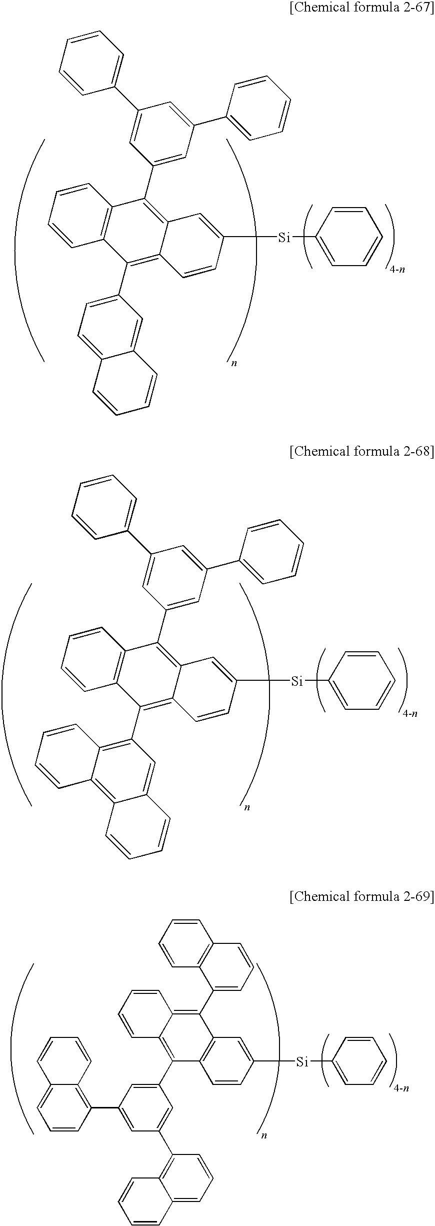

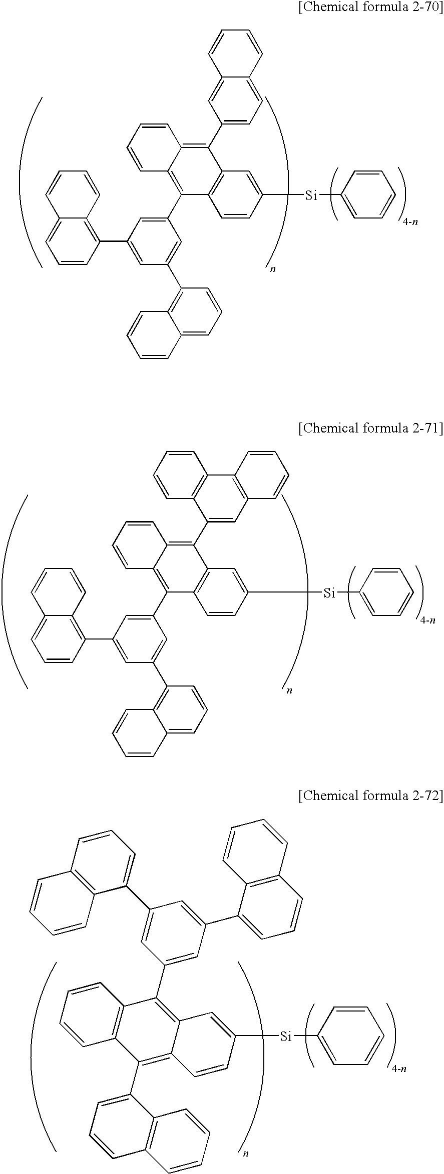

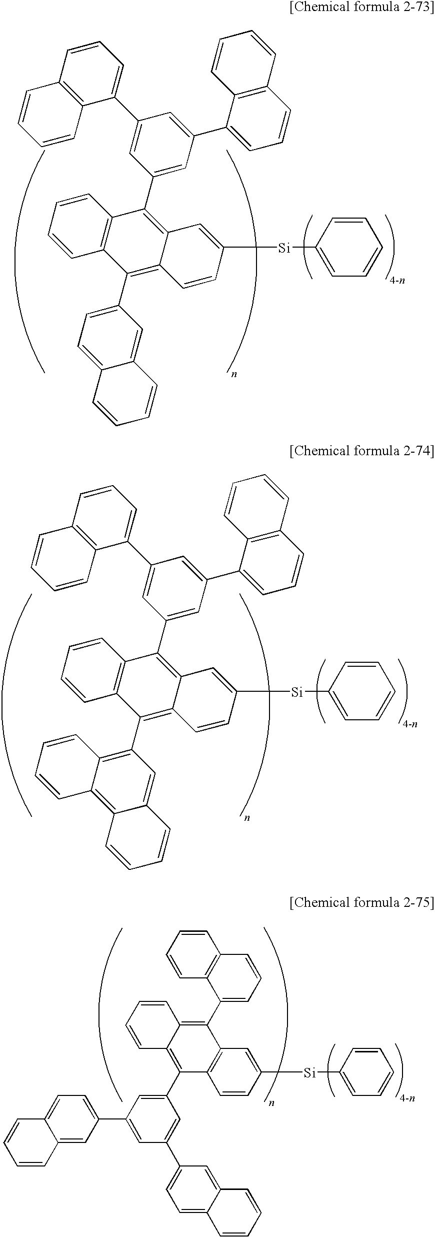

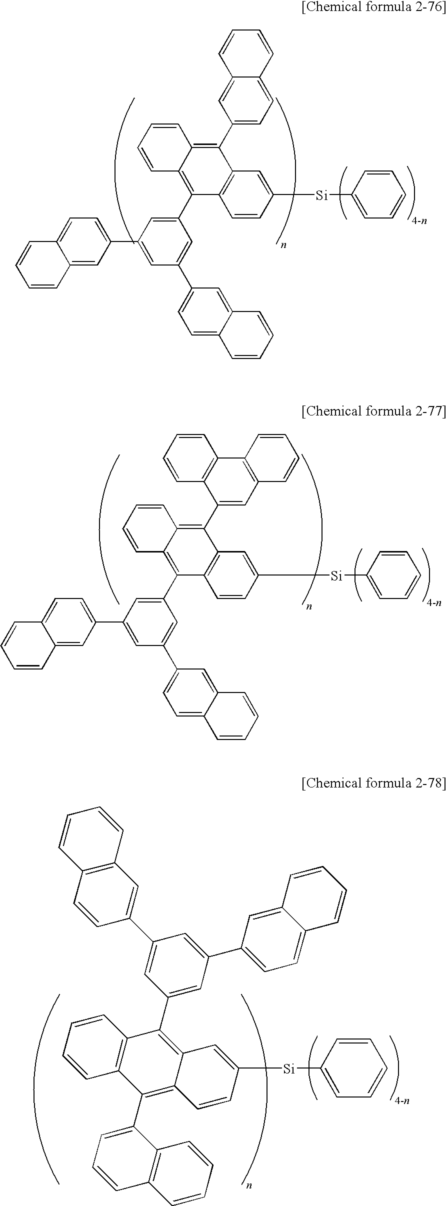

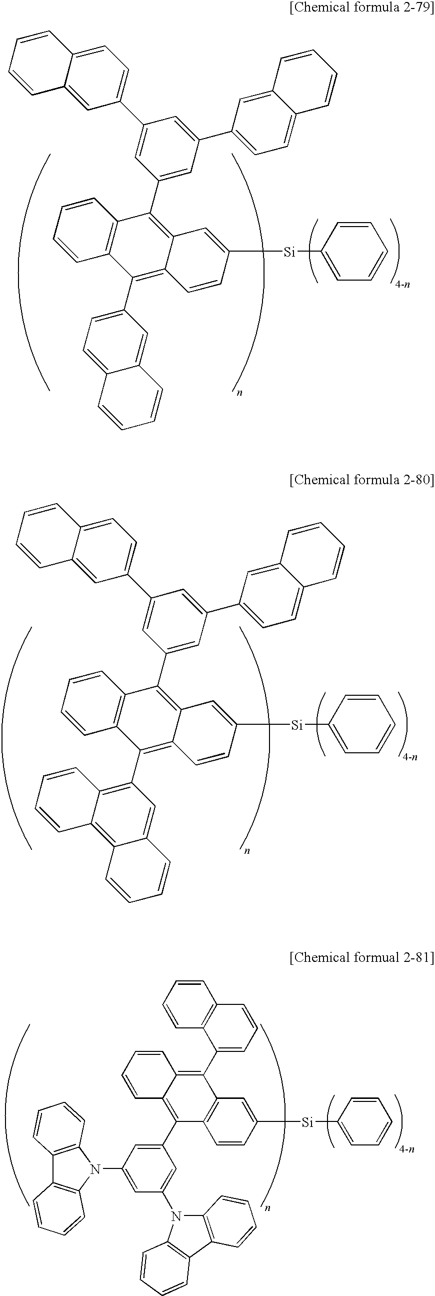

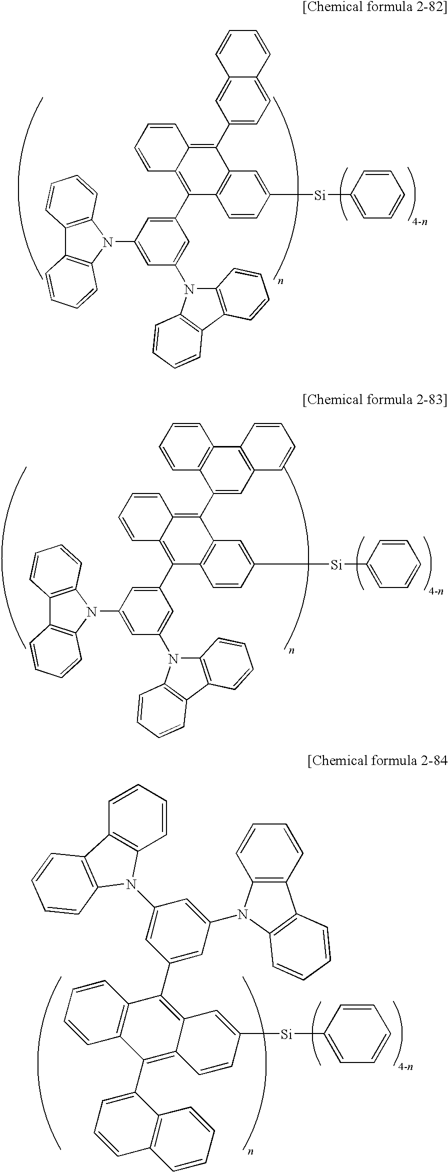

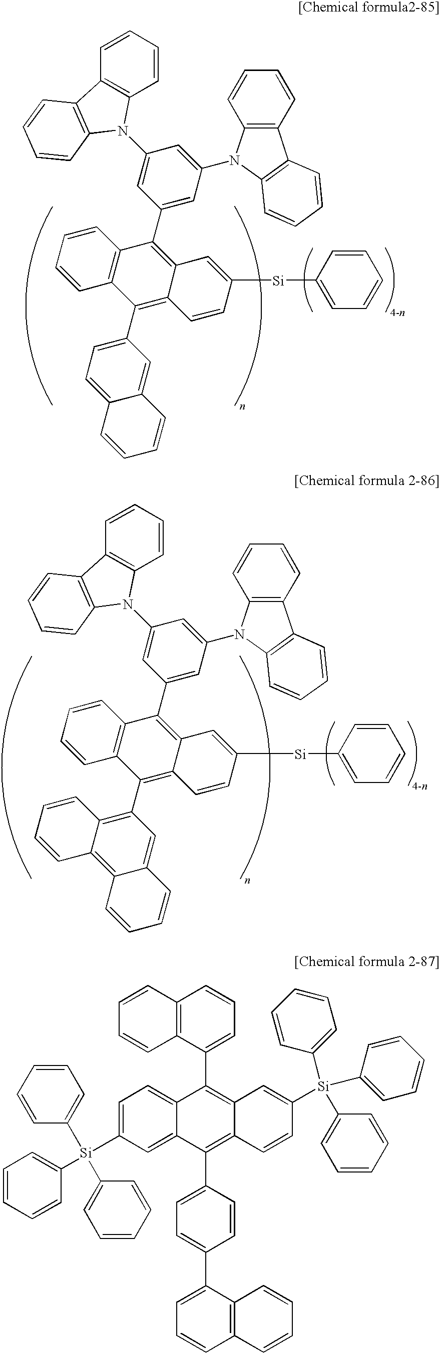

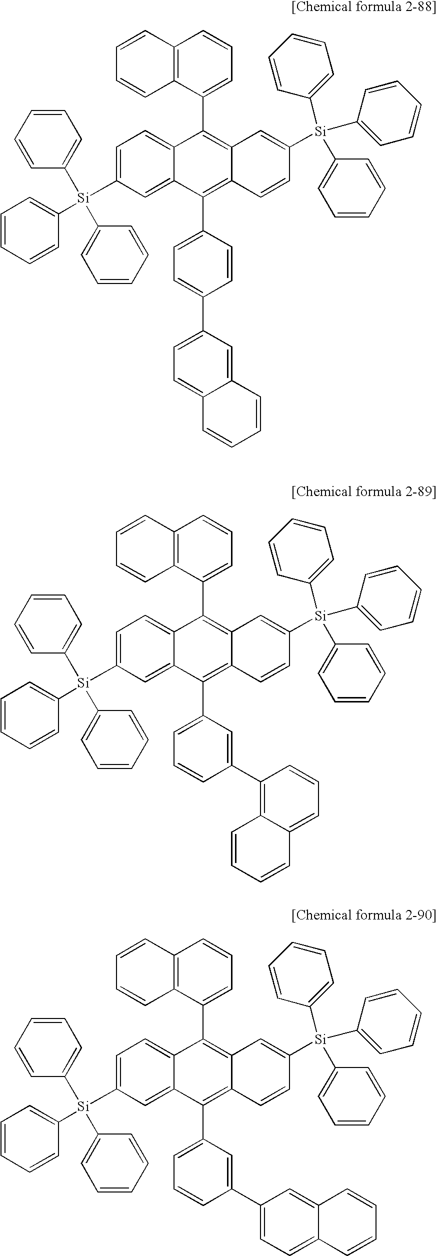

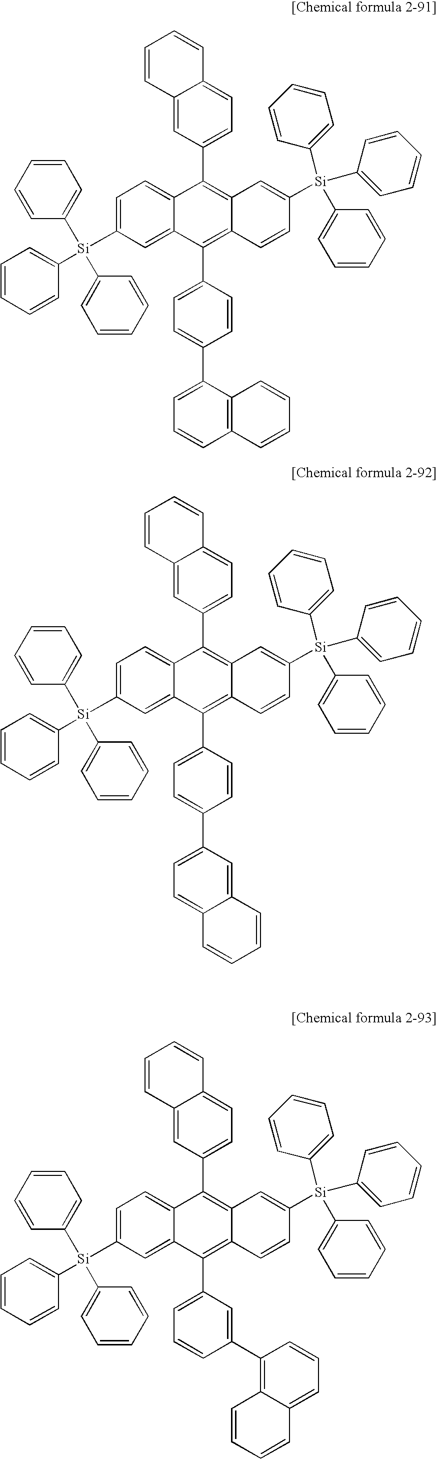

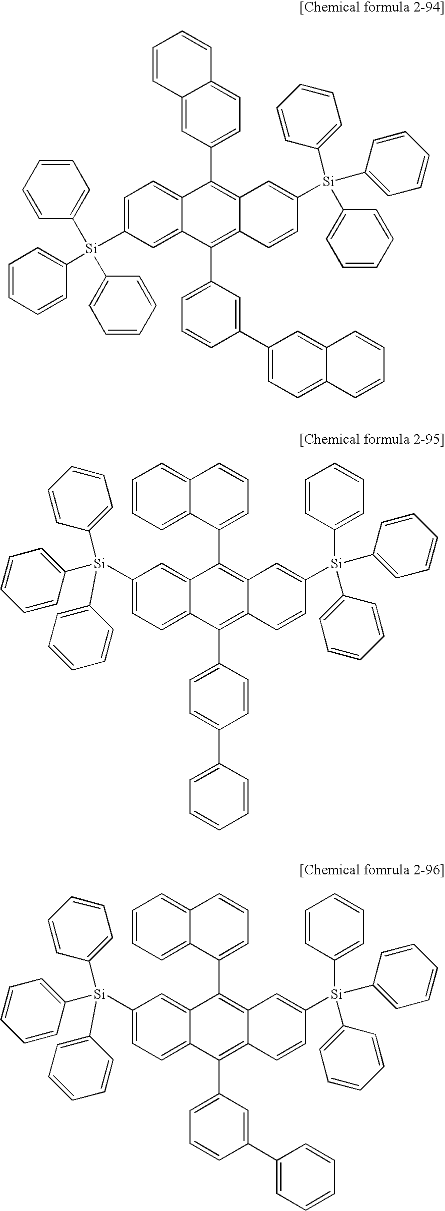

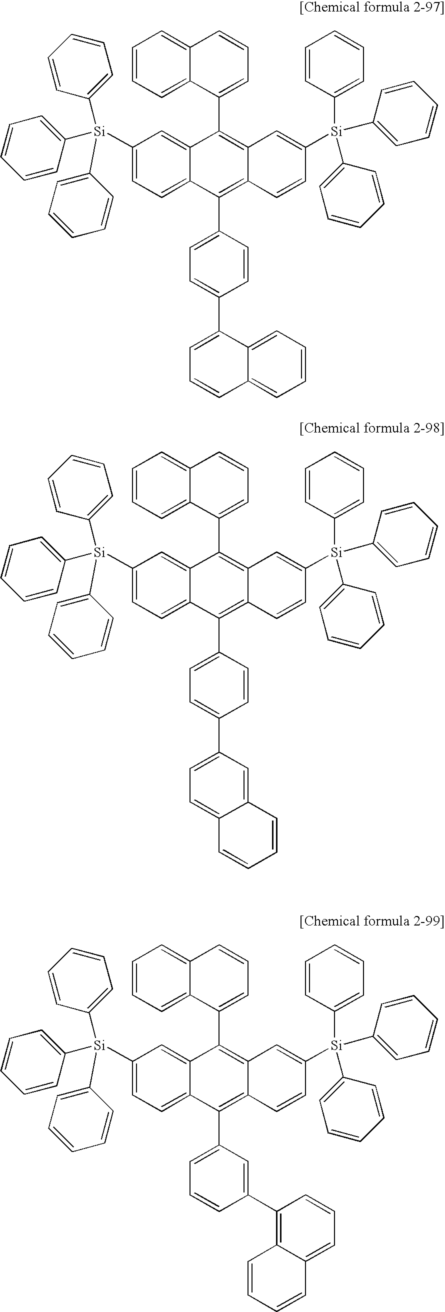

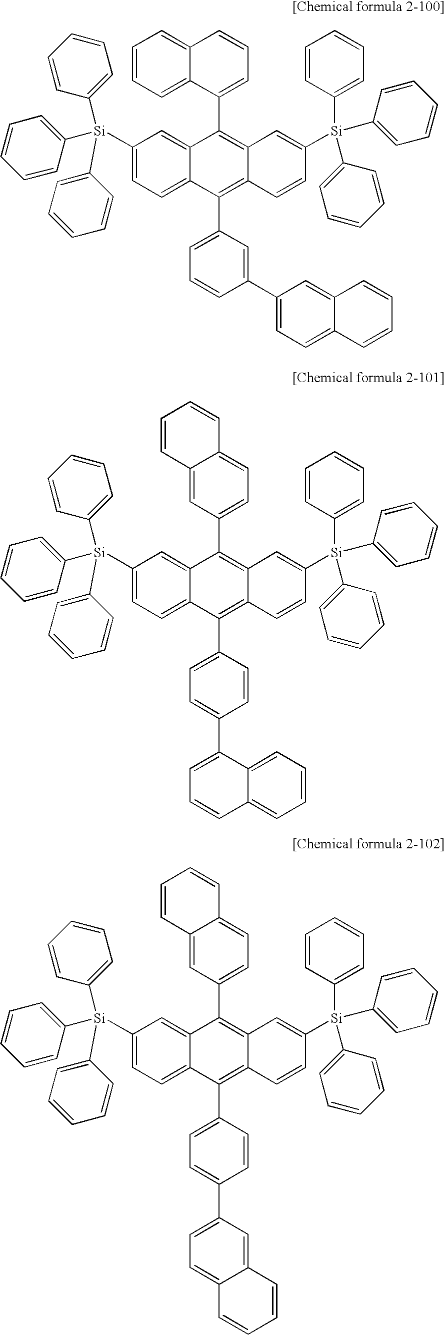

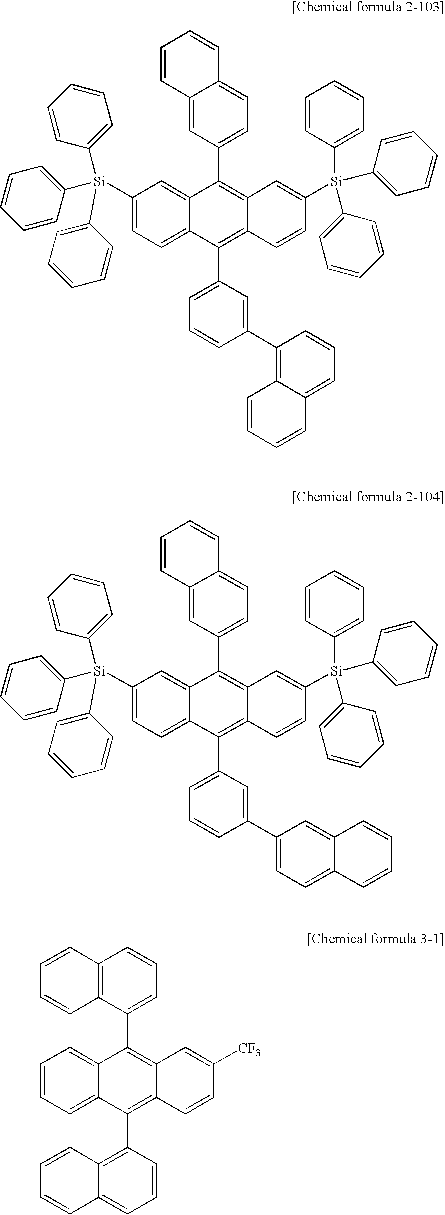

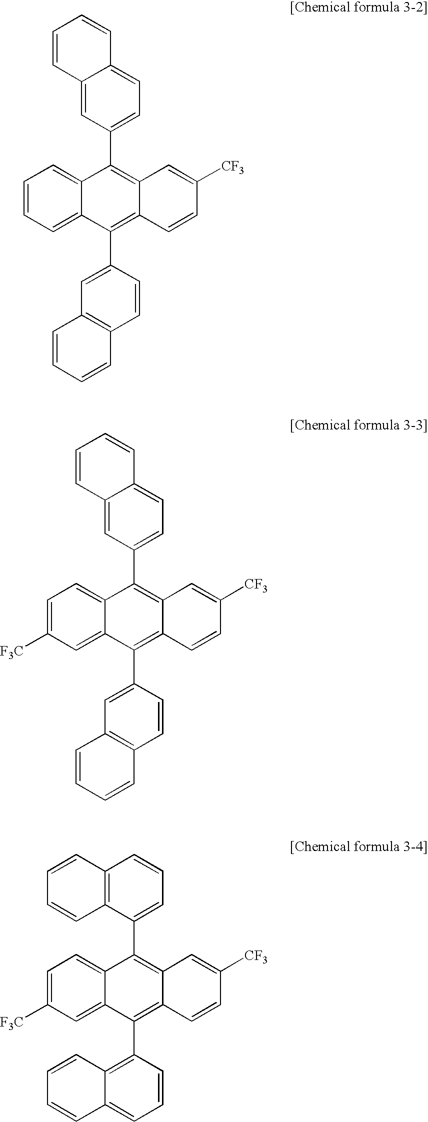

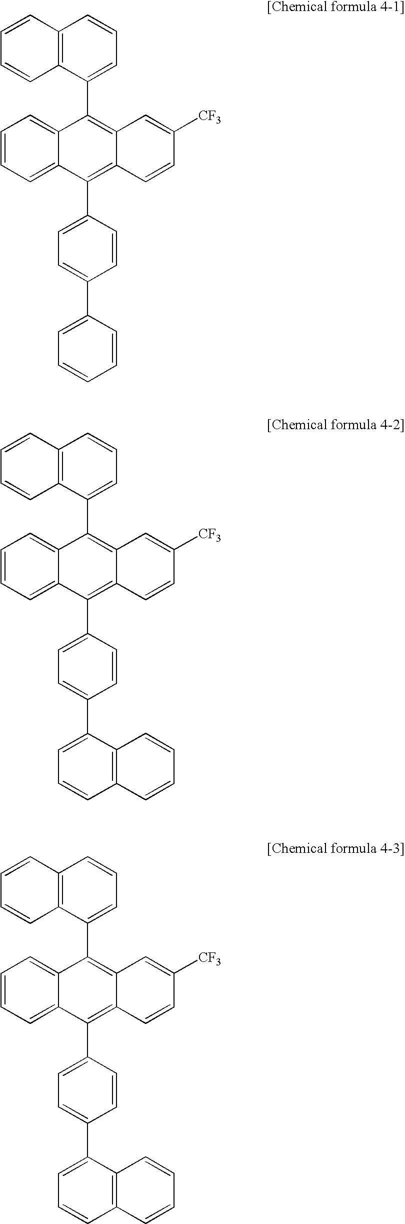

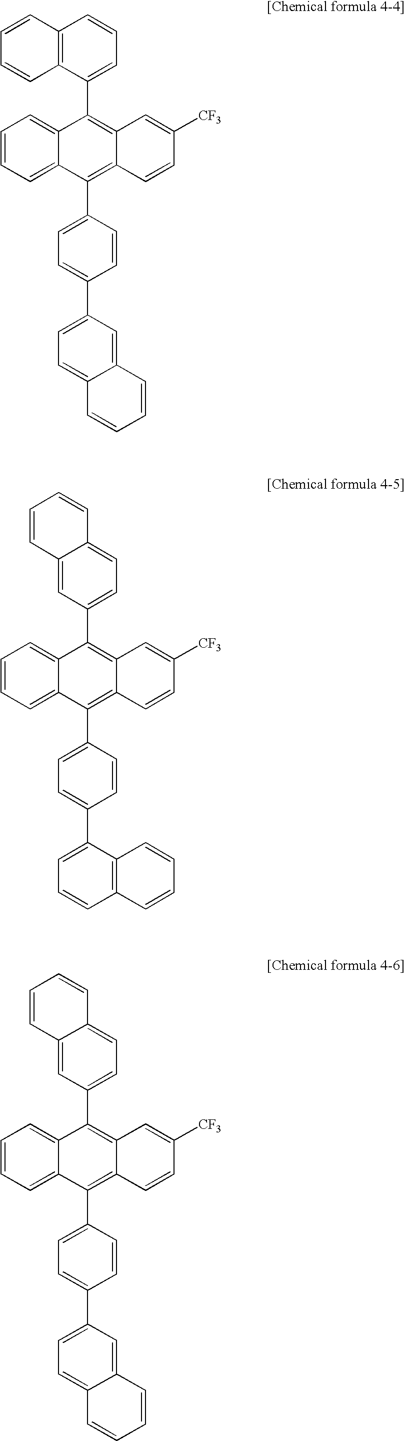

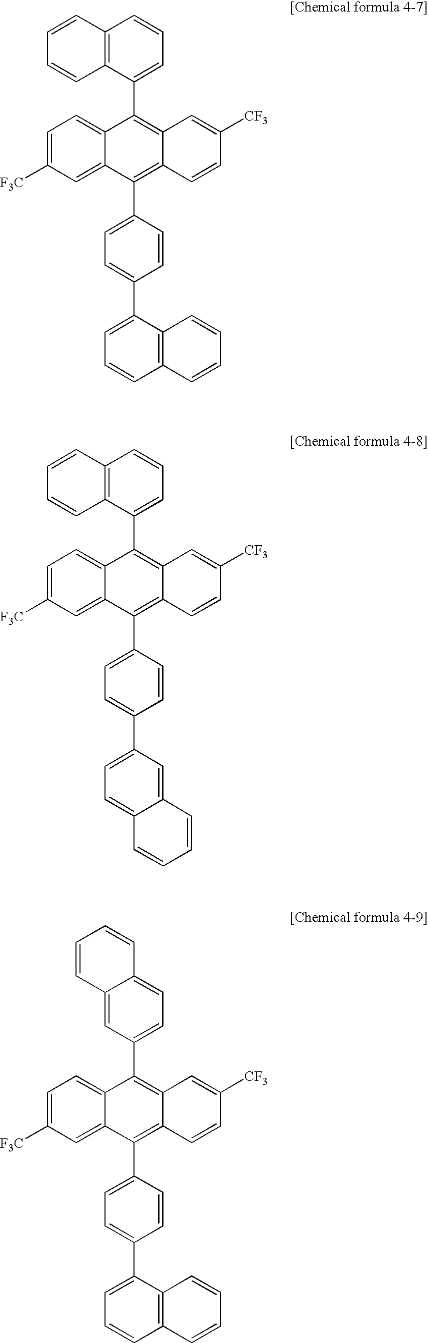

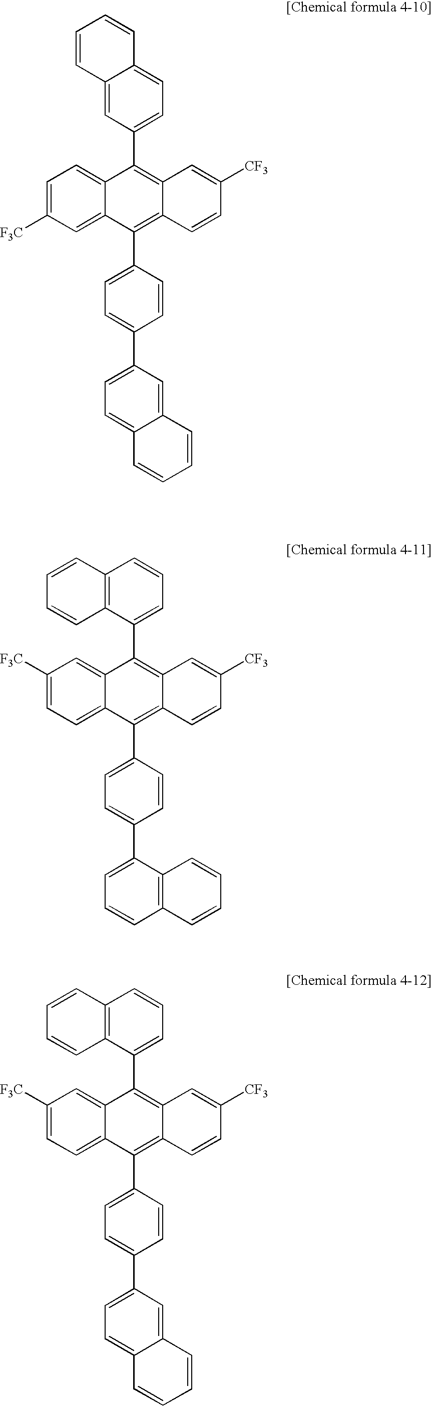

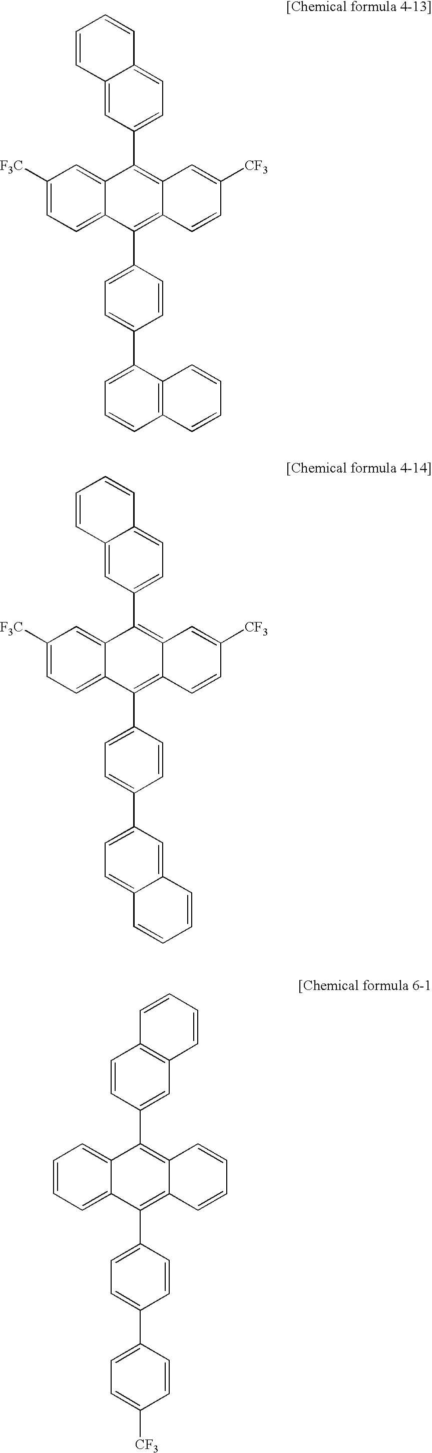

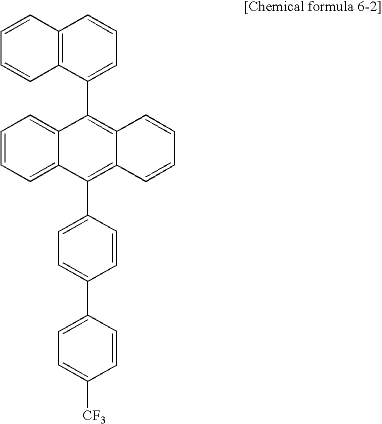

The present invention further provides an organic thin layer of an organic electroluminescent display device formed by one of the chemical formulas 1 to 6 and an organic electroluminescent display device having at least one organic thin layer. Hereinafter, a manufacturing method of the organic electroluminescent display device will be described.

Generally, an organic electroluminescent display device may include at least one organic thin layer such as a hole injecting layer, a hole transporting layer, a light emitting layer, an electron transporting layer and an electron injecting layer between an anode and a cathode.

First, an anode electrode material which has a high work function is deposited on a substrate to form an anode. The substrate may include a substrate used for a typical organic electroluminescent display device, and more particularly, an organic substrate or a transparent plastic substrate which has good mechanical strength, thermal stability, transparency, surface planarization and water proofness and is easy to handle. The anode electrode material may include indium tin oxide (ITO), indium zinc oxide (IZO), SnO₂ or ZnO which is transparent and highly conductive. The anode electrode material may be deposited by a typical anode forming method, and more specifically, by deposition or sputtering.

A hole injecting layer may be formed on the anode electrode by a vacuum deposition, spin coating, cast or LB (Langmuir-Blodgett). Preferably, the hole injecting layer is formed by a vacuum deposition since it may be uniform and hardly have a pin hole. If the hole injecting layer is formed by the vacuum deposition, the deposition condition differs by a compound used as a material for the hole injecting layer and a configuration and a thermal property of the desired hole injecting layer. Generally, however, the deposition condition may be determined within a deposition temperature of 50 to 500° C., vacuum degree of 10⁻⁸ to 10⁻³ torr, a deposition speed of 0.01 to 100 Å/sec and a layer thickness of 10 Å to 5 μm.

The hole injecting layer material may include a phthalocyanine compound such as copper phthalocyanine disclosed in U.S. Pat. No. 4,356,429 or TCTA, m-MTDATA, m-MTDAPB (Advanced Material, 6, p 677 (1994)) as starburst amine derivatives, but not limited thereto.

A hole transporting layer material may be formed on the hole injecting layer by a vacuum deposition, spin coating, cast or LB. Preferably, the hole transporting layer is formed by a vacuum deposition since it may be uniform and hardly have a pin hole. If the hole transporting layer is formed by the vacuum deposition, the deposition condition differs by a compound used. Generally, however, the deposition condition may be almost equivalent to those of the hole injecting layer.

The hole transporting layer material may include a compound represented by the chemical formula 1 or 2 according to the present invention or a typical known material used for the hole transporting layer, but not limited thereto. More specifically, the hole transporting layer may include a carbazole derivative such as N-phenyl carbazole and polyvinylcarbazole, or typical amine derivatives having an aromatic ring such as N,N′-bis(3-methylphenyl)-N,N′-diphenyl-[1,1-biphenyl]-4,4′-diamine (TPD), N,N′-di(naphthalene-1-yl)-N,N′-diphenyl benzidine(α-NPD).

A light emitting layer material may be formed on the hole transporting layer by a vacuum deposition, spin coating, cast or LB. Preferably, the light emitting layer is formed by a vacuum deposition since it may be uniform and hardly have a pin hole. If the light emitting layer is formed by the vacuum deposition, the deposition condition differs by a compound used. Generally, however, the deposition condition may be almost equivalent to those of the hole injecting layer. The light emitting layer material may include a compound represented by the chemical formulas 1 to 6 according to the present invention only or as a host.

If the compound which is represented by the chemical formulas 1 to 6 is used as a light emitting host, a phosphorescent or fluorescent dopant may be used together to form the light emitting layer. The fluorescent dopant may include IDE102 or IDE105 manufactured by Idemitsu. The phosphorescent dopant may include Ir(ppy)3(factris(2-phenylpyridine) iridium) as a green phosphorescent dopant and F2Irpic(iridium(III)bis[4,6-di-fluorophenyl)-pyridinato-N,C2′]picolinate) as a blue phosphorescent dopant, and RD61 as a red phosphorescent dopant manufactured by UDC which may be commonly vacuum deposited (doped). These dopants may be vacuum deposited (doped). A doping density of the dopants may be 0.01 to 15 wt % versus the host of 100 wt %, but not limited thereto.

Preferably, a hole blocking material may be deposited additionally by a vacuum deposition or spin coating to thereby prevent a triplet exiton or hole from being spread to the hole transporting layer. The hole blocking material may be determined among those known in the art, but not limited thereto. For example, the hole blocking material may include an oxadiazole derivative, a triazole derivative, phenanthroline derivative or a hole blocking material disclosed in Japanese Patent First Publication 1999-329734(A1), and representatively, a phenanthrolines compound (e.g., BCP made by UDC).

An electron transporting layer is formed on the light emitting layer by a vacuum deposition, spin coating, cast, etc., and preferably, by a vacuum deposition.

The electron transporting layer material may include e.g., a quinoline derivative, particularly tris(8-quinolinorate)aluminum (Alq3) to stably transport electrons from a cathode, but not limited thereto. An electron injecting layer which is used to inject electrons from a cathode may be formed on the electron transporting layer. The electron injecting layer material may include LiF, NaCl, CsF, Li₂O, BaO, etc.

The deposition condition of the electron transporting layer may differ by a used compound, but preferably be almost equivalent to those of the hole injecting layer.

An electron injecting layer may be formed on the electron transporting layer by a vacuum deposition, spin coating, cast, etc., and particularly, by a vacuum deposition.

A cathode is finally formed on the electron injecting layer by a vacuum deposition or sputtering with a cathode forming metal. The cathode forming metal may include metal, alloy, conductive compound and a mixture thereof which has a low work function. More specifically, the metal may include lithium (Li), magnesium (Mg), aluminum (Al), aluminum-lithium (Al—Li), calcium (Ca), magnesium-indium (Mg—In), magnesium-silver (Mg—Ag), etc. A transmissive cathode with ITO or IZO may be used to achieve a frontal electroluminescent display device.

The organic electroluminescent display device according to the present invention may have various configurations as well as a configuration of anode, hole injecting layer, hole transporting layer, light emitting layer, electron transporting layer, electron injecting layer and cathode. A single or double intermediate layers may be formed as necessary.

The thickness of the organic thin layer formed by the present invention may be adjusted as required. Preferably, the thickness of the organic thin layer is 10 to 1,000 nm, and more preferably 20 to 150 nm.

Hereinafter, exemplary embodiments of the present invention are provided to help understand the present invention. However, the present invention is not limited to following exemplary embodiments.

### Exemplary Embodiment 1

### (1) Synthesis of Compound <1a> (2-bromoanthraquinone)

Copper bromide (CuBr₂) of 18 g (81 mmol) and tert-butyl nitrite of 12 ml (101 mmol) were dispersed by acetonitrile having a temperature of 65° C., and 2-aminoanthraquinone of 15 g (67 mmol) was added while the mixture was vigorously stirred. The mixture was stirred until nitrogen gas was not generated at all and then cooled to room temperatures. After 20% hydrochloric acid of 1 L was added, the mixture was extracted by dichloromethane. An organic layer was dried by sulfur trioxide magnesium, and a solvent was removed from the mixture under reduced pressure. The mixture was purified by silica gel column chromatography to obtain a following compound <1a> of 14 g (75%).

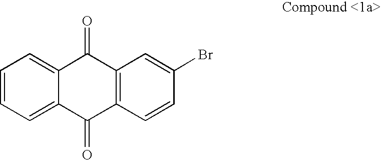

### (2) Compound <1b> Synthesis of (2-bromo-9,10-di-naphthalene-1-yl-9,10-dihydro-anthracene-9,10-diol)

1-bromonaphthalene of 10.5 ml (75.23 mmol) was melted by tetrahydrofuran anhydride of 100 ml to be stirred. After maintaining the temperature at −78° C., 2.5M N-BuLi of 30 ml (75.23 mmol) was dropped slowly. Thirty minutes later, the mixture was mixed with the compound <1a> of 9 g (31.34 mmol) to be stirred at room temperatures. The reaction mixture was cleansed by NH₄Cl two hours later, extracted by dichloromethane, and water was dried by magnesium sulfate anhydride. Then, the solvent was removed from the mixture under reduced pressure. The mixture was cleansed by methanol to obtain a following compound <1b> (7.7 g, 45%).

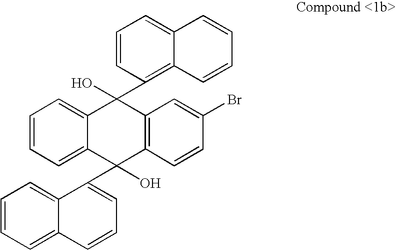

### (3) Synthesis of Compound <1c> (2-bromo-9,10-di-naphthalene-1-yl-anthracene)

The compound <1b> of 7.7 g (14.18 mmol) was melted by glacial acetic acid of 100 ml to be stirred. After potassium iodide (KI) of 23.4 g (141.8 mmol) and sodium hypophosphite (NaPO₂H₂) of 12.4 g (141.8 mmol) were added, the mixture was refluxed. Reactants started being melted and about two hours later, white precipitate was formed. After the reaction was completed, glacial acetic acid was filtered off. The precipitate was stirred by ethanol and added with water. After the formed precipitate was filtered off, a following white solid compound <1c> of 6.6 g (92%) was obtained. Blue light emission (418 nm)

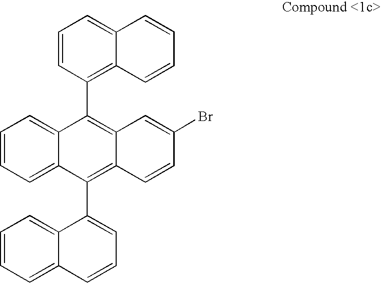

### (4) Synthesis of Compound <1> (2-triphenylsilyl-9,10-dinaphthalen-1-yl-anthracene)

The compound <1c> of 6.6 g (12.9 mmol) was melted by tetrahydrofuran anhydride of 100 ml, stirred and maintained at −78° C. 2.5MN-BuLi of 6.2 ml (15.55 mmol) was slowly dropped. Thirty minutes later, triphenylsilyl chloride of 4.6 g (15.55 mmol) was added to the mixture to be stirred at room temperatures. Two hours later, white precipitate started being formed. After the reaction was completed, the precipitate was filtered off to obtain a white solid compound [Chemical formula 1-1] (5.3 g, 60%).

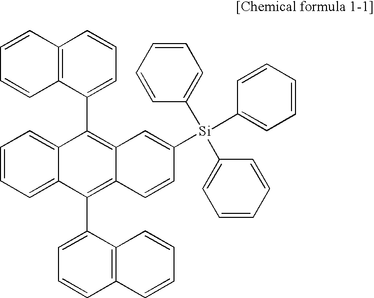

### Exemplary Embodiment 2

### Synthesis of Compound <1-2>

The procedure of the exemplary embodiment 1 was repeated to obtain [chemical formula 1-2] (5.56 g, 63%) except that 2-bromonaphthalene of 15.6 g replaced 1-bromonaphthalene according to the exemplary embodiment 1.

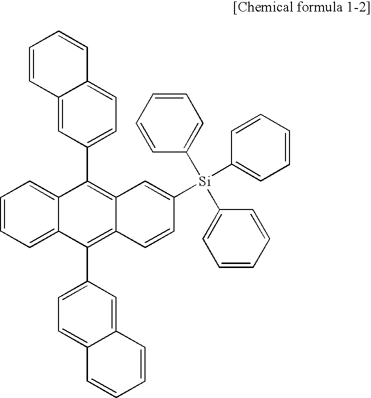

### Exemplary Embodiment 3

### (1) Synthesis of Compound <2a>

The compound <1a> of 5.77 g (20.1 mmol), tinchloride (SnCl₂.H₂O) of 13.90 g (61.5 mmol) and 12M hydrochloric acid aqueous solution of 15 ml were melted by acetic acid of 90 ml to be refluxed. The mixture was cooled five hours later, diluted by water, and neutralized by sodium hydrogen carbonate aqueous solution. After the mixture was extracted by dichloromethane, water was dried by magnesium sulfate anhydride. After the solvent was removed from the mixture under reduced pressure, the solid was purified by column chromatography to obtain a compound <2a> of 2.18 g (yield 38%).

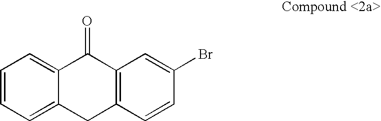

### (2) Synthesis of Compound 2b

2-bromonaphthalene of 1.8 g (8.79 mmol) was melted by tetrahydrofuran anhydride of 100 ml, stirred and maintained at −78° C. Then, 2.5M N-BuLi of 3.5 ml (8.79 mmol) was slowly dropped. Thirty minutes later, the compound <2a> of 2 g (7.32 mmol) was added to stir the mixture at room temperature. Twelve hours later, 6M HCl solution was added to stir the mixture. After being extracted by dichloromethane, water was dried by magnesium sulfate anhydride and the solvent was removed from the mixture under reduced pressure. The mixture was cleansed by ethanol to obtain a following compound <2b> of 1.68 g (60%).

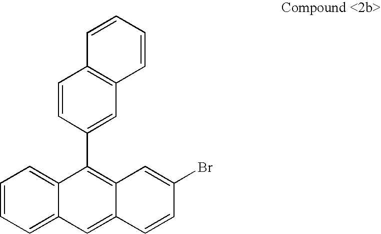

### (3) Synthesis of Compound <2c>

The compound <2b> of 1.68 g (4.39 mmol) was melted by tetrahydrofuran anhydride of 20 ml, stirred and maintained at −78° C. Then, 2.5M N-BuLi of 1.8 ml (4.39 mmol) was slowly dropped. Thirty minutes later, triphenylsilyl chloride of 1.6 g (5.27 mmol) was added to stir the mixture at room temperatures. Two hours later, white precipitate started being formed. After the reaction was completed, the precipitate was filtered off to obtain a white solid compound <2c> of 1.48 g (60%).

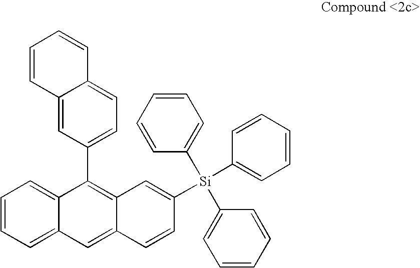

### (4) Synthesis of Compound <2d>

The compound <2c> of 1.48 g (2.63 mmol) was melted by dichloromethane of 50 mL under nitrogen atmosphere, and added with N.B.S of 0.6 g (3.42 mmol) which was melted by 25 mL dichloromethane at 5° C. and below. After the mixture was stirred for about 30 minutes, it was stirred again at room temperatures. The progress of the reaction was verified by TLC. If the reaction did not continue anymore, sodiumthiosulfate saturated aqueous solution of 20 mL was added. The organic solvent layer was set aside to be dehydrated by MgSO₄ and distilled under reduced pressure. The obtained reaction mixture was separated by a column filled with silica gel by using a mixture solvent of methylene chloride and n-hexane as a mobile phase to thereby form a light yellow crystal compound <2d> of 1.06 g (63%).

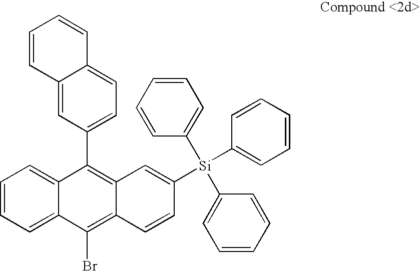

### (5) Synthesis of Compound 2-1

Under nitrogen atmosphere, 4-biphenylboronic acid of 0.39 g (1.98 mmol) and the compound <2d> of 1.0 g (1.65 mmol), Pd (PP₃)₄, 2M K₂CO₃ aqueous solution and toluene of 50 mL were vigorously stirred and refluxed. H₂O of 10 mL was added 12 hours later, and the formed precipitate was filtered off to obtain white solid [Chemical formula 2-1] of 8 g (68%).

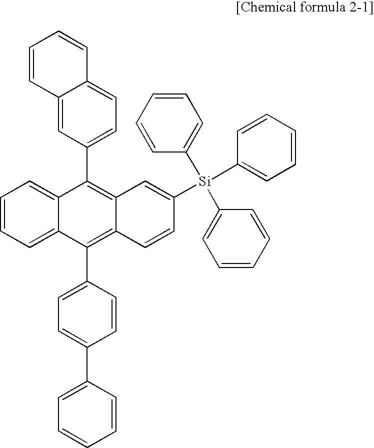

### Exemplary Embodiment 4

### (1) Synthesis of Compound 2-42

The procedure of the exemplary embodiment 3 was repeated to obtain [Chemical formula 2-42] (1.2 g, 63%) except that 3-(naphthalene-1-yl)phenylboronic replaced 4-biphenylboronic acid according to the exemplary embodiment 3.

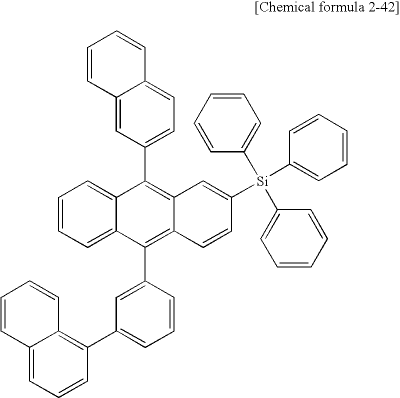

### Exemplary Embodiment 5

### (1) Synthesis of Compound 1-3

The procedure of the exemplary embodiment 1 was repeated to obtain [Chemical formula 1-3] (1.2 g, 42%) except that 2,6-diaminoanthraquinone replaced 2-aminoanthraquinone.

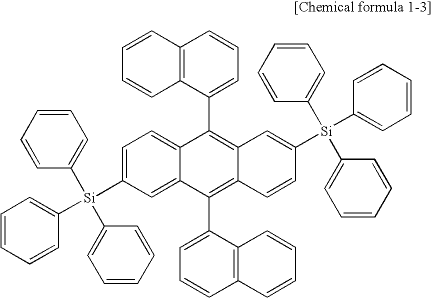

### Exemplary Embodiment 6

### (1) Synthesis of compound 1-4

The procedure of the exemplary embodiment 2 was repeated to obtain [Chemical formula 1-4] (1.42 g, 50%) except that 2,6-diaminoanthraquinone replaced 2-aminoanthraquinone.

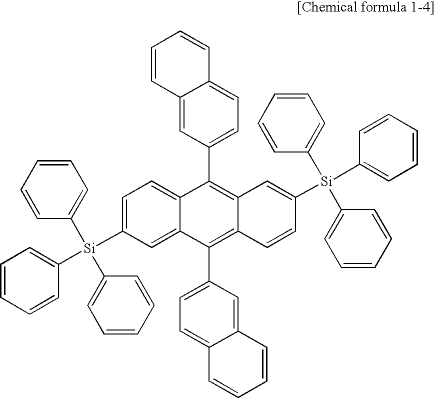

### Exemplary Embodiment 7

### (1) Synthesis of Compound 2-7

The procedure of the exemplary embodiment 3 was repeated to obtain

[Chemical formula 2-7] (0.8 g, 35%) except that 2,6-dibromoanthraquinone replaced the compound <1a> according to the exemplary embodiment 3.

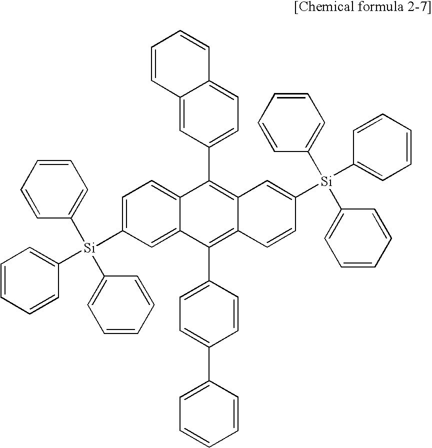

### Exemplary Embodiment 8

### (1) Synthesis of Compound 2-93

The procedure of the exemplary embodiment 4 was repeated to obtain [Chemical formula 2-93] (0.5 g, 30%) except that 2,6-dibromoanthraquinone replaced the compound <1a> according to the exemplary embodiment 4.

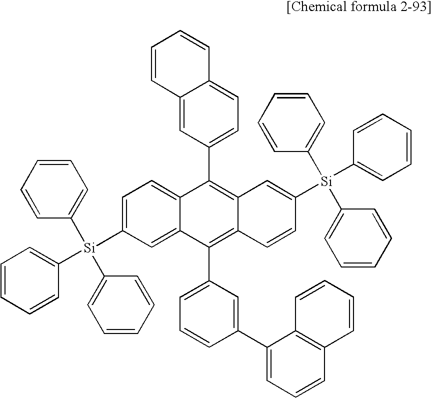

### Exemplary Embodiment 9

### (1) Synthesis of Compound <6a>

Under nitrogen atmosphere, 2-bromonaphthalene of 20 g (96.6 mmol) was melted by THF of 500 mL and cooled for 30 minutes at −78° C. After n-BuLi (2.5M) of 39 mL was slowly dropped for 30 minutes at −78° C., the mixture was stirred for another 30 minutes. The reaction mixture was added with anthrone of 16.5 g (85 mmol), which was melted by THF of 300 mL, for 15 minutes and then stirred at room temperatures 20 minutes later. The progress of the reaction was verified by TLC. If the reaction did not continue anymore, the reaction mixture was added with 6M HCl of 300 mL and then extracted three times by using ethyl acetate of 200 mL. The extracted mixtures were mixed together, and water was removed from the mixtures with MgSO₄ to distill the mixture under reduced pressure. The reactant was recrystallized with ethanol to obtain light green crystal 9-naphthalene-2-yl anthracene of 16.48 g (63.6%).

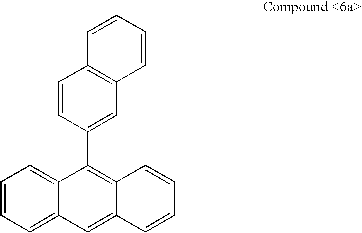

### (2) Synthesis of Compound <6b>

Under nitrogen atmosphere, 9-naphthalene-2-yl anthracene of 16.4 g (54.0 mmol) was melted by methylene chloride of 1050 mL and slowly added with N.B.S of 12.45 g (70 mmol) which was melted by methylene chloride of 550 mL at 5° C. and less. After being stirred for around 30 minutes, the mixture was stirred at room temperatures. The progress of the reaction was verified by TLC. It the reaction did not continue anymore, saturated sodium thiosulfate of 400 mL was added to the reaction mixture. The organic solvent layer was set aside to be dehydrated by MgSO₄ and then distilled under reduced pressure. The obtained reactant was separated in a column filled with silica gel by using a mixture solvent of methylene chloride and n-hexane as a mobile phase to obtain light yellow crystal 9-bromo-10-naphthalene-2-yl anthracene of 12 g (58%).

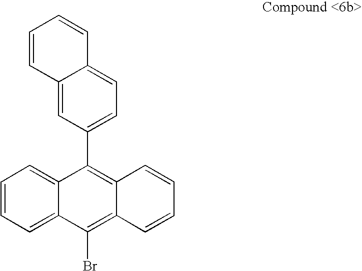

### (3) Synthesis of Compound <6c>

Under nitrogen atmosphere, 9-bromo-10-naphthalene-2-ylanthracene of 12 g (31.3 mmol) was melted by THF of 160 mL and then cooled for 30 minutes at −78° C. After n-BuLi (2.5M) of 13.8 mL was slowly dropped for 30 minutes at −78° C., the mixture was stirred for 30 minutes. After trimethyl borate of 4.2 mL (37.6 mmol) was dropped for 15 minutes, the mixture was stirred at room temperatures 20 minutes later. The progress of the reaction was verified by TLC. If the reaction did not continue anymore, the reaction mixture was added with 2M HCl of 100 mL and then extracted three times with ethyl acetate of 60 mL. After the extracted mixtures were mixed together, water was removed therefrom with MgSO₄ to distill the mixture under reduced pressure. The reactant was recrystallized by toluene and n-hexane to obtain white crystal of 5.3 g (49%).

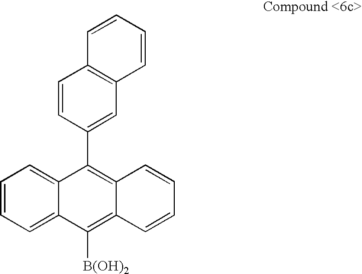

### (4) Synthesis of Compound <6d>

The synthesis procedure of the compound 6c was repeated to obtain a compound <6d> (8 g, 73%) except that 1-bromo-4-(trifluoromethyl)benzene replaced the compound <6d>.

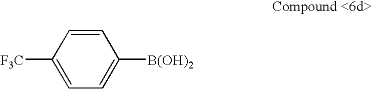

### (5) Synthesis of Compound <6e>

The procedure of the exemplary embodiments 3 to 5 was repeated to obtain a compound <5e> (5.7 g, 63%) except that the compound <6d> and 4-bromoiodobenzen replaced 4-biphenylboronic acid and the compound <2d>, respectively.

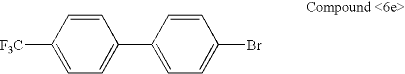

### (6) Synthesis of Compound 6-1

The procedure of the exemplary embodiments 3 to 5 was repeated to obtain a compound 6-1 (2.2 g, 57%) except that the compound <6c> and compound <6e> replaced 4-biphenylboronic acid and the compound <2d>, respectively.

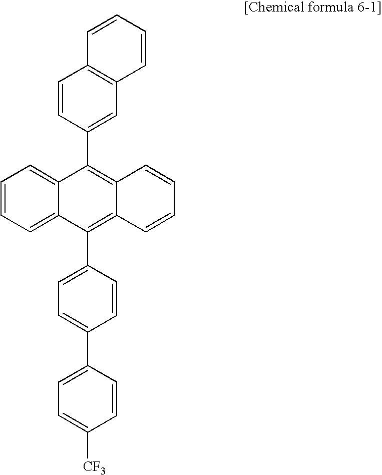

### Experiment Example

### Measurement of Light Emitting Peak

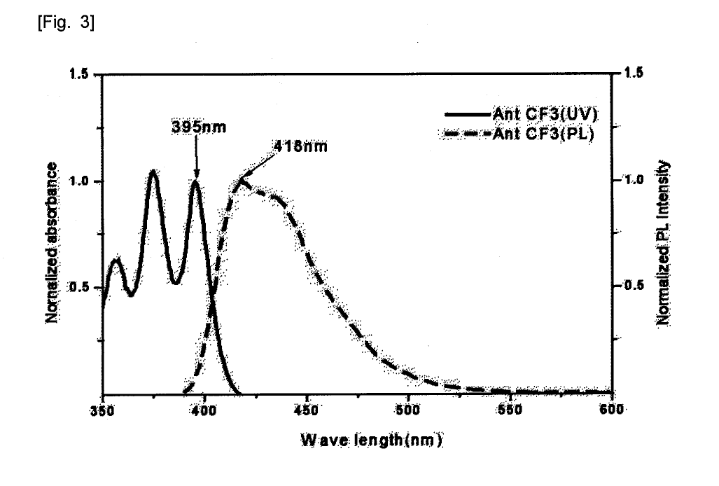

The compounds which were made according to the exemplary embodiments 1 to 9 were dissolved by THF to measure a light emitting peak. The result is shown in FIG. 2 (exemplary embodiment 1), FIG. 3 (exemplary embodiment 9) and Table 1 below. The unit in Table 1 is nm.

TABLE 1

| | Ex. | Ex. | Ex. | Ex. | Ex. | Ex. | Ex. | Ex. | Ex. |
|---|---|---|---|---|---|---|---|---|---|
| | Embod. 1 | Embod. 2 | Embod. 3 | Embod. 4 | Embod. 5 | Embod. 6 | Embod. 7 | Embod. 8 | Embod. 9 |
| Light | 418 | 420 | 417 | 423 | 434 | 434 | 428 | 436 | 418 |
| Emitting | | | | | | | | | |
| Peak (nm) | | | | | | | | | |

As shown in Table 1, FIGS. 2 and 3, the compounds according to the exemplary embodiments 1 to 9 of the present invention have good blue light emission.

### Measurement of Physical Property of Organic Electroluminescent Display Device

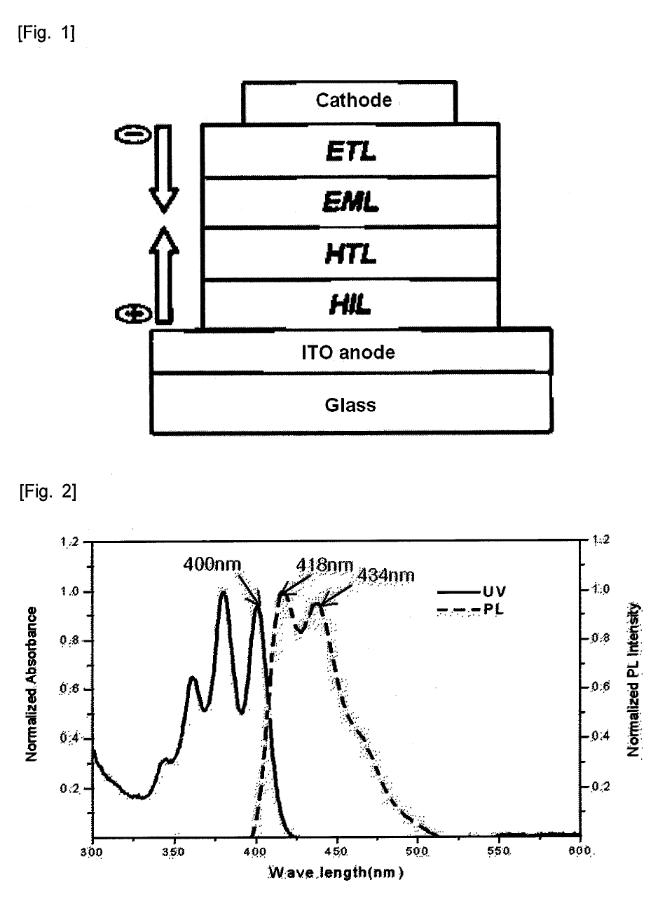

The compounds which were made according to the exemplary embodiments 1 to 9 were used as a light emitting host to manufacture an organic electroluminescent display device as in FIG. 1. Following layers were sequentially formed on a 1500 Å ITO layer (anode) formed on a glass substrate: a 650 Å hole injecting layer (hole injecting material: HI-406 (N¹,N¹-(biphenyl-4,4′-diyl)bis(N¹-(naphthalene-1-yl)-N⁴,N⁴-diphenylbenzene-1,4-diamine)); a 200 Å hole transporting layer (a hole transporting layer material: bis(N-(1-naphthyl-n-phenyl))benzidine(α-NPB)); a 350 Å light emitting layer doped with BD142 (BD142: N⁶,N¹²-bis(3,4-dimethylphenyl)-N⁶,N¹²-dimesitylchrysene-6,12-diamine); a 200 Å electron transporting layer (electron transporting layer material: ET4 (6,6′-(3,4-dimesityl-1,1-dimethyl-1H-silole-2,5-diyl)di-2,2′-bipyridine)) and a 1000/10 Å aluminum/LiF cathode to manufacture an organic electroluminescent display device. The amount of the dopant BD142 used for the light emitting layer was 7 wt % versus a host of 100 wt %.

According to the measuring result of the organic electroluminescent display device, the device provides good electrical stability, light emitting efficiency and brightness. Table 2 shows a measuring result of the compound according to the exemplary embodiment 1.

TABLE 2

| Doping | | | | | | | |
|---|---|---|---|---|---|---|---|
| Amount | | | | | | | |
| (wt. part) | Volt(V) | Cd/A | Im/A | Q.E(%) | CD/m2 | CIEx | CIEy |
| 7 | 5.32 | 6.73 | 3.79 | 4.89 | 1345 | 0.134 | 0.2044 |

Although a few exemplary embodiments of the present invention have been shown and described, it will be appreciated by those skilled in the art that changes may be made in these exemplary embodiments without departing from the principles and spirit of the invention, the scope of which is defined in the appended claims and their equivalents.

### INDUSTRIAL APPLICABILITY

An anthracene type compound which is represented by chemical formulas 1 to 6 according to the present invention provides good blue light emitting property and hole transporting property, is used as a blue light emitting material or a host for various phosphorescent or fluorescent dopants such as red, green, blue and white colors, is applicable to an organic electroluminescent display device for high efficiency, low voltage, high brightness and long lifetime.

1. A compound which is represented by one of following chemical formulas 1 to 6: 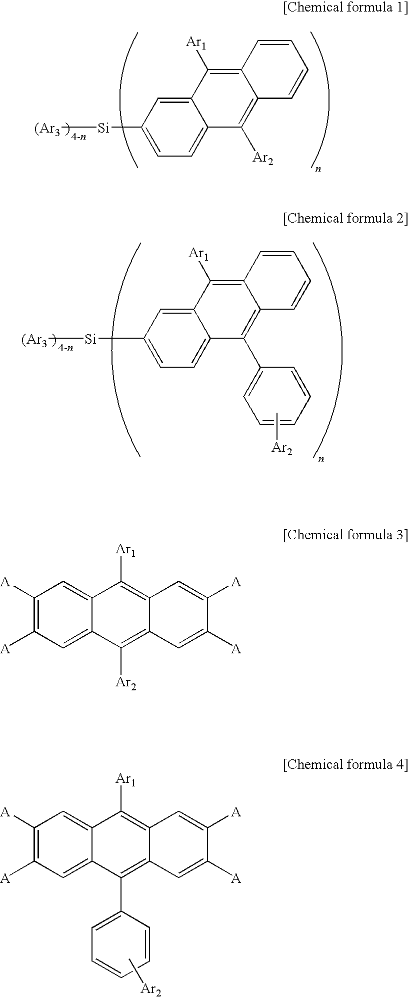
wherein, Ar₁, Ar₂ and Ar₃ are a substituted or unsubstituted aryl group, independently, n is a positive number from 1 to 4, A is hydrogen, CF₃ or a substituted or unsubstituted triarylsilyl group, and at least one of A is CF₃ or a substituted or unsubstituted triarylsilyl group, 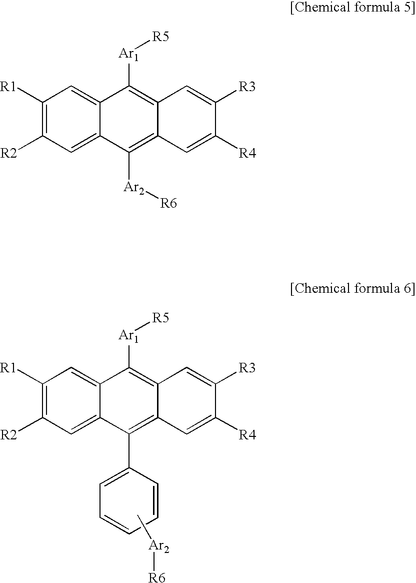
wherein, Ar₁ and Ar₂ are a substituted or unsubstituted aryl group, independently, R₁ to R₆ are hydrogen or CF₃, independently, and at least one of R₁ to R₆ is CF₃.

2. The compound according to claim 2, which is one of compounds represented by following chemical formulas 1-1 to 6-2:

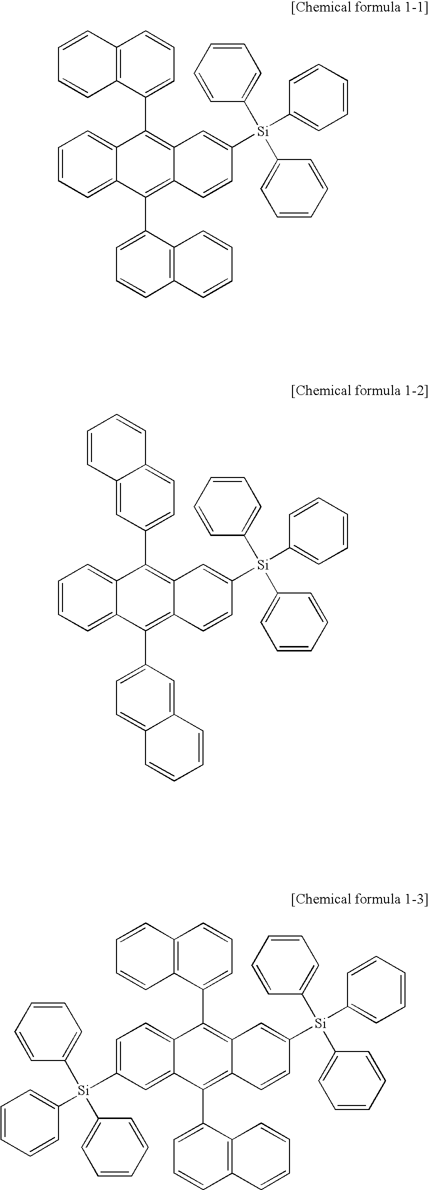

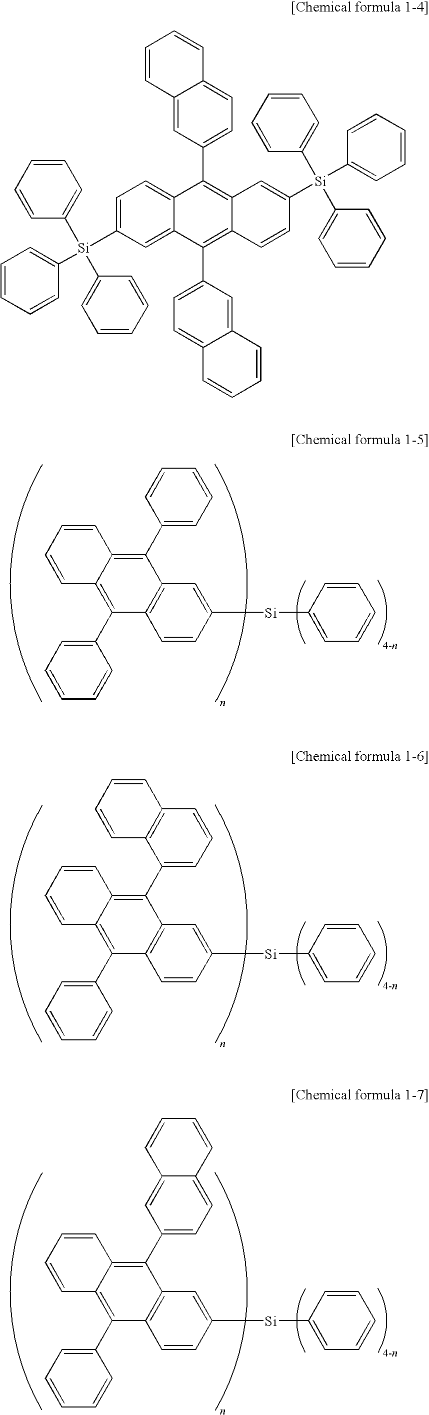

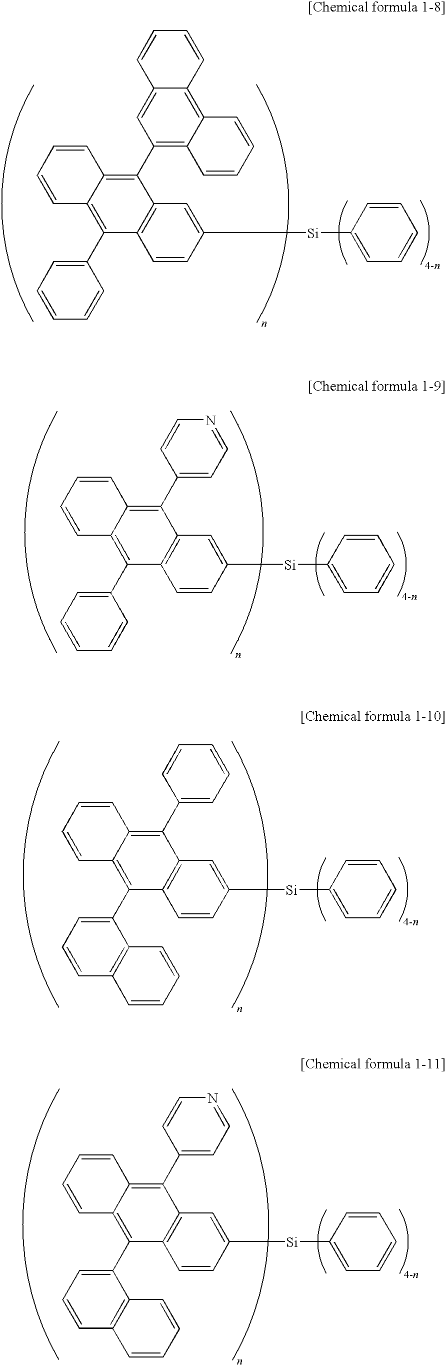

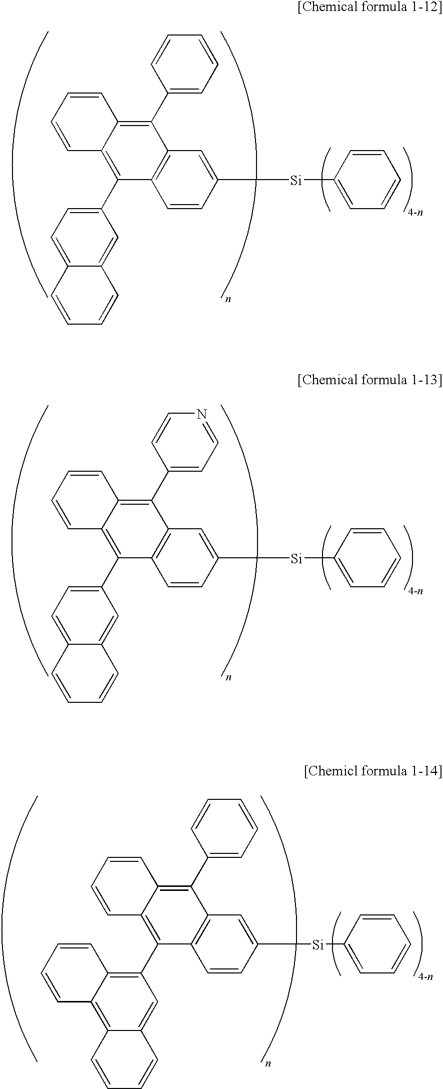

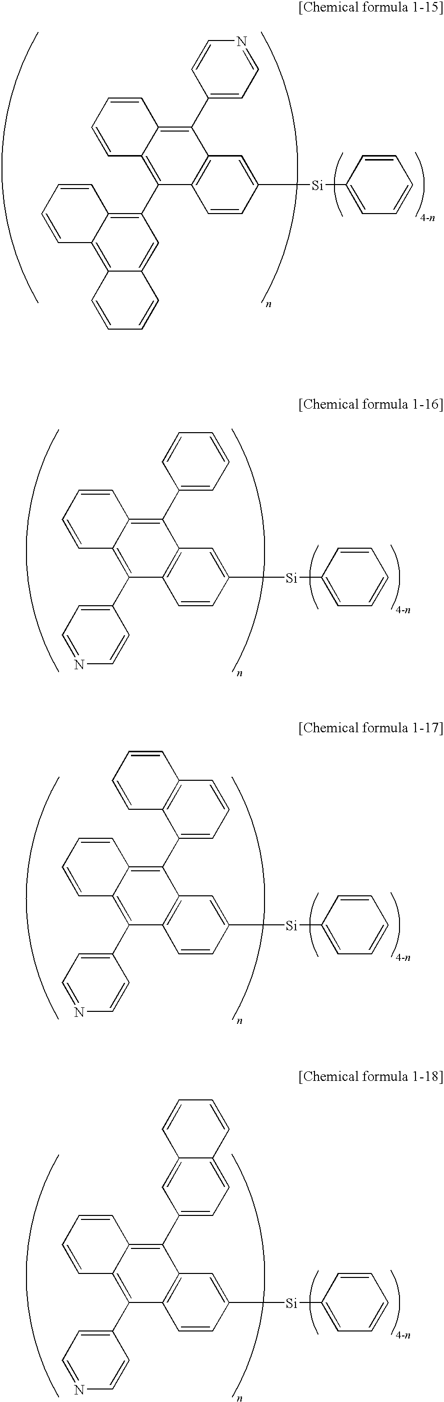

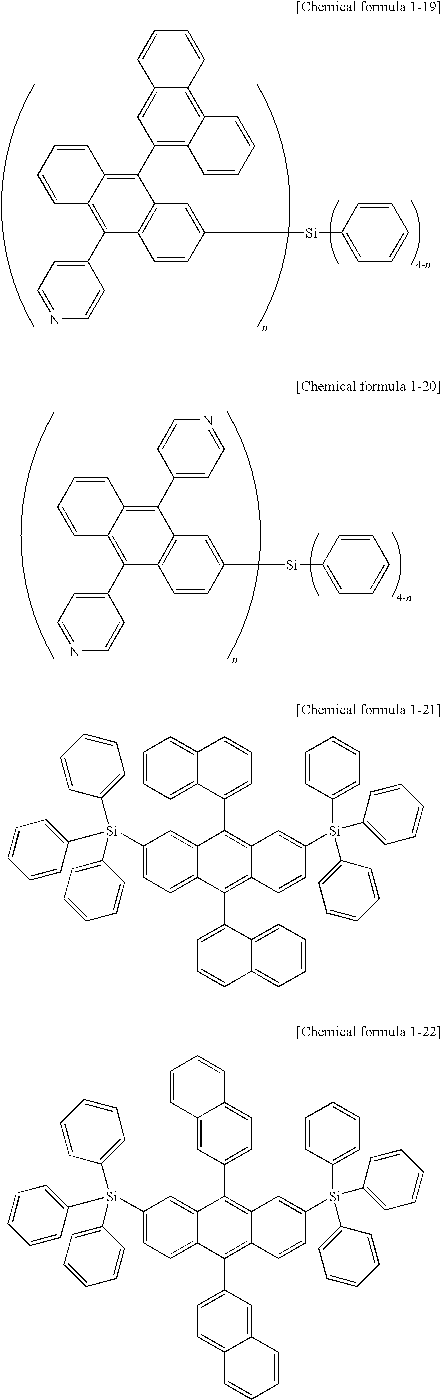

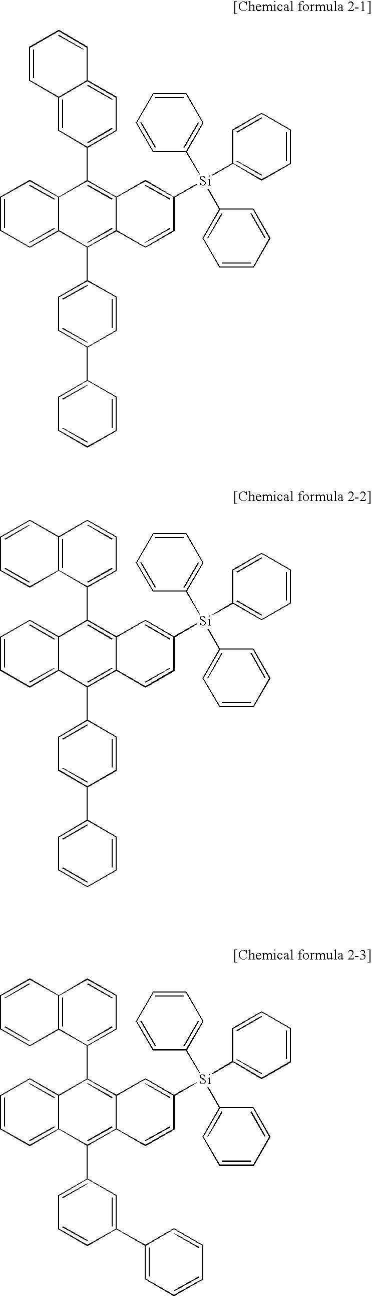

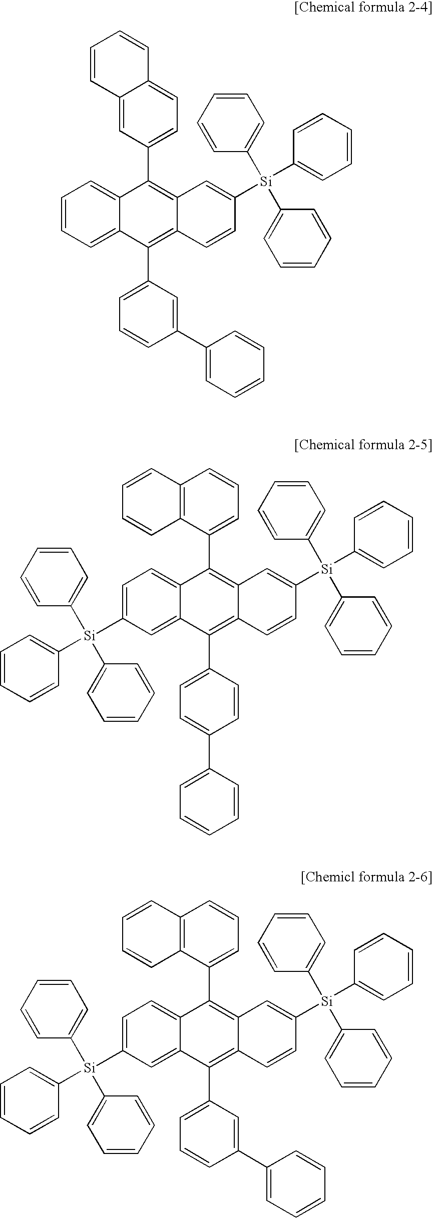

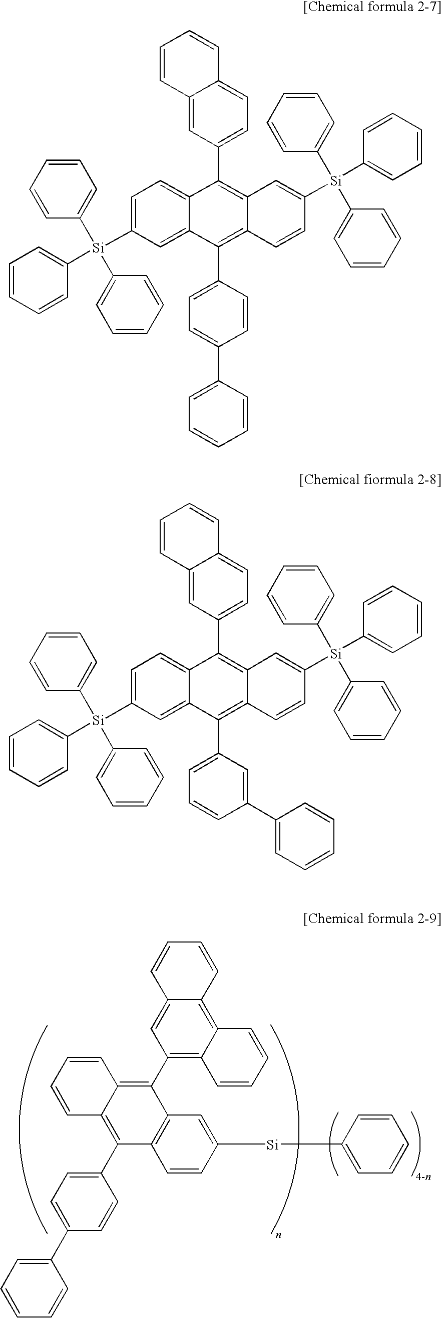

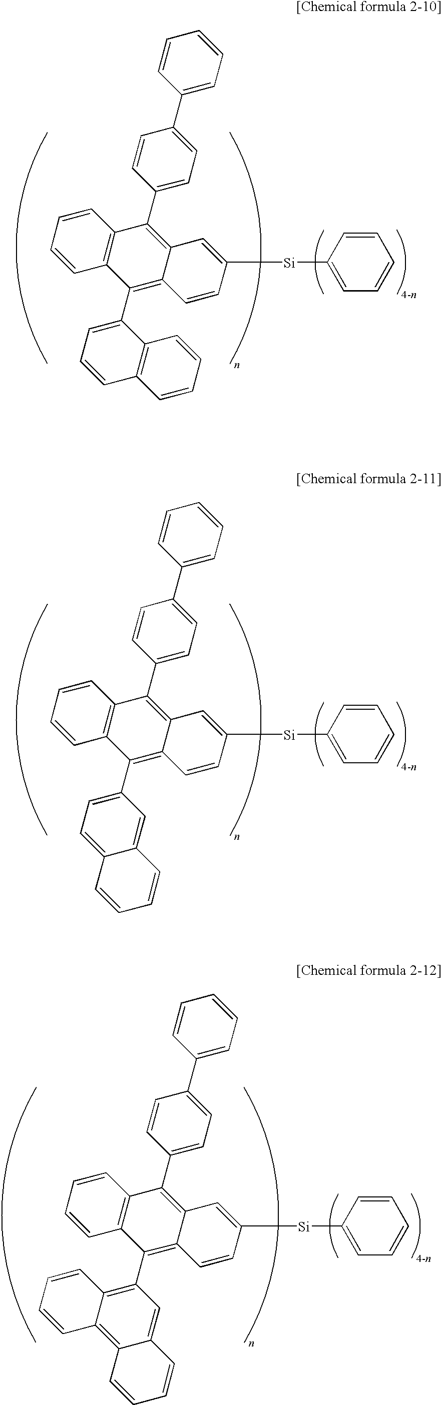

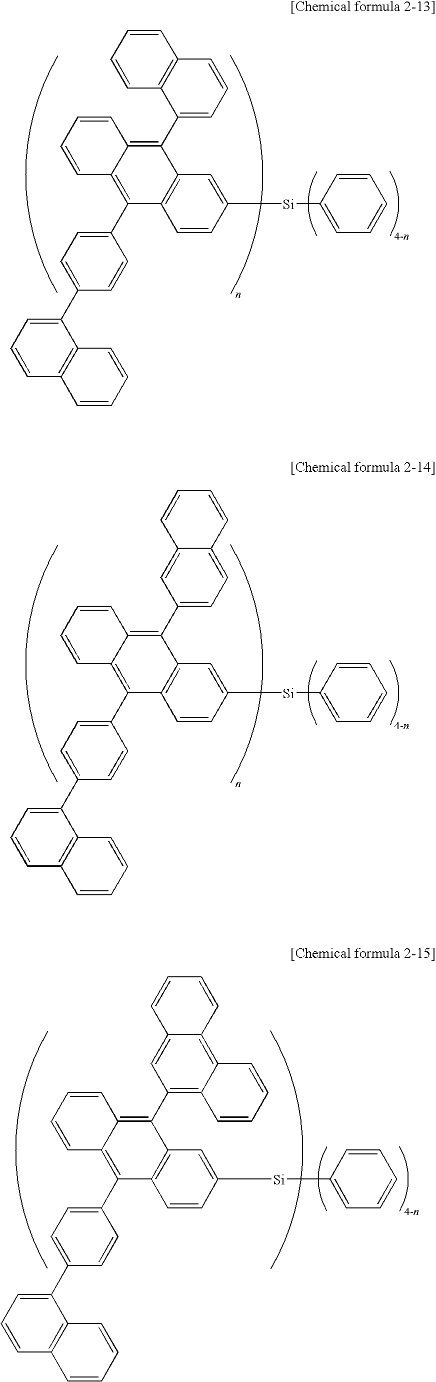

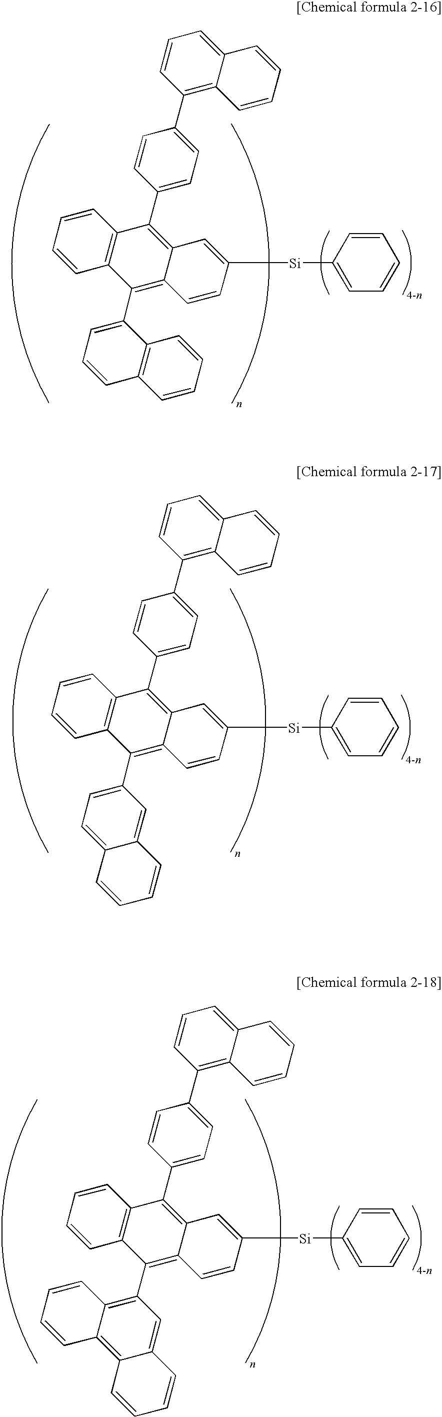

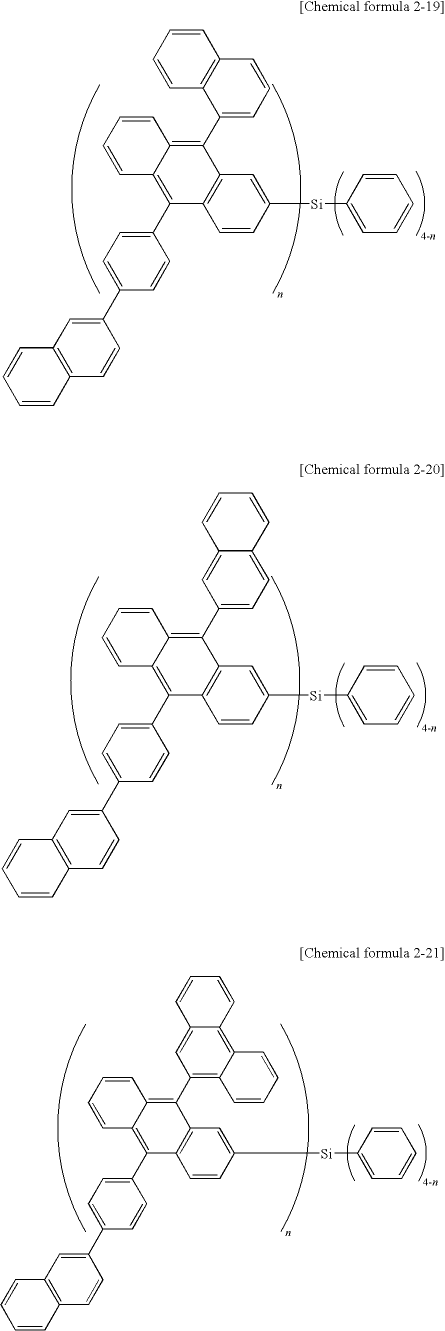

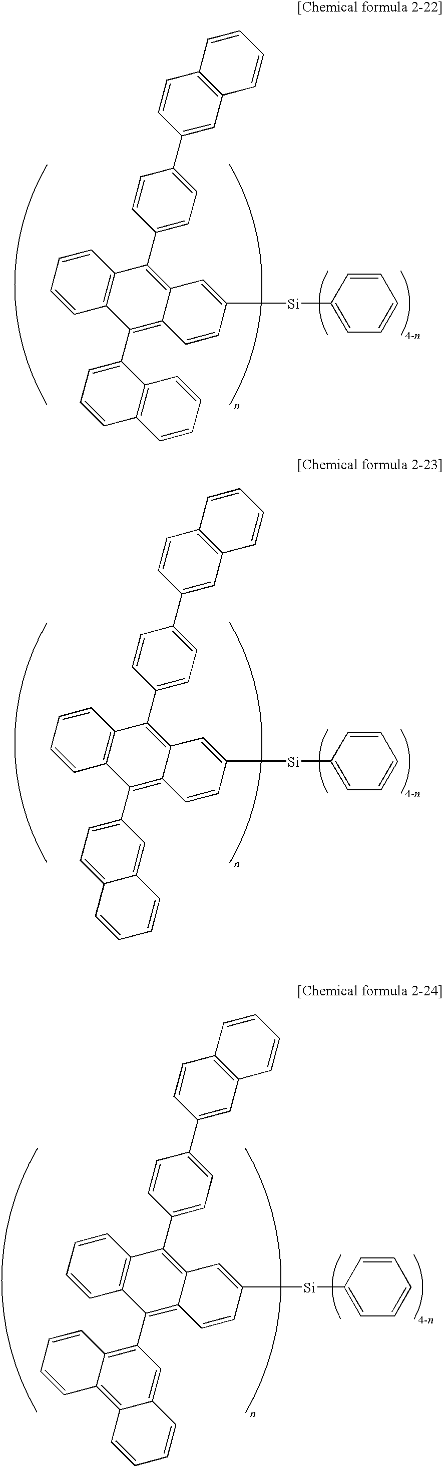

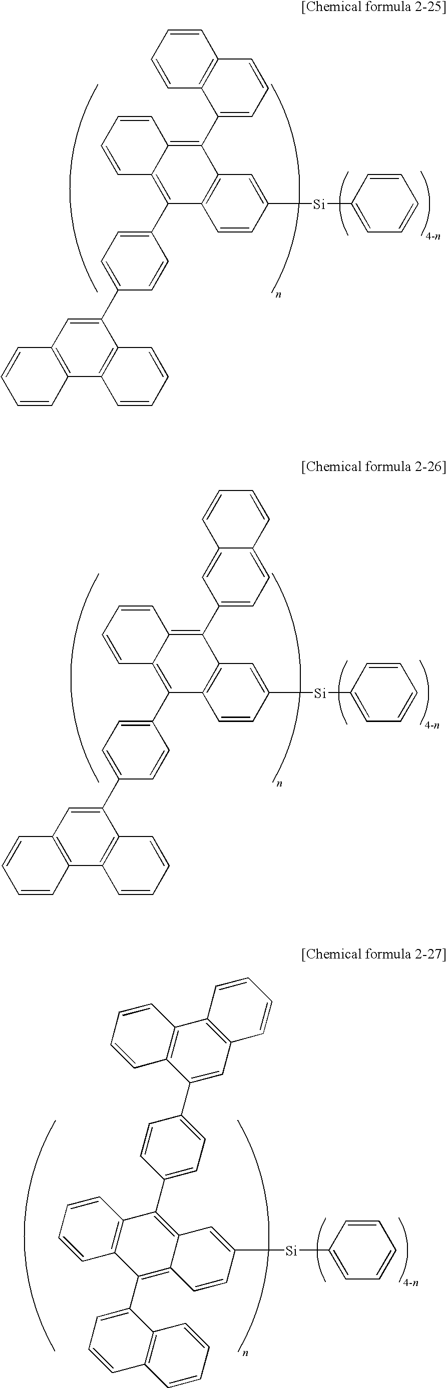

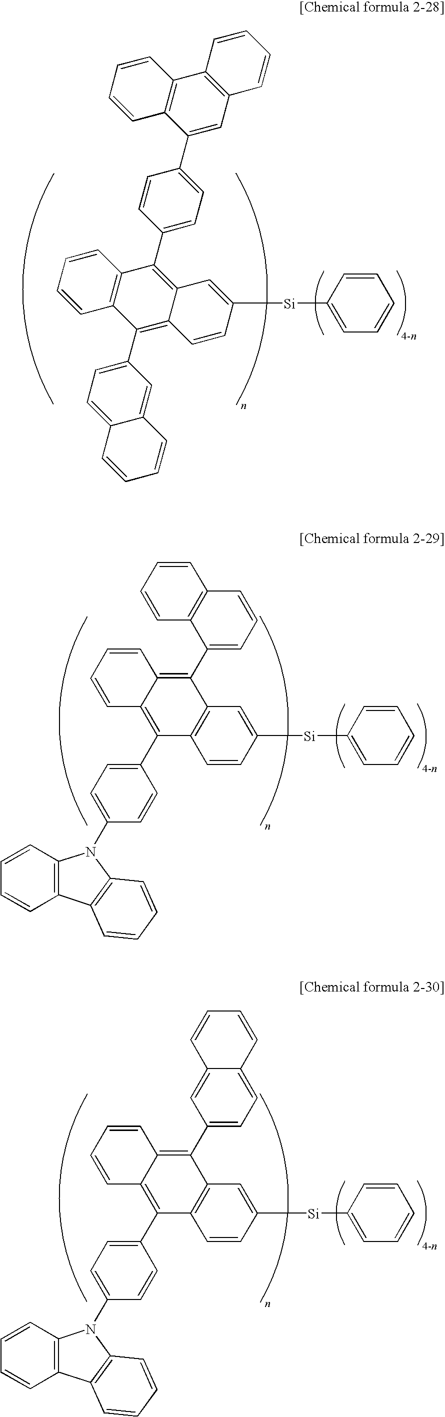

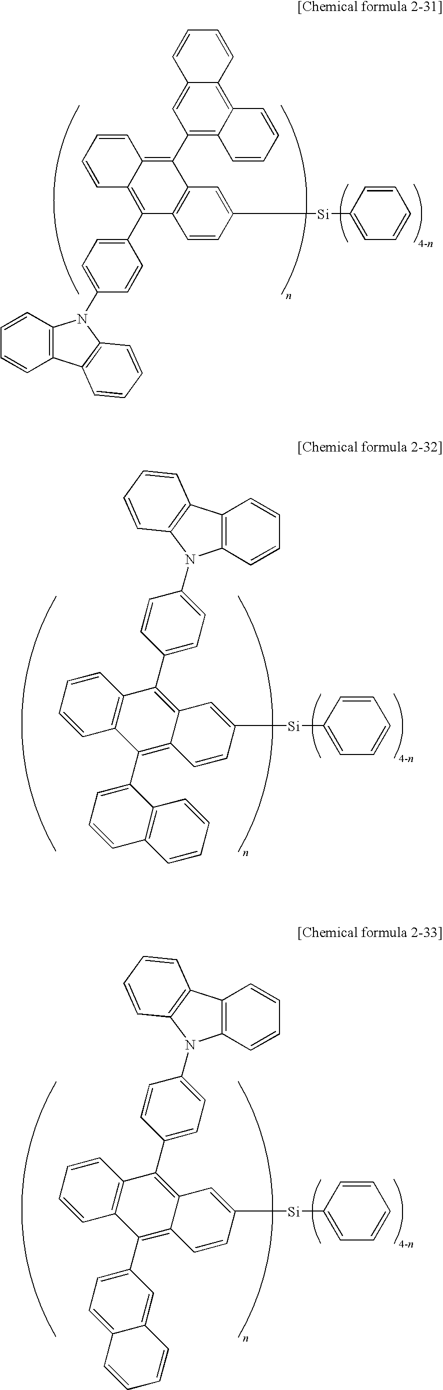

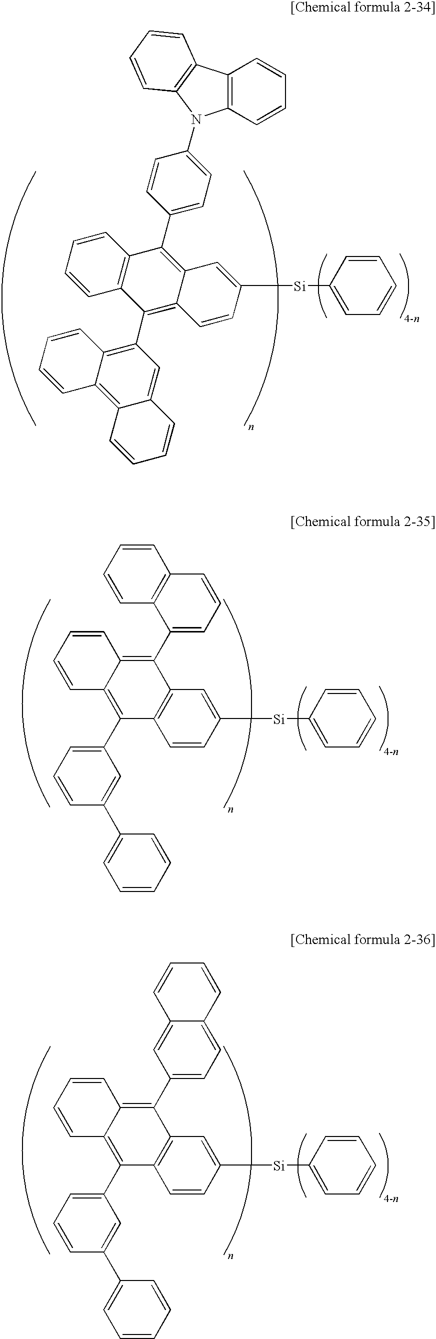

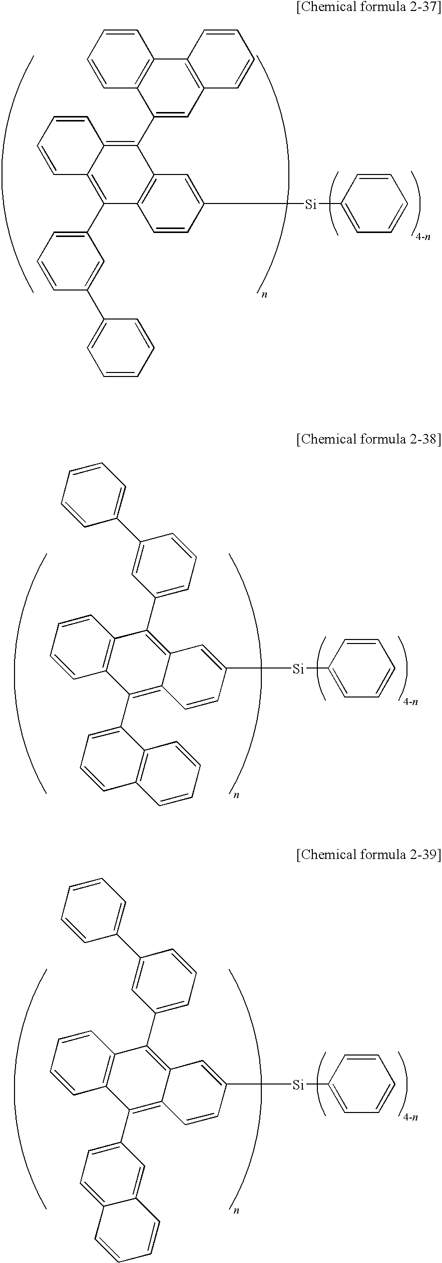

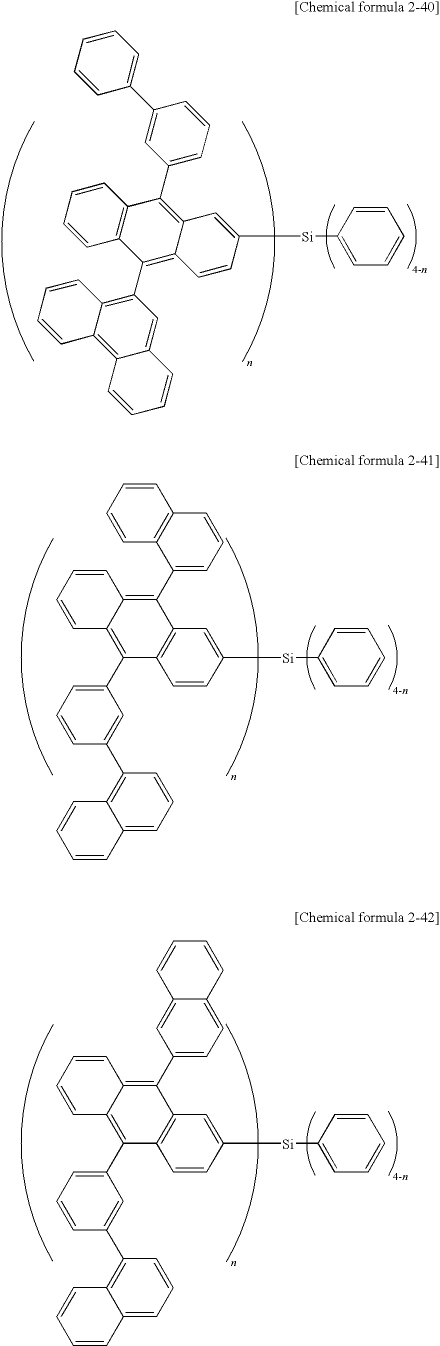

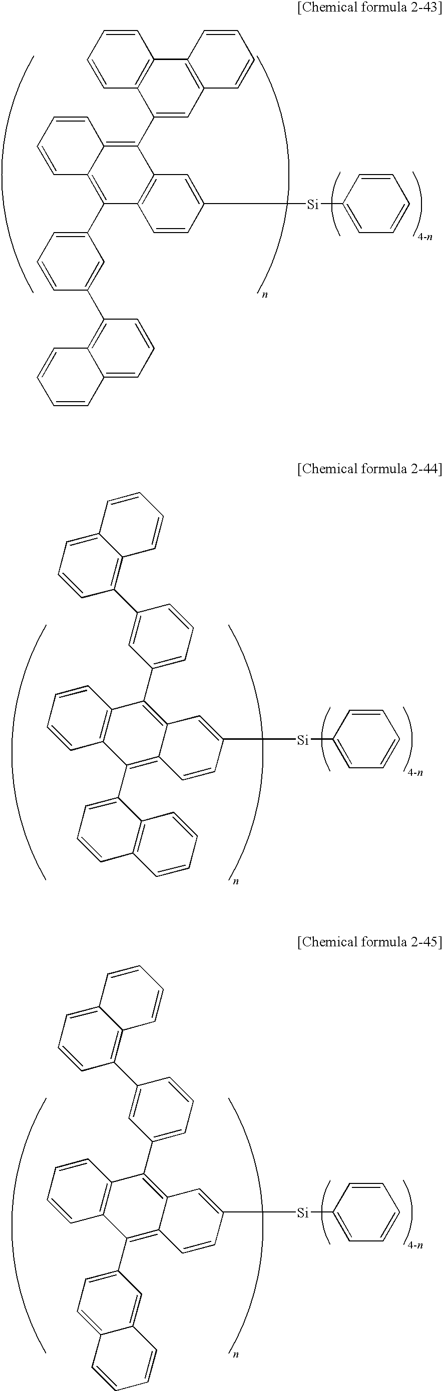

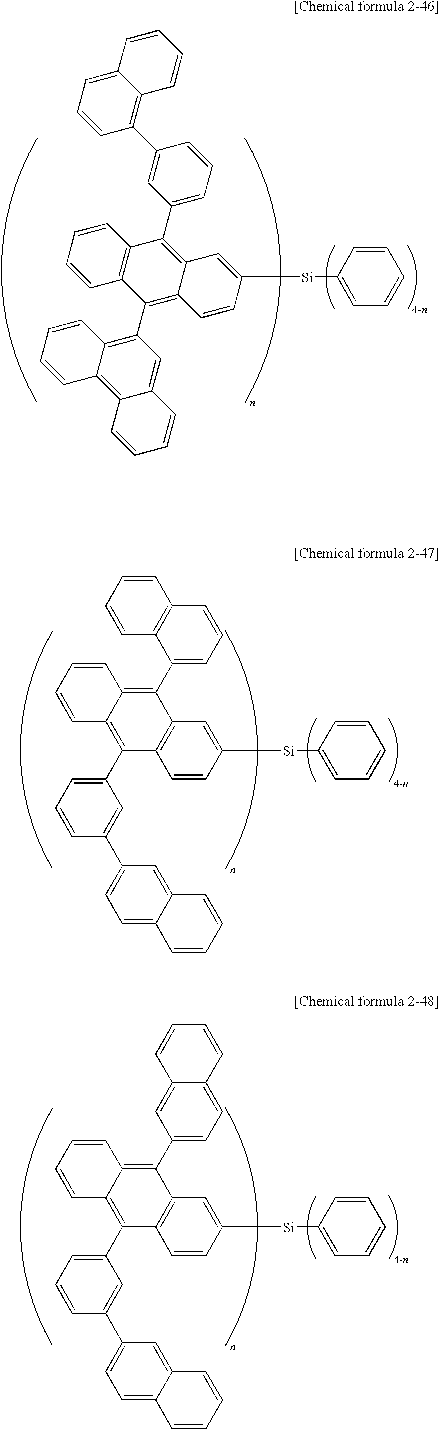

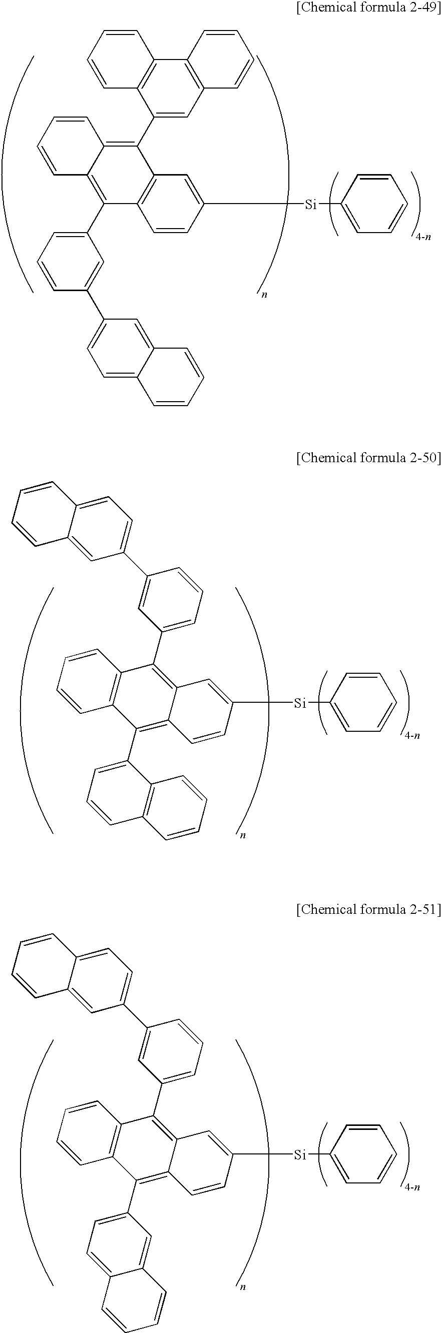

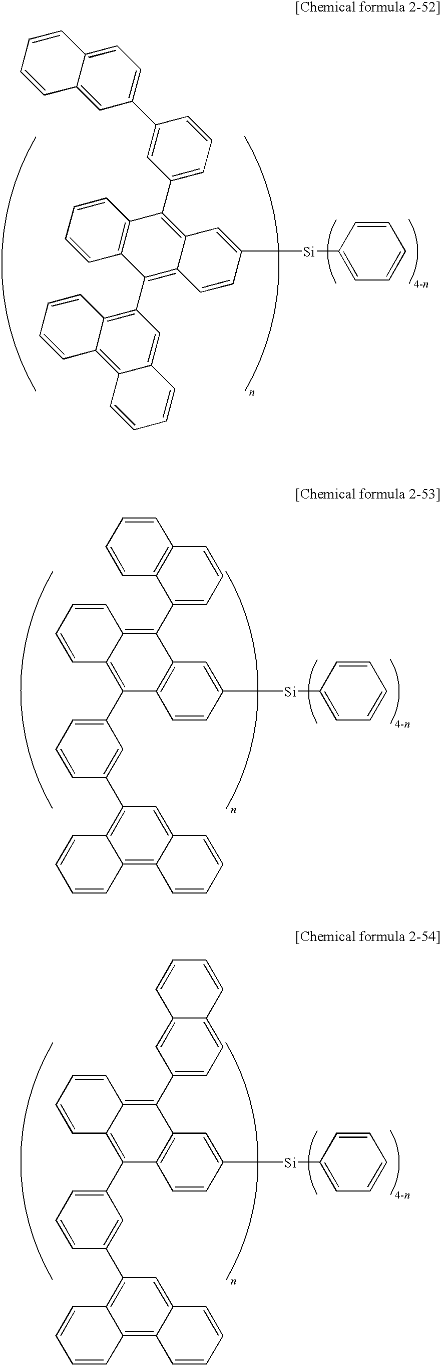

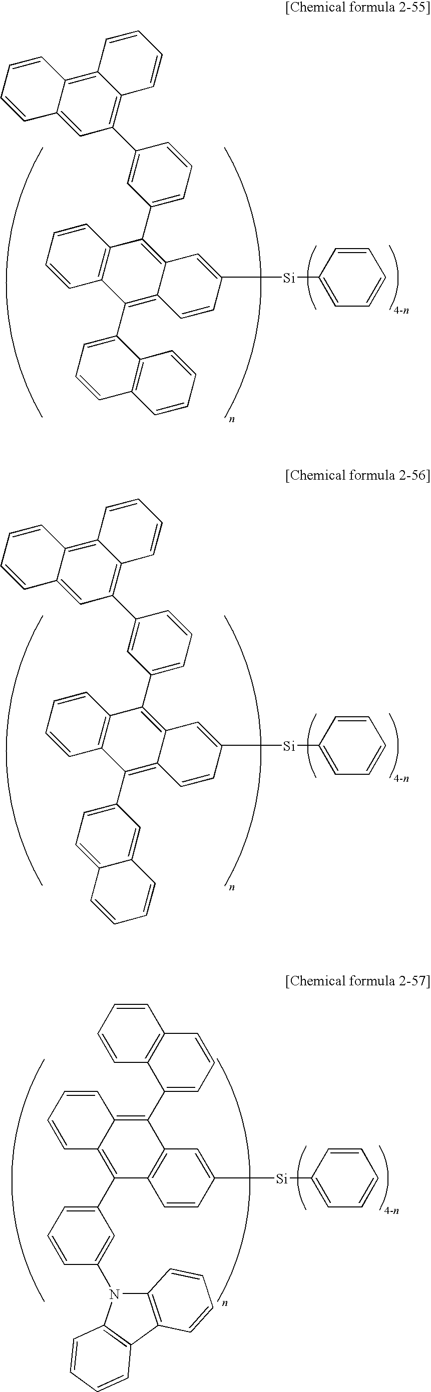

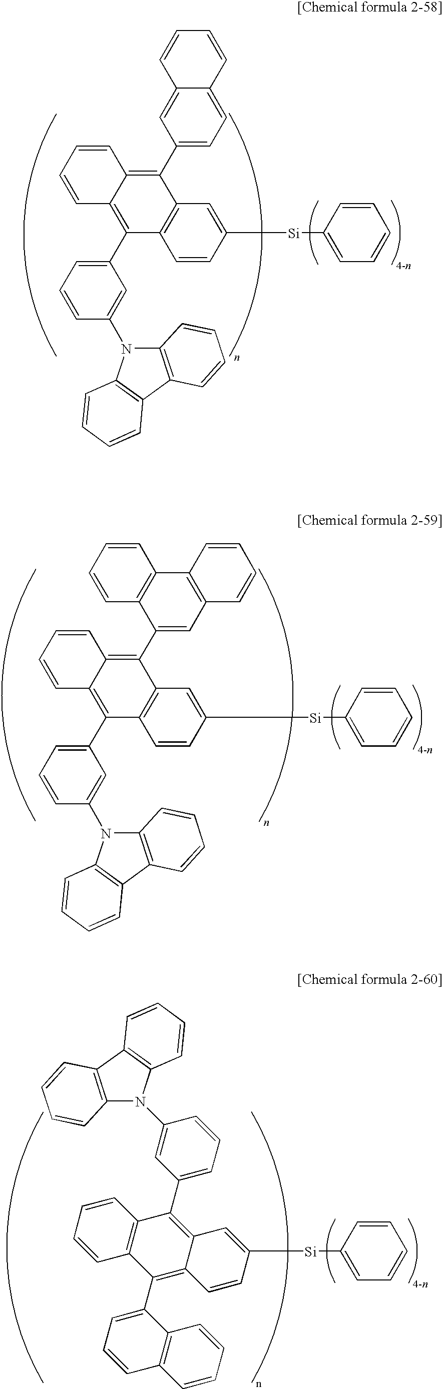

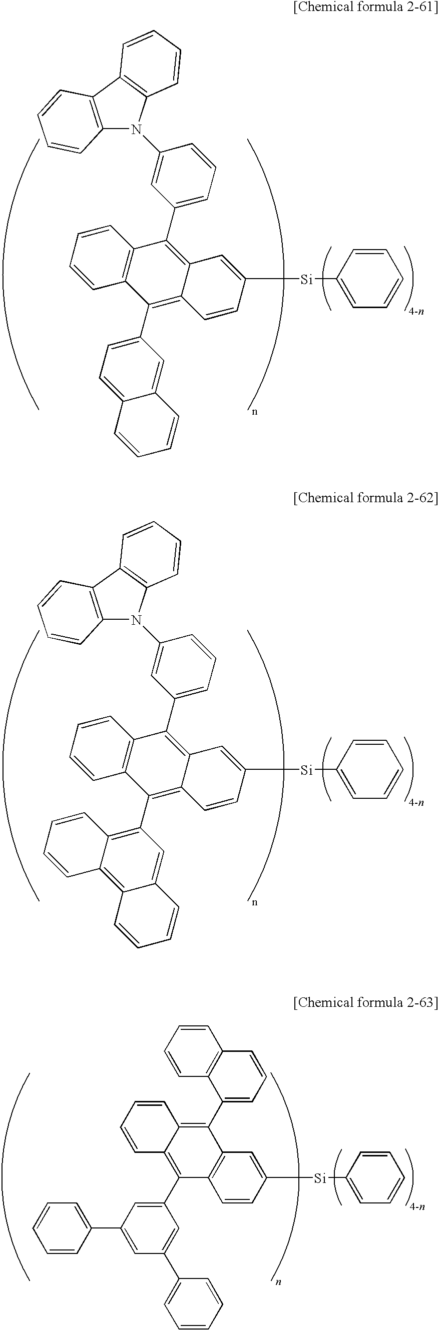

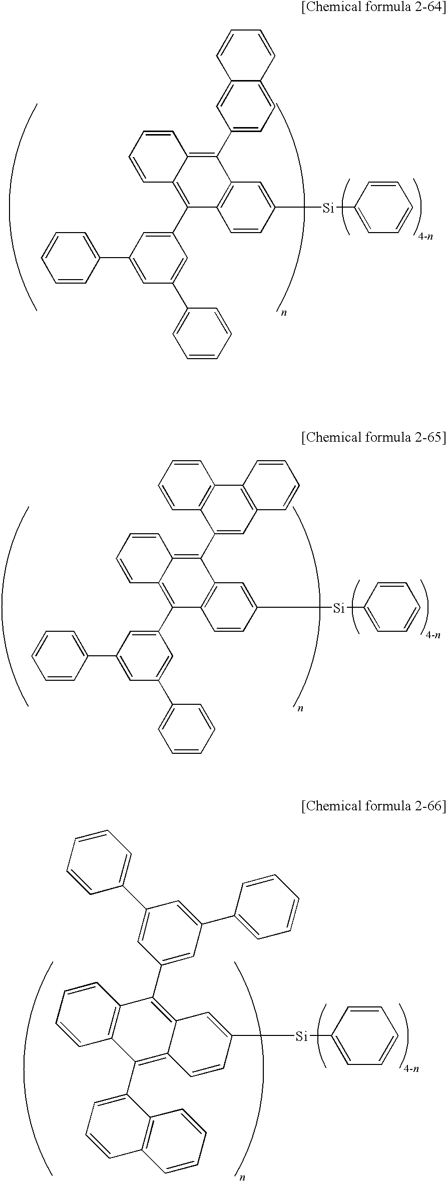

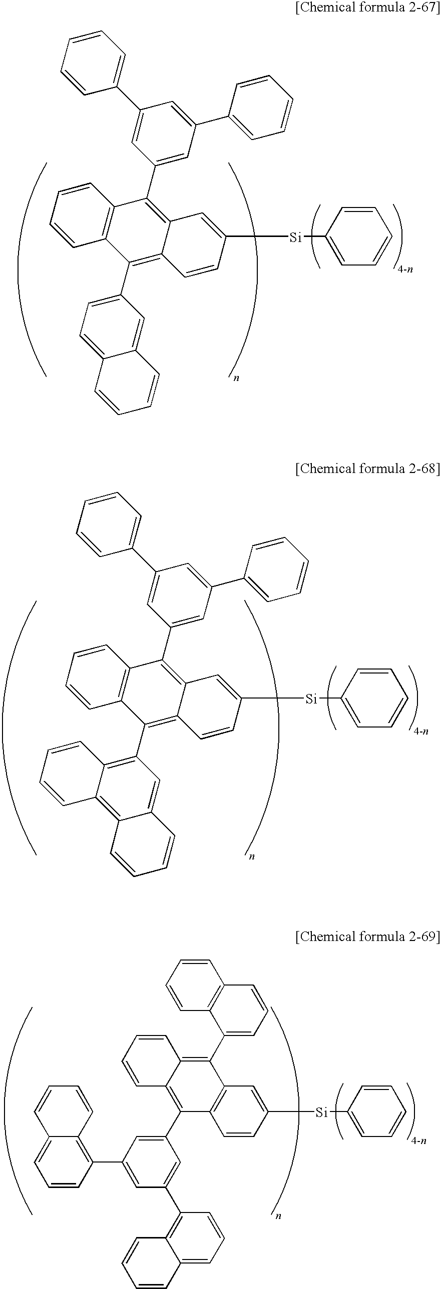

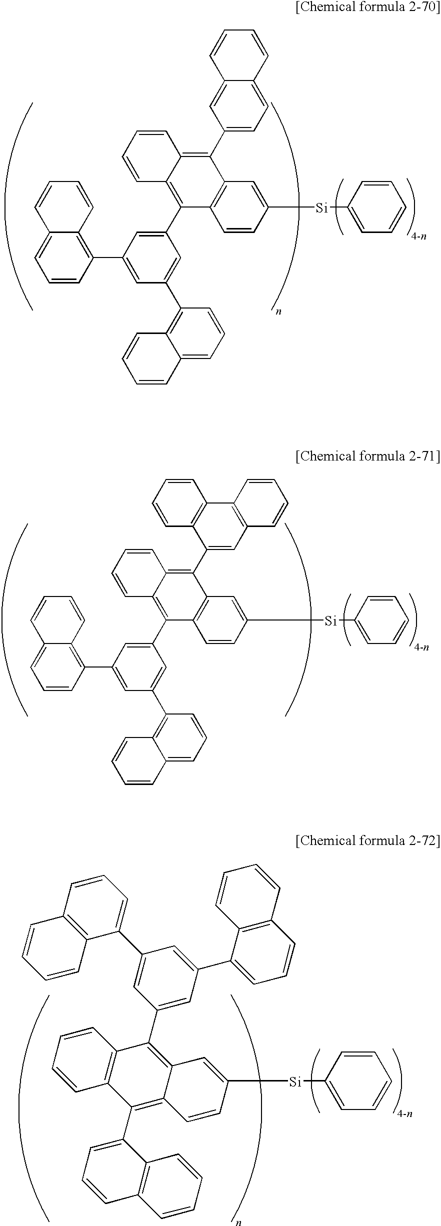

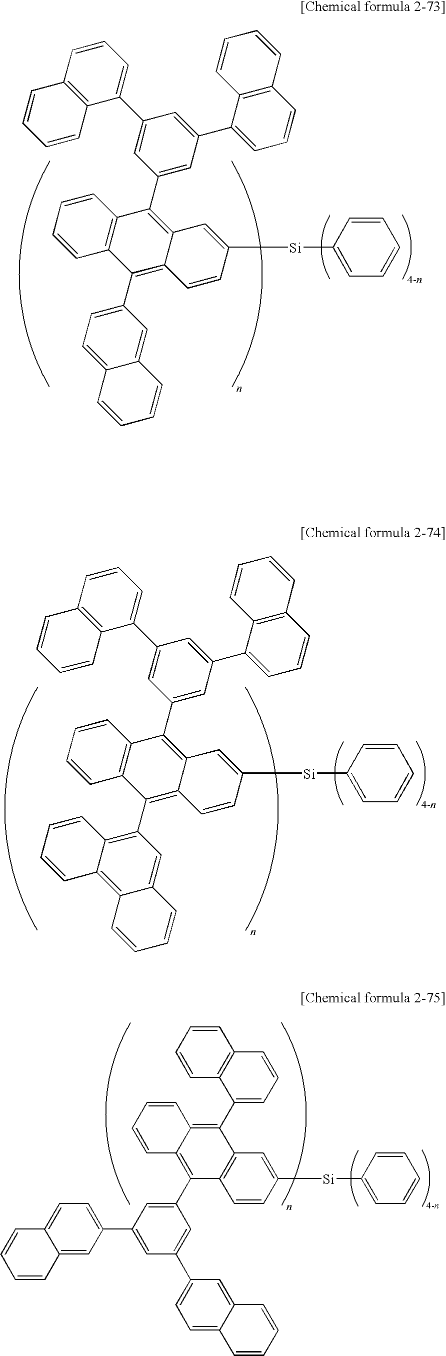

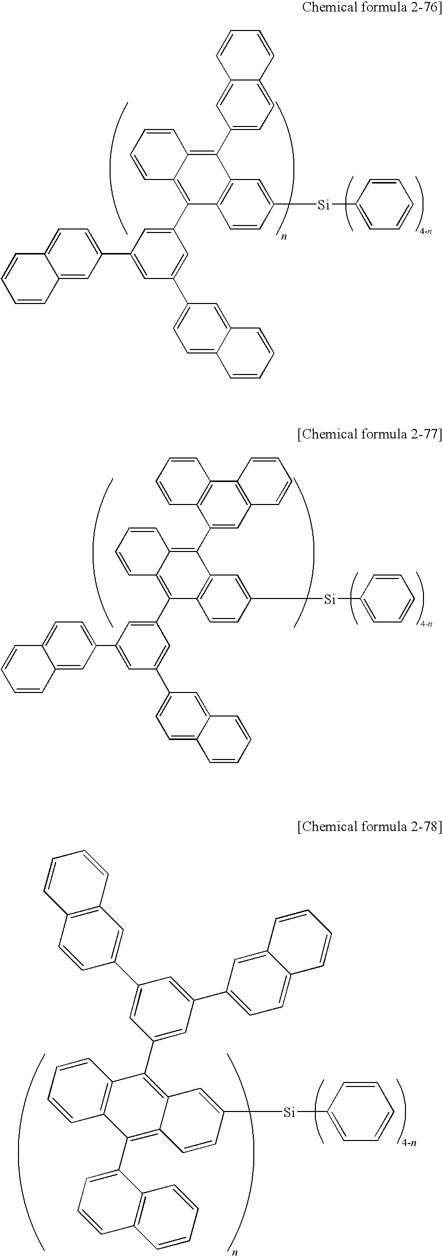

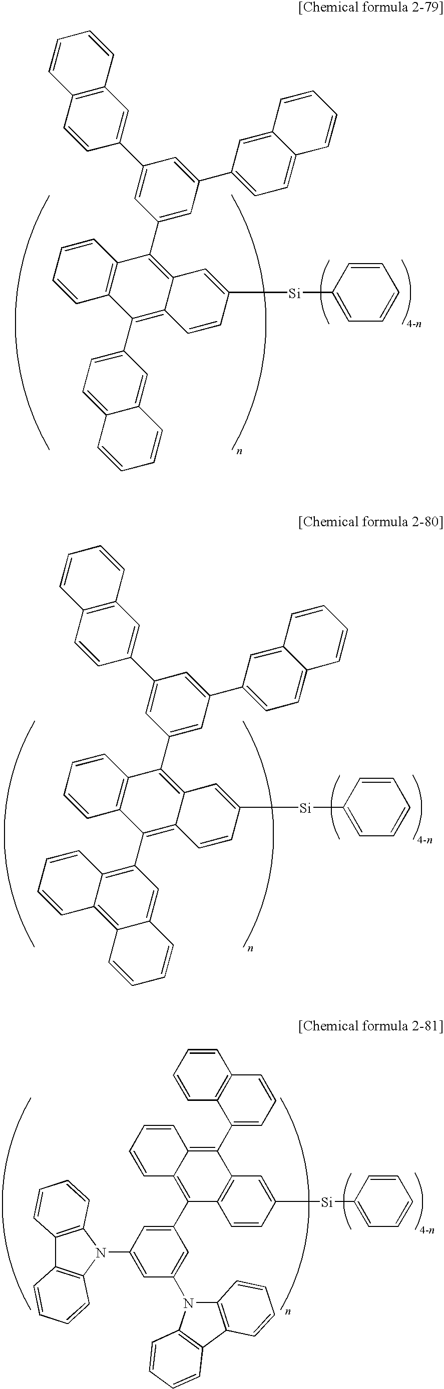

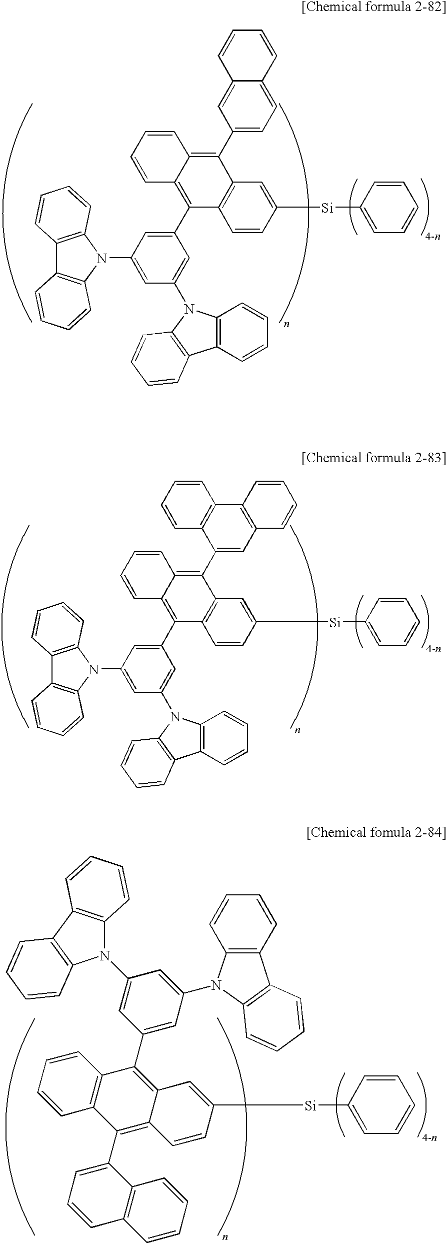

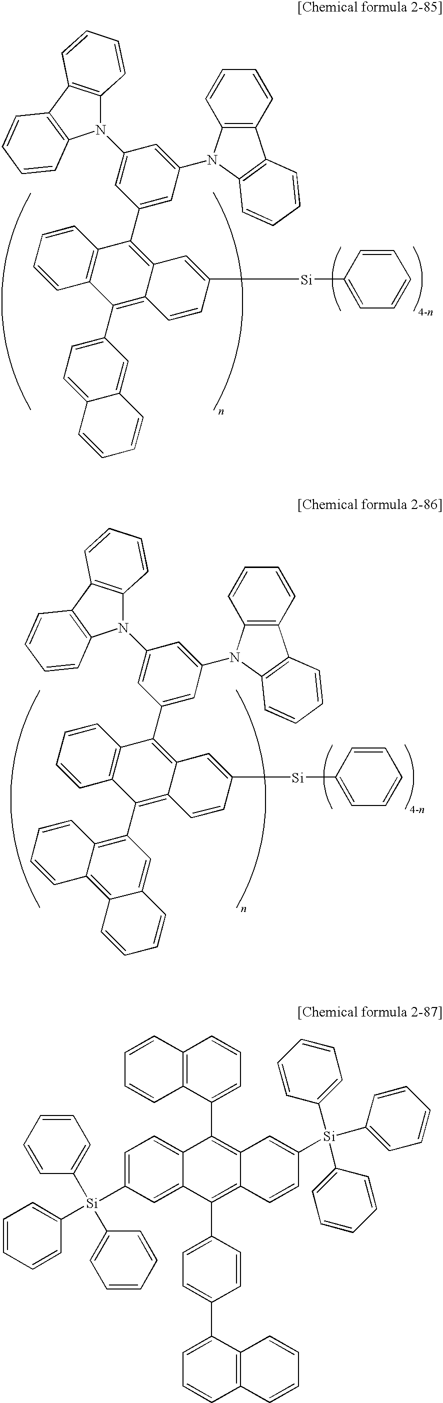

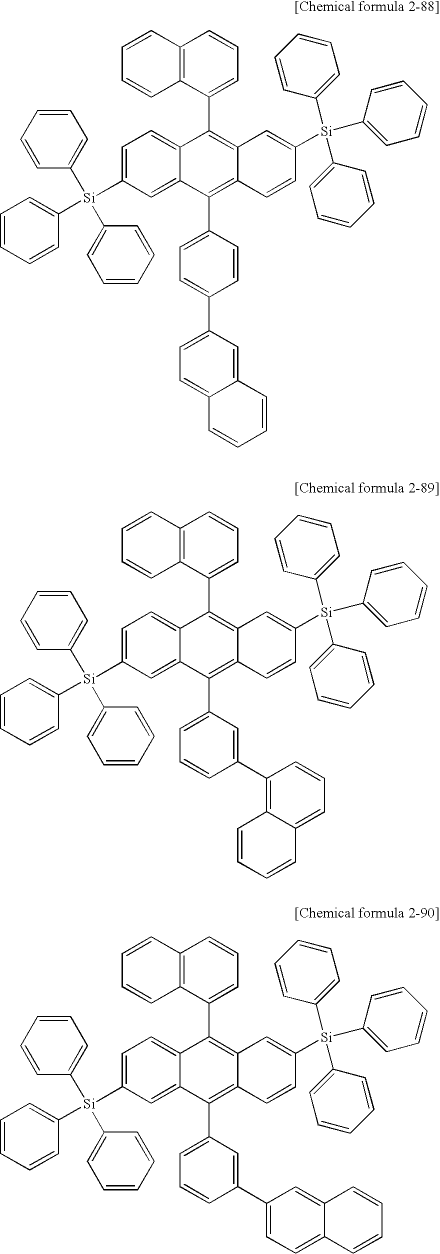

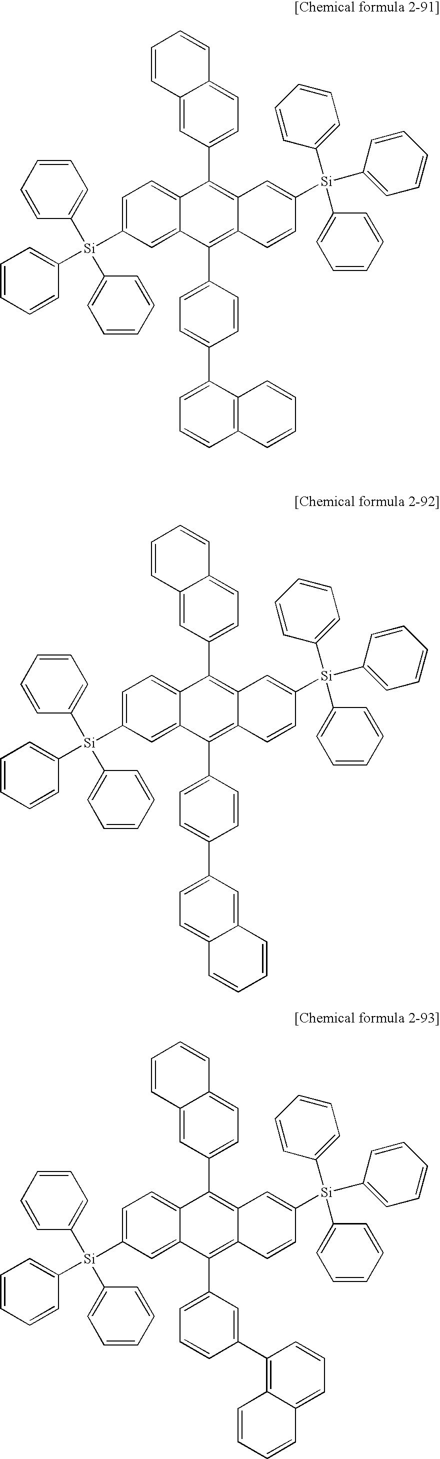

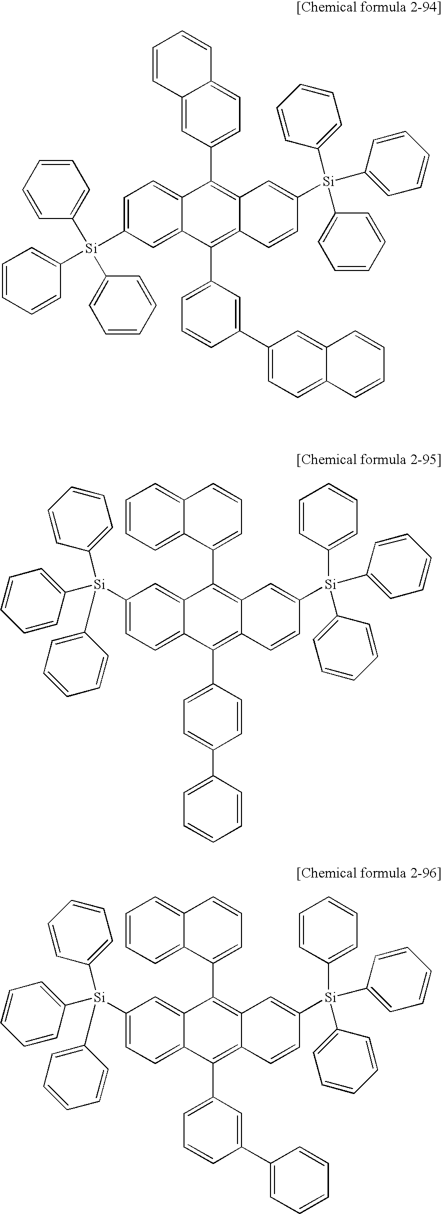

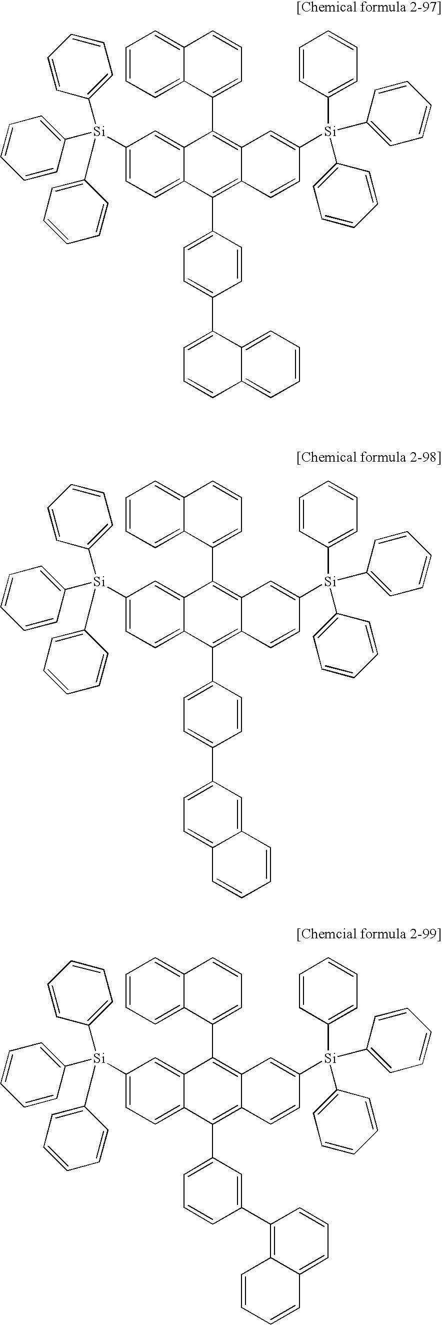

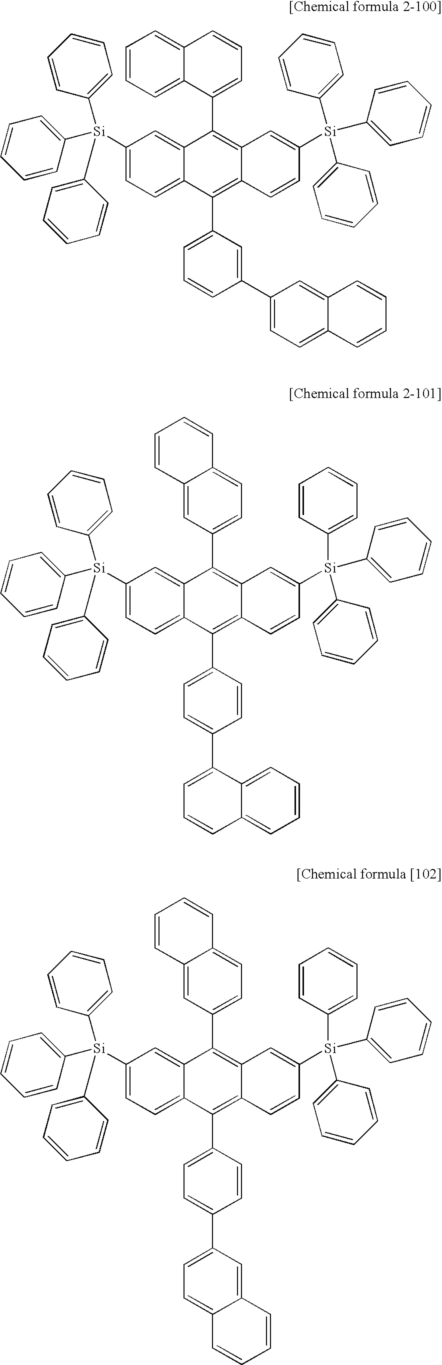

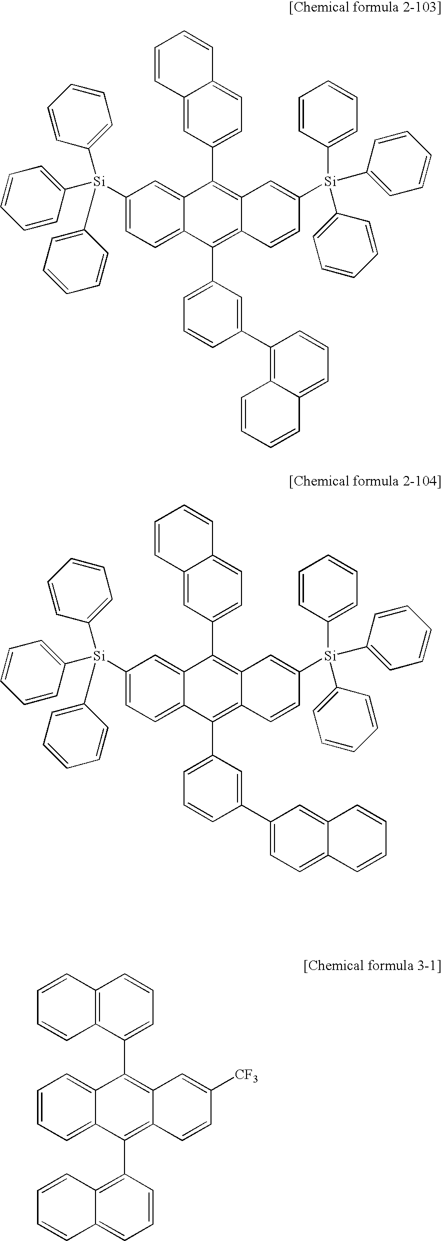

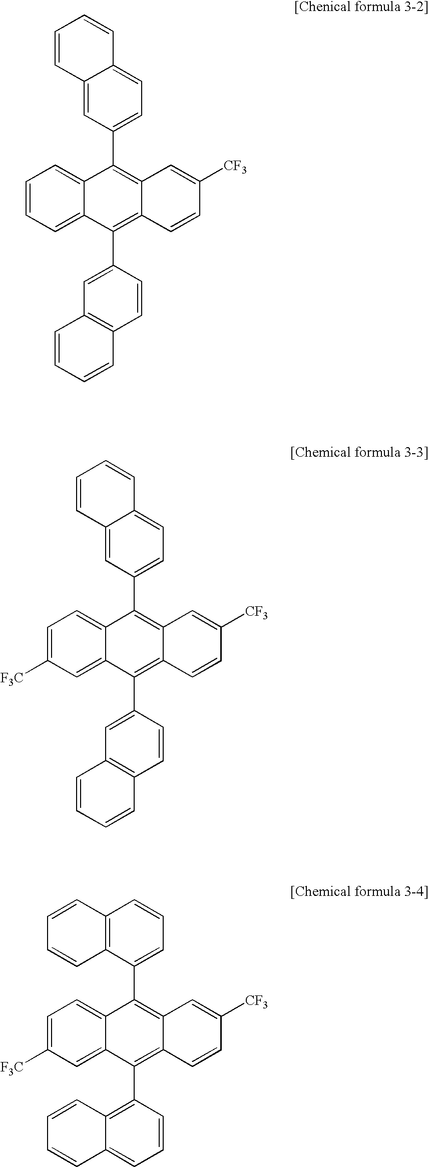

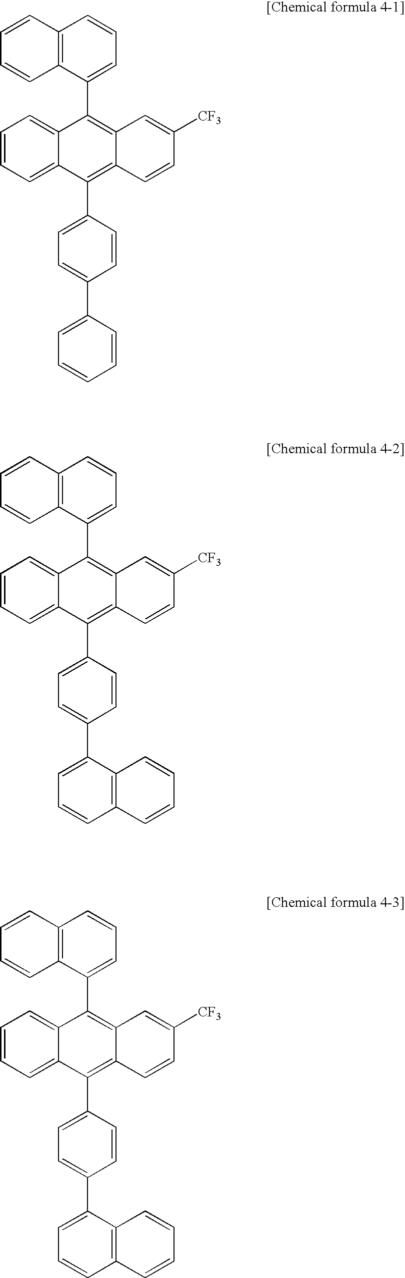

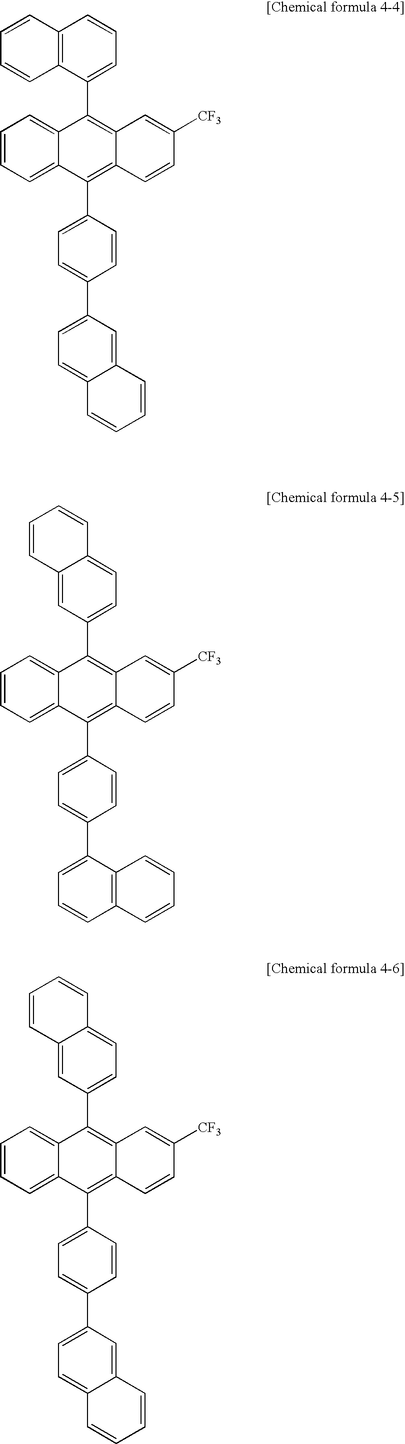

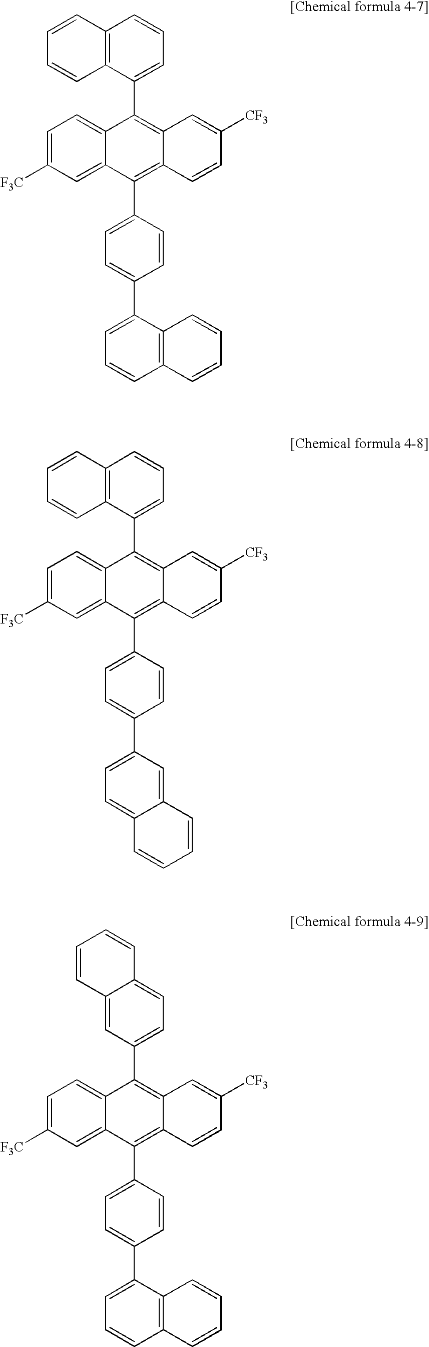

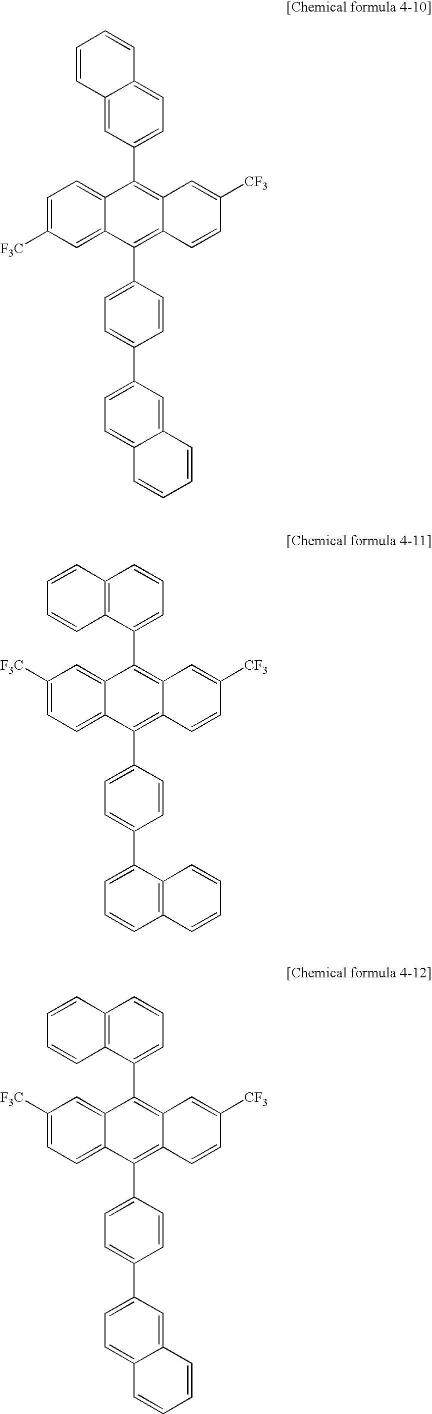

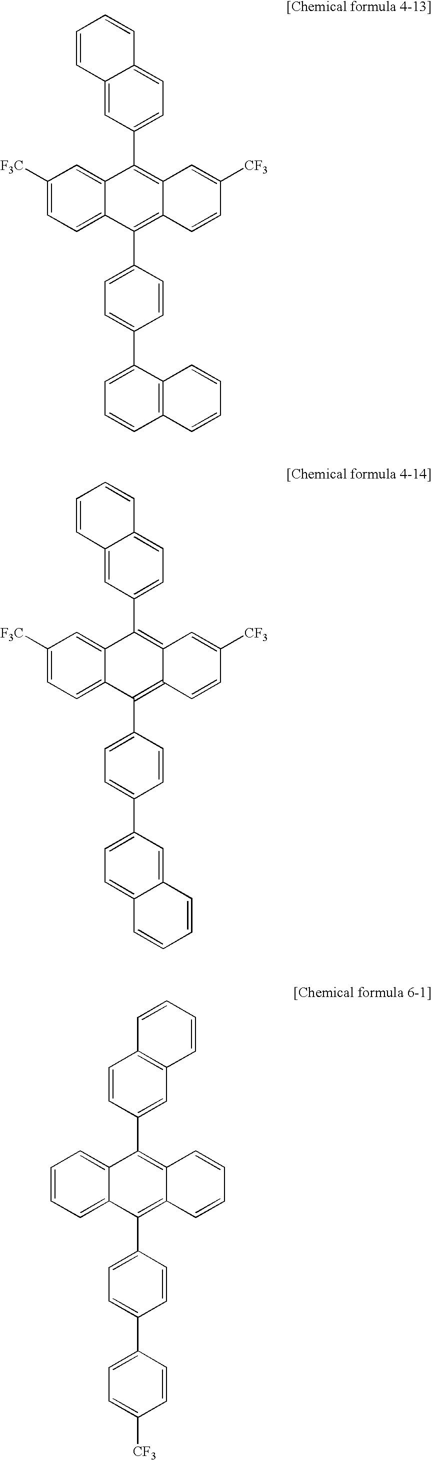

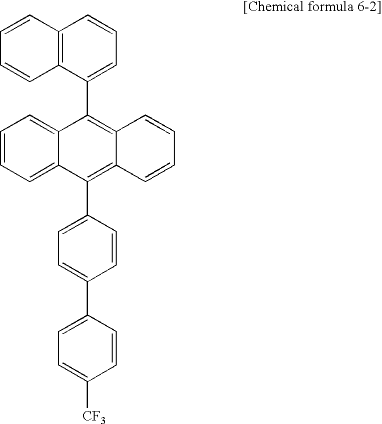

3. A making method of a compound which is represented by one of the chemical formulas 1 to 4 including one of following reaction formulas 1 to 4: 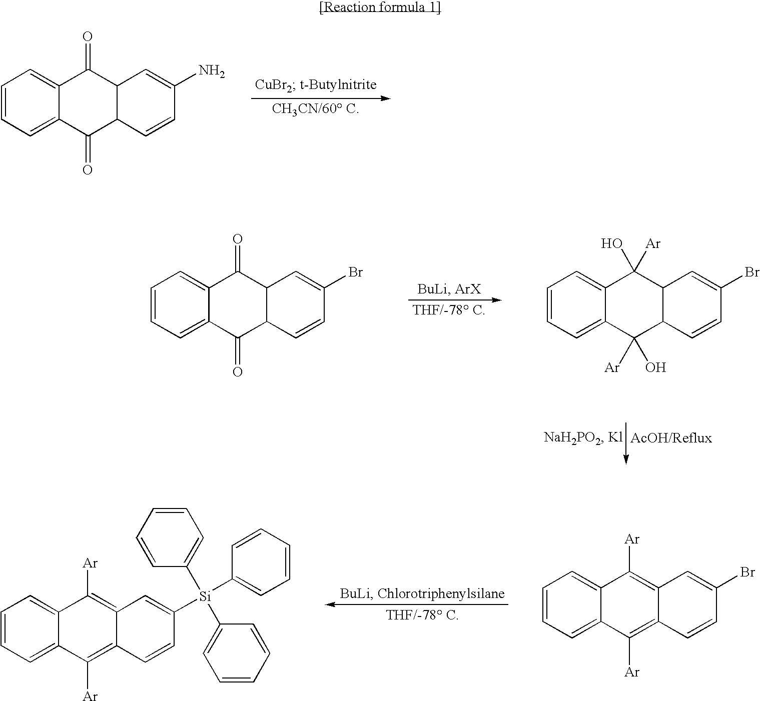 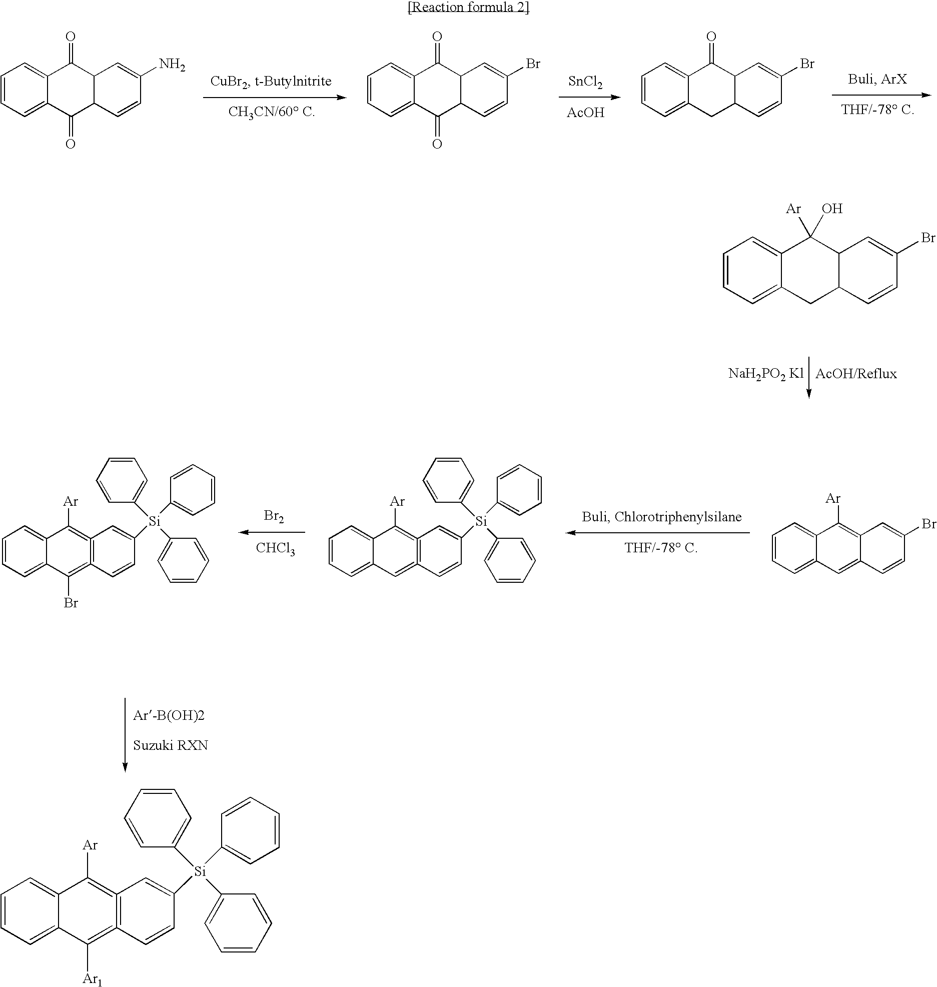 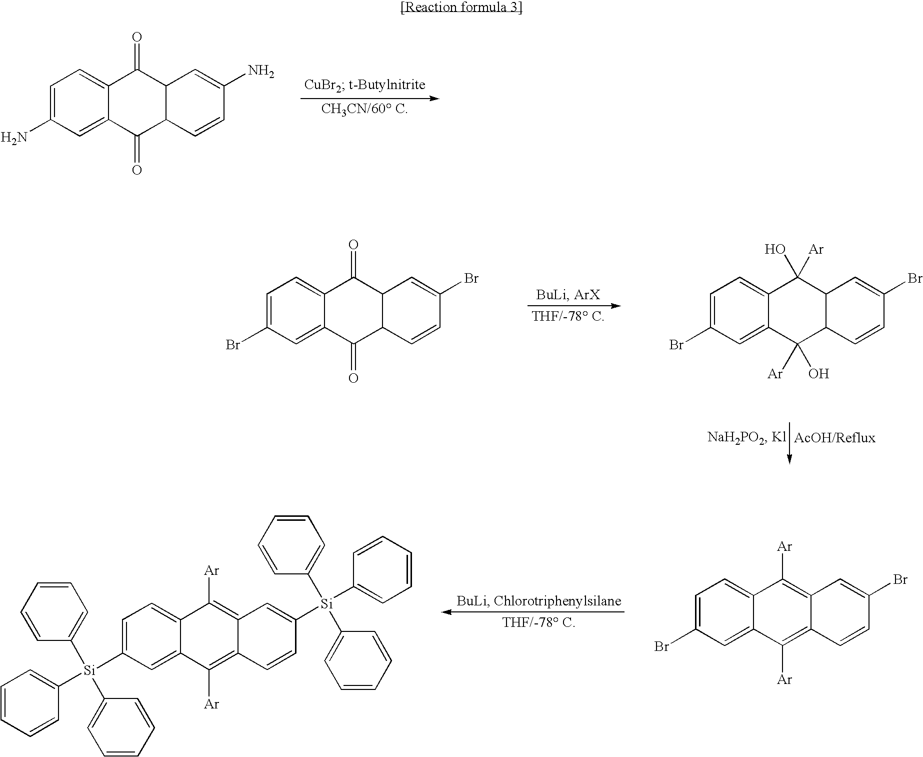 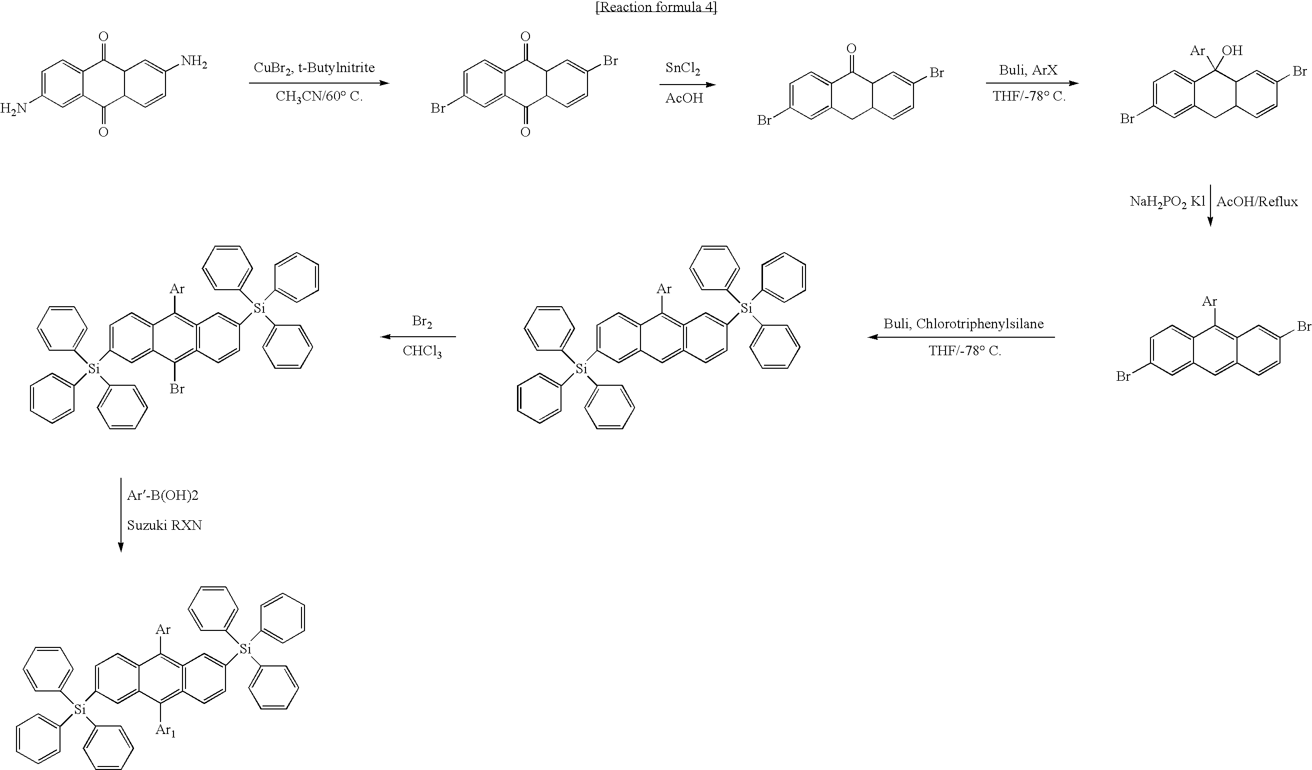
wherein, Ar and Ar₁ are a substituted or unsubstituted aryl group, independently, and X is a halogen compound.

4. An organic thin layer of an organic electroluminescent display device which is formed by the compound according to claim 1.

5. The organic thin layer according to claim 4, which comprises a hole injecting layer, a hole transporting layer or a light emitting layer.

6. An organic electroluminescent display device which comprises at least one organic thin layer between an anode and a cathode, the display device comprising:
at least one organic thin layer according to claim 4.

7. A display device which comprises an organic electroluminescent display device according to claim 6.
